(19) United States
(12) Patent Application Publication
(10) Pub. No.: US 2012/0202153 A1
(43) Pub. Date: Aug. 9, 2012

(54) RESIST COMPOSITION AND PATTERNING PROCESS

(75) Inventor: Jun Hatakeyama, Joetsu-shi (JP)

(73) Assignee: SHIN-ETSU CHEMICAL CO., LTD., Tokyo (JP)

(21) Appl. No.: 13/368,582

(22) Filed: Feb. 8, 2012

(30) Foreign Application Priority Data
Feb. 9, 2011 (JP) 2011-025653

(51) Int. Cl. G03F 7/20; G03F 7/004; C08F 234/04; C08F 230/04; C08F 234/00

(52) U.S. Cl. 430/283.1; 526/240; 526/241; 430/285.1; 430/325; 430/296

(57) ABSTRACT

A resist composition comprising a polymer having recurring units having an acid labile group and recurring units of a magnesium, copper, zinc or cesium salt of (meth)acrylic acid, styrenecarboxylic acid or vinylnaphthalenecarboxylic acid copolymerized together exhibits a high resolution, high sensitivity, and minimal LER. The resist composition is best suited as the patterning material for VLSIs and photomasks.

### CROSS-REFERENCE TO RELATED APPLICATION

This non-provisional application claims priority under 35 U.S.C. §119(a) on Patent Application No. 2011-025653 filed in Japan on Feb. 9, 2011, the entire contents of which are hereby incorporated by reference.

### TECHNICAL FIELD

This invention relates to a resist composition, and more particularly to a chemically amplified positive resist composition adapted for the EB and EUV lithography processes; and a patterning process using the same.

### BACKGROUND ART

To meet the demand for higher integration density and operating speed of LSIs, the effort to reduce the pattern rule is in rapid progress. The wide-spreading flash memory market and the demand for increased storage capacities drive forward the miniaturization technology. As the advanced miniaturization technology, manufacturing of microelectronic devices at the 65-nm node by the ArF lithography has been implemented in a mass scale. Manufacturing of 45-nm node devices by the next generation ArF immersion lithography is approaching to the verge of high-volume application. The candidates for the next generation 32-nm node include ultra-high NA lens immersion lithography using a liquid having a higher refractive index than water in combination with a high refractive index lens and a high refractive index resist film, EUV lithography of 13.5 nm wavelength, and double patterning version of the ArF lithography, on which active research efforts have been made.

The current technology is approaching to the processing size which is reduced below 50 nm as minimum line width. When the processing size is so reduced, the thickness of resist film must be reduced below 100 nm, depending on the surface material of the substrate to be processed, because of such factors as the structural strength to maintain the pattern against the surface tension of developer and the adhesion strength to the substrate. On use of prior art chemically amplified resist materials intended to form high-resolution resist film, for example, based on a base resin having an acetal protective group, no significant degradation of line edge roughness (LER) does occur with a resist film having a thickness of 150 nm, but LER is substantially exacerbated when the film thickness is reduced below 100 nm.

With respect to high-energy radiation of very short wavelength such as EB or x-ray, hydrocarbons and similar light elements used in resist materials have little absorption. Then polyhydroxystyrene base resist materials are under consideration. Resist materials for EB lithography are practically used in the mask image writing application. Recently, the mask manufacturing technology becomes of greater interest. Reduction projection exposure systems or steppers have been used since the time when the exposure light was g-line. While their demagnification factor was ⅕, a factor of ¼ is now used as a result of chip size enlargement and projection lens diameter increase. It becomes of concern that a dimensional error of a mask has an impact on the dimensional variation of a pattern on wafer. It is pointed out that as the pattern feature is reduced, the value of a dimensional variation on the wafer becomes greater than the value of a dimensional error of the mask. This is evaluated by a mask error enhancement factor (MEEF) which is a dimensional variation on wafer divided by a dimensional error of mask. Patterns on the order of 45 nm often show an MEEF in excess of 4. In a situation including a demagnification factor of ¼ and a MEEF of 4, the mask manufacture needs an accuracy substantially equivalent to that for equi-magnification masks.

The exposure system for mask manufacturing made a transition from the laser beam exposure system to the EB exposure system to increase the accuracy of line width. Since a further size reduction becomes possible by increasing the accelerating voltage of the electron gun in the EB exposure system, the accelerating voltage increased from 10 keV to 30 keV and reached 50 keV in the current mainstream system, with a voltage of 100 keV being under investigation.

As the accelerating voltage increases, a lowering of sensitivity of resist film becomes of concern. As the accelerating voltage increases, the influence of forward scattering in a resist film becomes so reduced that the contrast of electron image writing energy is improved to ameliorate resolution and dimensional control whereas electrons can pass straightforward through the resist film so that the resist film lowers its sensitivity. Since the mask exposure tool is designed for exposure by direct continuous writing, a lowering of sensitivity of resist film leads to an undesirably reduced throughput. Due to a need for higher sensitivity, chemically amplified resist compositions are contemplated.

As the feature size is reduced, image blurs due to acid diffusion become a problem (see Non-Patent Document 1). To insure resolution for fine patterns with a size of 45 nm et seq., not only an improvement in dissolution contrast is requisite, but control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having polymerizable olefin. Patent Documents 1 to 3 disclose sulfonium salts having polymerizable olefin capable of generating a sulfonic acid and similar iodonium salts. Patent Document 1 discloses a polymer-bound sulfonium salt in which sulfonic acid is directly attached to the backbone.

The EB writing of a resist film encounters a problem that the point of writing is shifted by electrostatic charges on the resist film. It is proposed to overlay the resist film with an antistatic film to prevent the resist film from being charged. Undesirably coating of the antistatic film adds to the cost of the overall process.

It was impossible to use metal-containing materials as the photoresist material for the semiconductor lithography because of a possible malfunction of semiconductor devices. However, it is known in the application other than the semiconductor, for example, as the resist material for forming color filters for LCD (see Patent Document 2), to use a metal-containing (meth)acrylate as a copolymerizable monomer. The metal-containing (meth)acrylate is typically contemplated as the antifouling paint for ships. Patent Document 3 shows many examples such as zinc acrylate, copper acrylate and magnesium acrylate.

### CITATION LIST

Patent Document 1: JP-A 2006-178317
Patent Document 2: JP-A 2009-237150
Patent Document 3: JP-A 2001-329228
Non-Patent Document 1: SPIE Vol. 5039 μl (2003)
Non-Patent Document 2: SPIE Vol. 6520 p65203L-1 (2007)

### DISCLOSURE OF INVENTION

An object of the invention is to provide a chemically amplified positive resist composition which has both high resolution and sensitivity, forms a pattern with a satisfactory profile and minimal LER after exposure and development, and has an electro-conductive function to prevent charging during image writing; and a patterning process using the same.

In one aspect, the invention provides a resist composition comprising a polymer having copolymerized together recurring units of acid labile group-substituted (meth)acrylic acid, styrenecarboxylic acid or vinylnaphthalenecarboxylic acid and/or recurring units having an acid labile group-substituted phenolic hydroxyl group, and recurring units of a magnesium, copper, zinc or cesium salt of (meth)acrylic acid, styrenecarboxylic acid or vinylnaphthalenecarboxylic acid.

Specifically, the polymer comprises recurring units (a1) of acid labile group-substituted (meth)acrylic acid, styrenecarboxylic acid or vinylnaphthalenecarboxylic acid and/or recurring units (a2) having an acid labile group-substituted phenolic hydroxyl group, and recurring units (b1) of a magnesium, copper or zinc salt of (meth)acrylic acid, styrenecarboxylic acid or vinylnaphthalenecarboxylic acid and/or recurring units (b2) of a cesium salt of (meth)acrylic acid, styrenecarboxylic acid or vinylnaphthalenecarboxylic acid, as represented by the general formula (1).

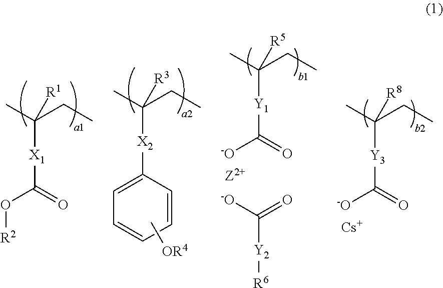

Herein R¹, R³, R⁵, and R⁸ are each independently hydrogen or methyl, R² and R⁴ each are an acid labile group, X₁ is a single bond, a C₁-C₁₂ linking group having at least one of ester moiety, lactone ring, phenylene moiety or naphthylene moiety, a phenylene group, or a naphthylene group, X₂ is a single bond or an ester group, Y₁, Y₂ and Y₃ are each independently a single bond, a C₆-C₁₂ arylene group, or —C(═O)—O—R⁷—, R⁷ is a straight, branched or cyclic C₁-C₁₀ alkylene group or C₆-C₁₂ arylene group, which may contain an ether, ester, lactone ring, hydroxyl, amino, cyano moiety, double bond, or triple bond, R⁶ is hydrogen, a straight, branched or cyclic C₁-C₁₀ alkyl group, C₂-C₁₆ alkenyl group, or C₂-C₁₆ alkynyl group, which may contain an ether, ester, amino, amide, sulfonic acid ester, halogen, cyano, nitro, carbonate, carbamate, thiol, sulfide, thioketone moiety or hetero-aromatic ring,

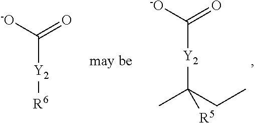

Z is magnesium, copper or zinc, a1, a2, b1 and b2 are numbers in the range: 0≦a1≦0.9, 0≦a2≦0.9, 0≦a1+a2<1, 0≦b1≦0.8, 0≦b2≦0.8, and 0<b1+b2≦0.8.

Also preferably, in addition to recurring units (a1), (a2), (b1) and (b2), the polymer may comprise recurring units (c1), (c2) or (c3) of a sulfonium salt having the general formula (2).

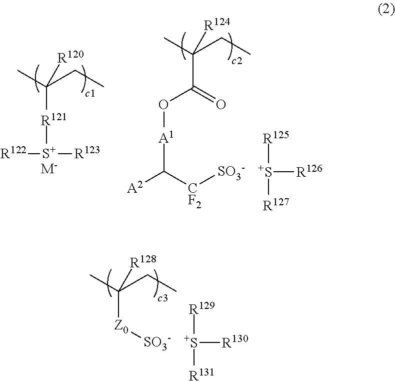

Herein R¹²⁰, R¹²⁴, and R¹²⁸ each are hydrogen or methyl, R¹²¹ is a single bond, phenylene, —O—R—, or —C(═O)—Y—R—, Y is oxygen or NH, R is a straight, branched or cyclic C₁-C₆ alkylene group, C₃-C₁₀ alkenylene or phenylene group, which may contain a carbonyl, ester, ether or hydroxyl moiety, R¹²², R¹²³, R¹²⁵, R¹²⁶, R¹²⁷, R¹²⁹, R¹³⁰, and R¹³¹ are each independently a straight, branched or cyclic C₁-C₁₂ alkyl group which may contain a carbonyl, ester or ether moiety, or a C₆-C₁₂ aryl, C₇-C₂₀ aralkyl, or thiophenyl group, A¹ is a single bond, -A⁰—C(═O)—O— or -A⁰-O—C(═O)—, A⁰ is a straight, branched or cyclic C₁-C₁₂ alkylene group which may contain a carbonyl, ester or ether moiety, A² is hydrogen or CF₃, Z₀ is a single bond, methylene, ethylene, phenylene, fluorophenylene, —O—R¹³²—, or —C(═O)—Z₁—R¹³²—, Z₁ is oxygen or NH, R¹³² is a straight, branched or cyclic C₁-C₆ alkylene group, alkenylene, phenylene, fluorophenylene, or trifluoromethyl-substituted phenylene group, which may contain a carbonyl, ester, ether or hydroxyl moiety, M⁻ is a non-nucleophilic counter ion, c1, c2 and c3 are in the range of 0≦c1≦0.3, 0≦c2≦0.3, 0≦c3≦0.3, and 0<c1+c2+c3≦0.3.

In a preferred embodiment, the polymer has further copolymerized therein recurring units having an adhesive group. The adhesive group is selected from among phenolic hydroxyl, hydroxyl other than phenolic hydroxyl, carboxyl, lactone ring, carbonate, thiocarbonate, carbonyl, cyclic acetal, ether, ester, sulfonic acid ester, cyano, amide, and —O—C(═O)-G- wherein G is sulfur or NH.

Typically the resist composition is a chemically amplified positive resist composition. Then the resist composition may further comprise at least one component selected from among an organic solvent, a dissolution inhibitor, an acid generator, a basic compound, and a surfactant.

In another aspect, the invention provides a pattern forming process comprising the steps of coating the resist composition defined above onto a substrate, baking, exposing to high-energy radiation, and developing with a developer. Typically, the high-energy radiation is EUV radiation having a wavelength of 3 to 15 nm or an electron beam at an accelerating voltage of 1 to 150 keV.

### ADVANTAGEOUS EFFECTS OF INVENTION

The resist composition has many advantages including a significantly high contrast of alkaline dissolution rate before and after exposure, a high sensitivity, a high resolution, a satisfactory pattern profile after exposure, a controlled rate of acid diffusion, and a minimal LER. The resist composition, typically chemically amplified positive resist composition is suited as the micropatterning material for VLSIs and photomasks, and the patterning material in the EB and EUV lithography.

### DESCRIPTION OF EMBODIMENTS

The singular forms “a,” “an” and “the” include plural referents unless the context clearly dictates otherwise. “Optional” or “optionally” means that the subsequently described event or circumstance may or may not occur, and that the description includes instances where the event occurs and instances where it does not. As used herein, the notation (Cₙ-Cₘ) means a group containing from n to m carbon atoms per group. The broken line depicted in a chemical formula denotes a valence bond.

The abbreviations and acronyms have the following meaning.

UV: ultraviolet radiation

DUV: deep ultraviolet

EUV: extreme ultraviolet

EB: electron beam

Mw: weight average molecular weight

Mn: number average molecular weight

Mw/Mn: molecular weight distribution or dispersity

GPC: gel permeation chromatography

PEB: post-exposure bake

LER: line edge roughness

LWR: line width roughness

While the effort to reduce the pattern rule is in rapid progress to meet the demand for higher integration density and operating speed of LSIs as alluded to previously, there is a need for a resist composition which has a high resolution and a high sensitivity and forms a pattern with a satisfactory profile and minimal LER through exposure and development.

Seeking for a resist material having a high resolution, high sensitivity and minimal LER, the inventor has found that a polymer comprising recurring units having an acid labile group and recurring units of a magnesium, copper, zinc or cesium salt of (meth)acrylic acid, styrenecarboxylic acid or vinylnaphthalenecarboxylic acid, and preferably recurring units of a sulfonium salt having polymerizable olefin is quite effective as the base resin in a resist composition, typically chemically amplified positive resist composition.

More particularly, when a polymer obtained from copolymerization of a monomer of acid labile group-substituted (meth)acrylic acid, styrenecarboxylic acid or vinylnaphthalenecarboxylic acid and/or a monomer having an acid labile group-substituted phenolic hydroxyl group with a monomer of a magnesium, copper, zinc or cesium salt of (meth)acrylic acid, styrenecarboxylic acid or vinylnaphthalenecarboxylic acid and preferably further with a monomer of a sulfonium salt having polymerizable olefin is used as the base resin, there is formulated a resist composition, typically chemically amplified positive resist composition which has many advantages including controlled acid diffusion, high resolution, high sensitivity, a satisfactory pattern profile after exposure, and minimal LER. In addition, the resist composition is effective for preventing electrostatic charges during EB image writing. The resist composition, typically chemically amplified positive resist composition is thus suited as the micropatterning material for the fabrication of VLSIs and photomasks.

Specifically, one embodiment of the invention is a resist composition comprising a polymer having copolymerized together recurring units of acid labile group-substituted (meth)acrylic acid, styrenecarboxylic acid or vinylnaphthalenecarboxylic acid and/or recurring units having an acid labile group-substituted phenolic hydroxyl group, and recurring units of a magnesium, copper, zinc or cesium salt of (meth)acrylic acid, styrenecarboxylic acid or vinylnaphthalenecarboxylic acid.

The polymer having copolymerized together recurring units of acid labile group-substituted (meth)acrylic acid, styrenecarboxylic acid or vinylnaphthalenecarboxylic acid and/or recurring units having an acid labile group-substituted phenolic hydroxyl group, and recurring units of a magnesium, copper, zinc or cesium salt of (meth)acrylic acid, styrenecarboxylic acid or vinylnaphthalenecarboxylic acid may be represented by the general formula (1).

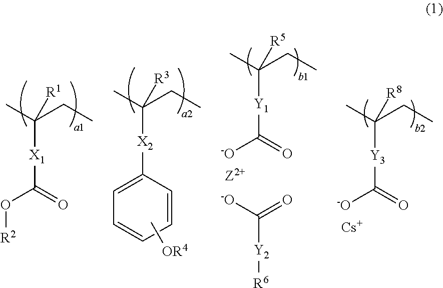

Herein R¹, R³, R⁵, and R⁸ are each independently hydrogen or methyl. R² and R⁴ each are an acid labile group. X₁ is a single bond, a C₁-C₁₂ linking group having one or more ester moiety, lactone ring, phenylene moiety or naphthylene moiety, a phenylene group, or a naphthylene group. X₂ is a single bond or an ester group. Y₁, Y₂ and Y₃ are each independently a single bond, a C₆-C₁₂ arylene group, or —C(═O)—O—R⁷— wherein R⁸ is a straight, branched or cyclic C₁-C₁₀ alkylene group or C₆-C₁₂ arylene group, which may contain an ether, ester, lactone ring, hydroxyl, amino, cyano moiety, double bond, or triple bond. R⁶ is hydrogen, a straight, branched or cyclic C₁-C₁₀ alkyl group, C₂-C₁₆ alkenyl group, or C₂-C₁₆ alkynyl group, which may contain an ether, ester, amino, amide, sulfonic acid ester, halogen, cyano, nitro, carbonate, carbamate, thiol, sulfide, thioketone moiety or hetero-aromatic ring.

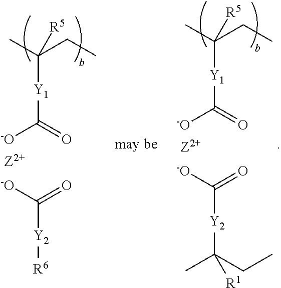

Z is magnesium, copper or zinc. The subscripts a1, a2, b1 and b2 are numbers in the range: 0≦a1≦0.9, 0≦a2≦0.9, 0≦a1+a2<1, 0≦b1≦0.8, 0≦b2≦0.8, and 0<b1+b2≦0.8.

The magnesium, copper, zinc or cesium salt of carboxylic acid, if a sulfonic acid stronger than the carboxylic acid is present, converts to a magnesium, copper, zinc or cesium salt of sulfonic acid through an ion exchange. The magnesium, copper, zinc or cesium salt of carboxylic acid functions as a quencher in that an ion exchange takes place between the sulfonic acid serving as a catalyst for deprotection of an acid labile group and a magnesium, copper, zinc or cesium ion of carboxylic acid. Since magnesium, copper or zinc is a divalent positive ion, one molecule can trap two molecules of sulfonic acid. Since cesium is a monovalent positive ion, one molecule can trap one molecule of sulfonic acid. These metal salts are more effective for suppressing acid diffusion than the amine quencher.

When the magnesium, copper, zinc or cesium salt of carboxylic acid is separately added to a resist composition, it functions as a quencher. However, once the magnesium, copper, zinc or cesium salt of carboxylic acid is blended in a resist solution, the salt agglomerates in the solution. The quencher agglomerated portions, where deprotection reaction does not take place, can cause defects such as bridge defects and scum and increase edge roughness.

To prevent agglomeration of the magnesium, copper, zinc or cesium salt of carboxylic acid, the method of binding the salt with a polymer is effective. The binding of the magnesium, copper, zinc or cesium salt of carboxylic acid with a polymer may be achieved by copolymerizing the salt with a monomer of acid labile group-substituted (meth)acrylic acid, styrenecarboxylic acid or vinylnaphthalenecarboxylic acid and/or a monomer having an acid labile group-substituted phenolic hydroxyl group.

Examples of suitable monomers from which recurring units (b1) of the magnesium, copper or zinc salt of carboxylic acid in formula (1) are derived are shown below.

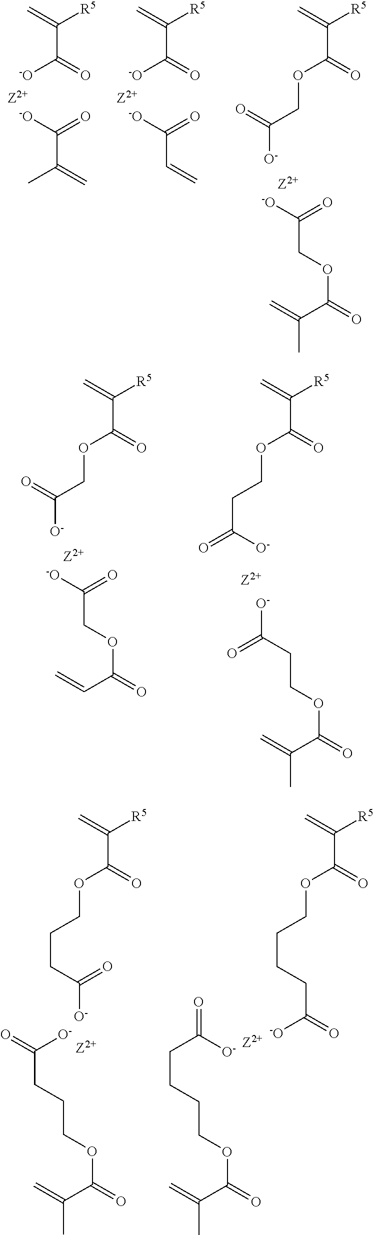

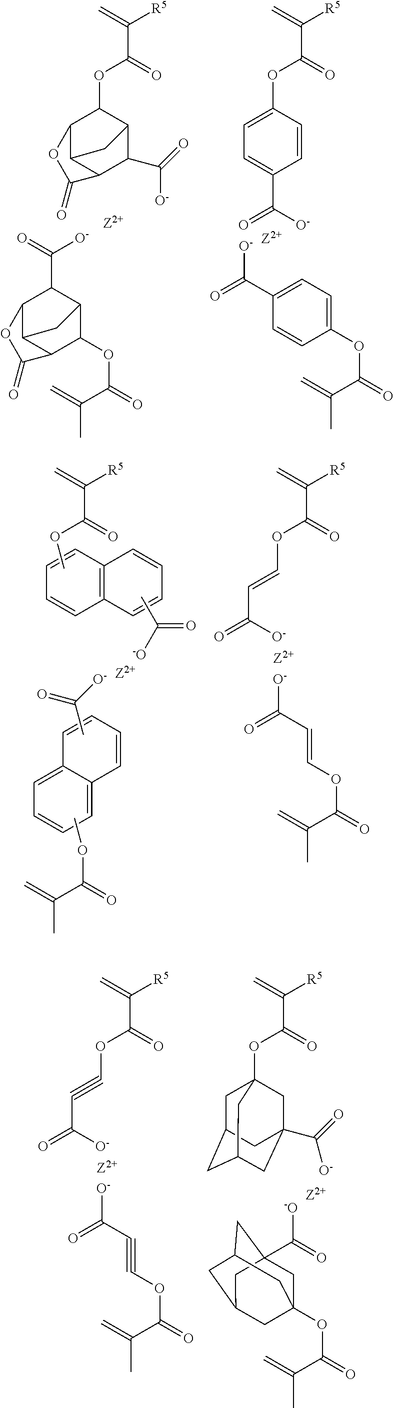

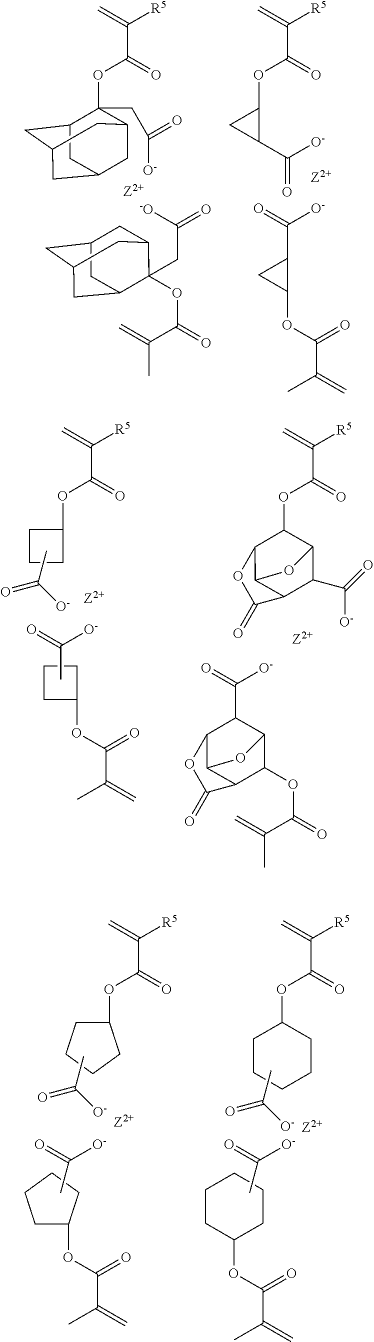

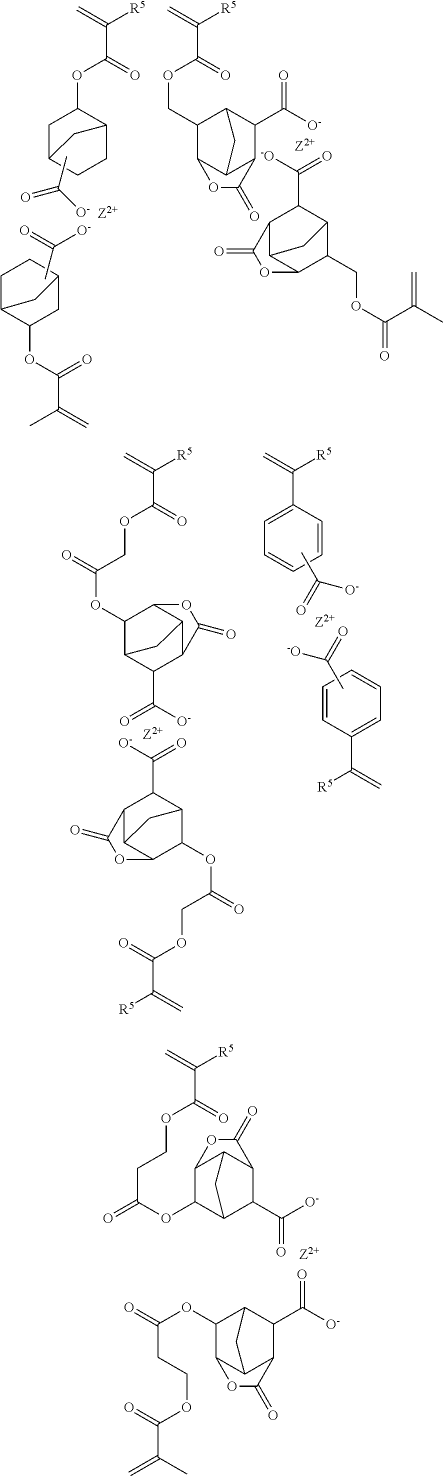

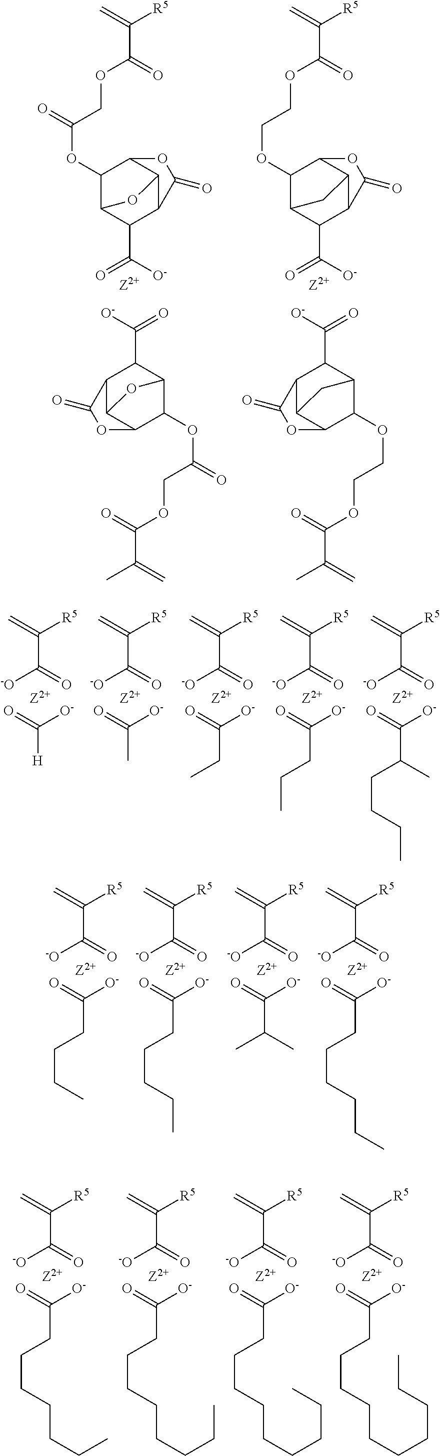

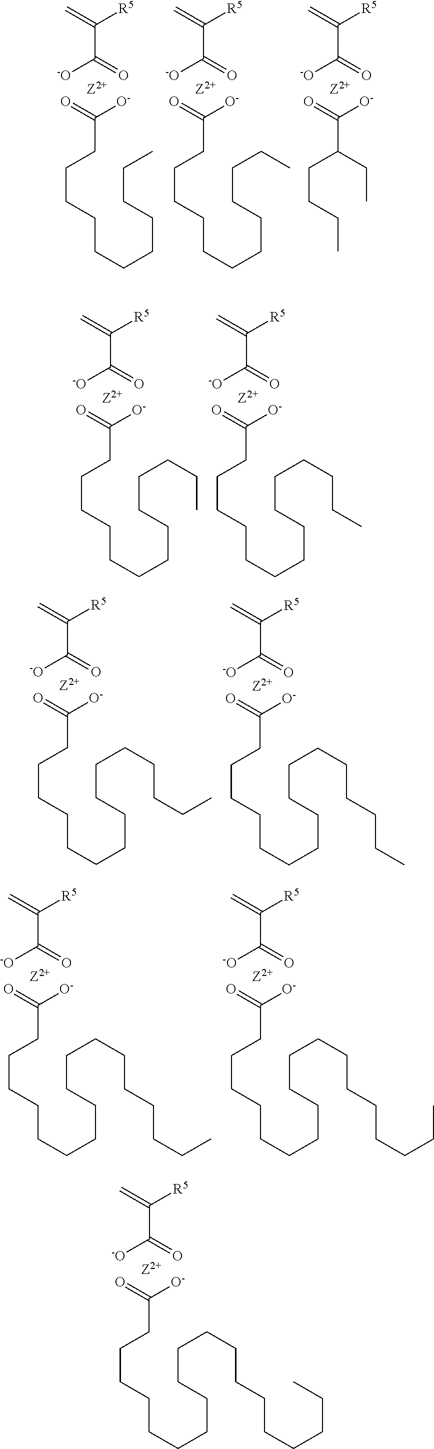

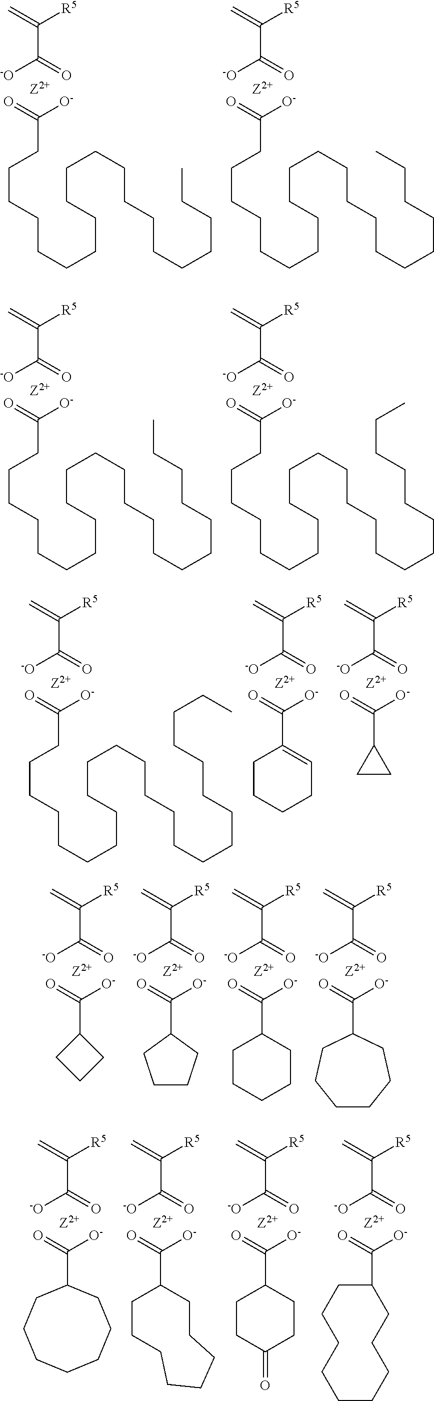

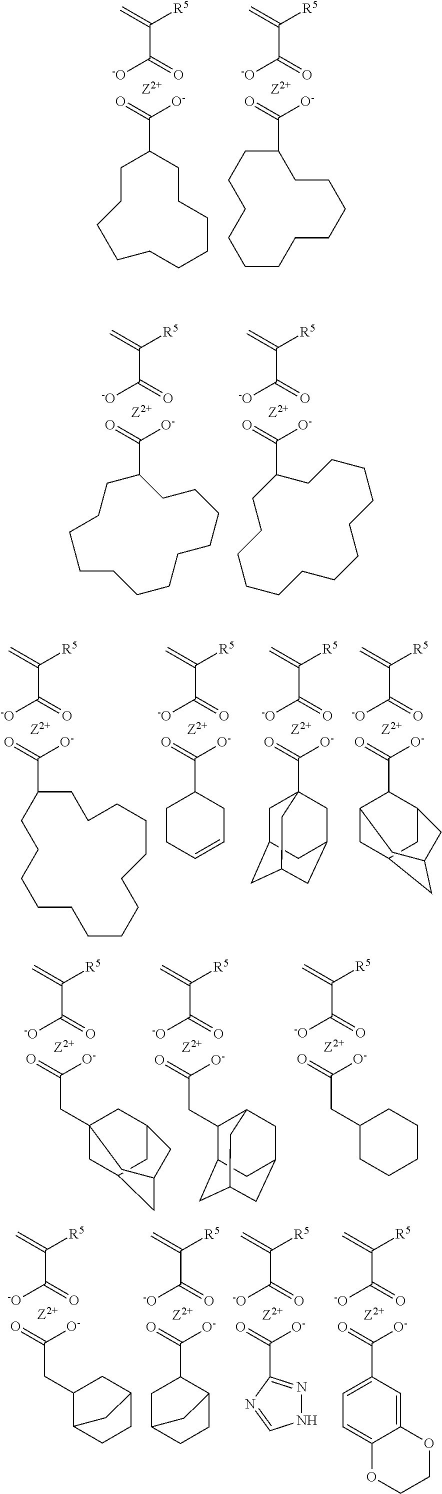

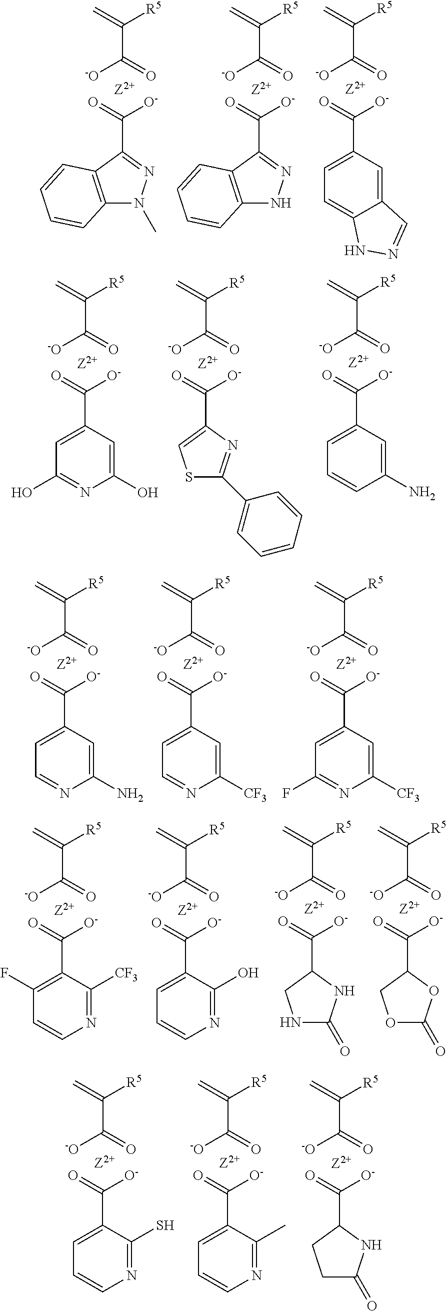

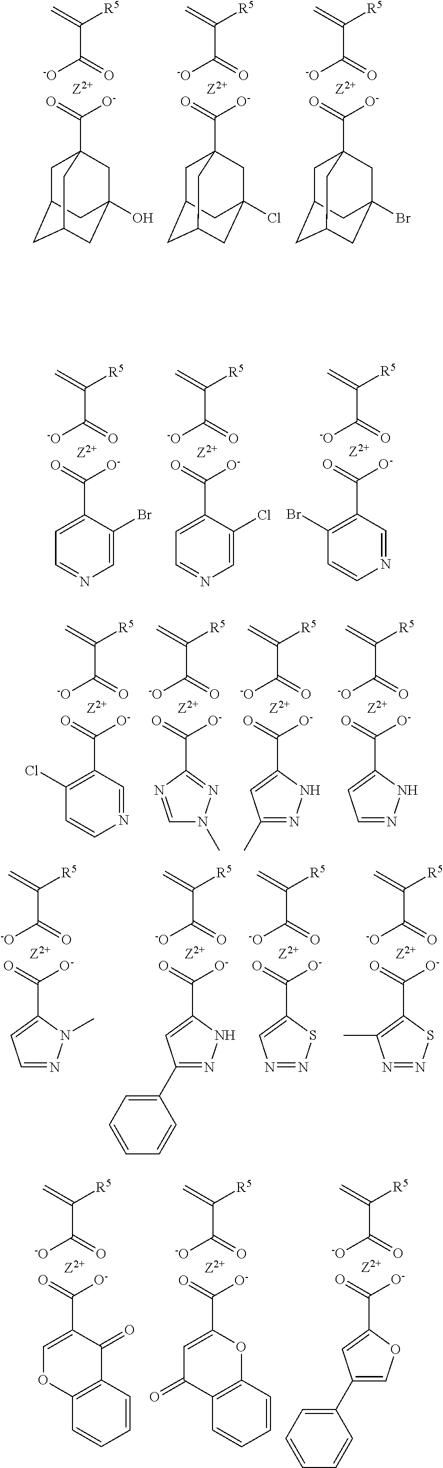

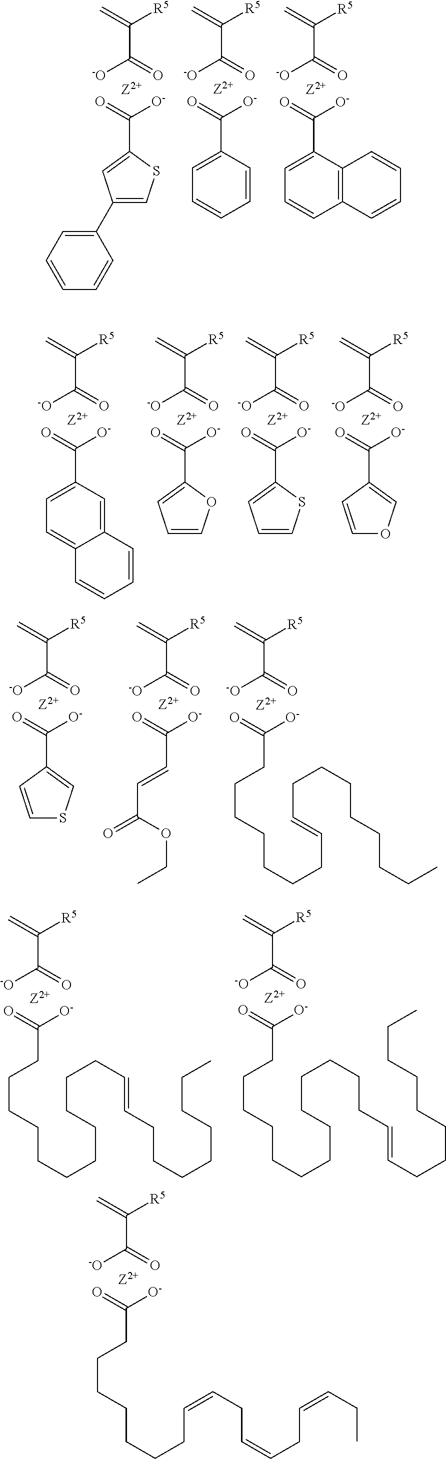

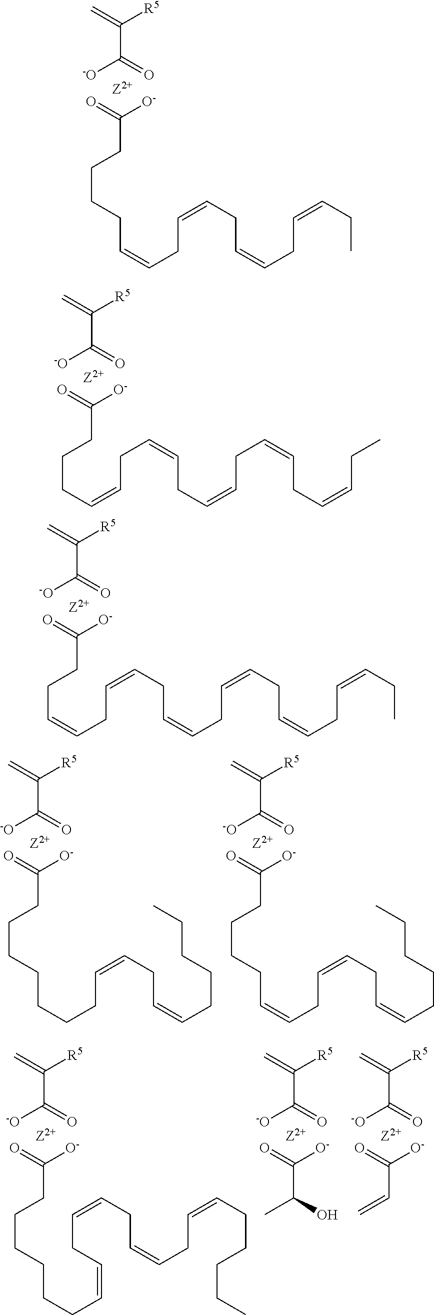

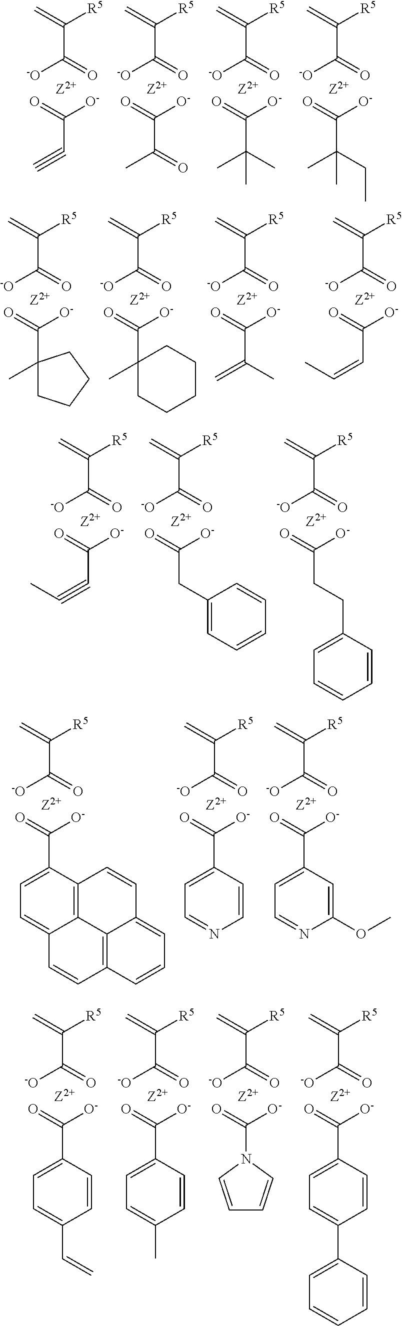

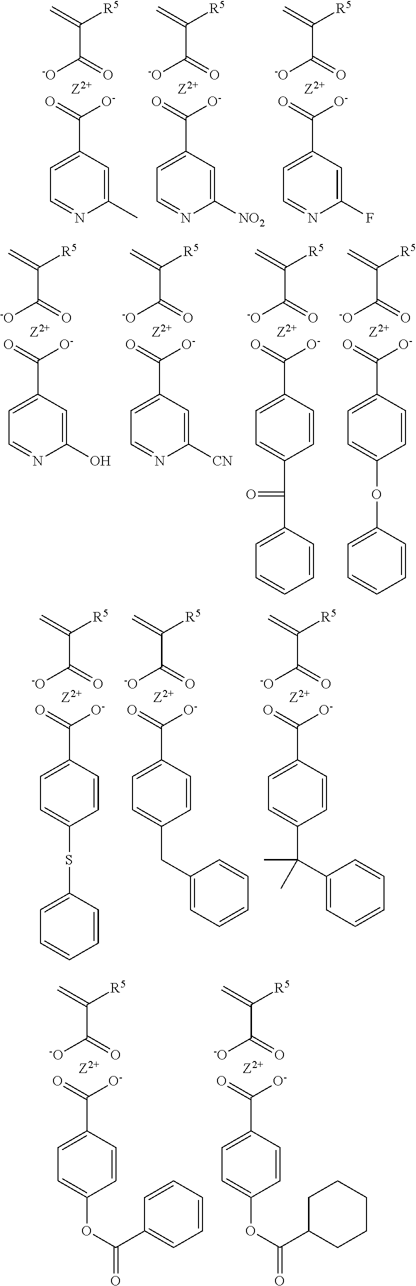

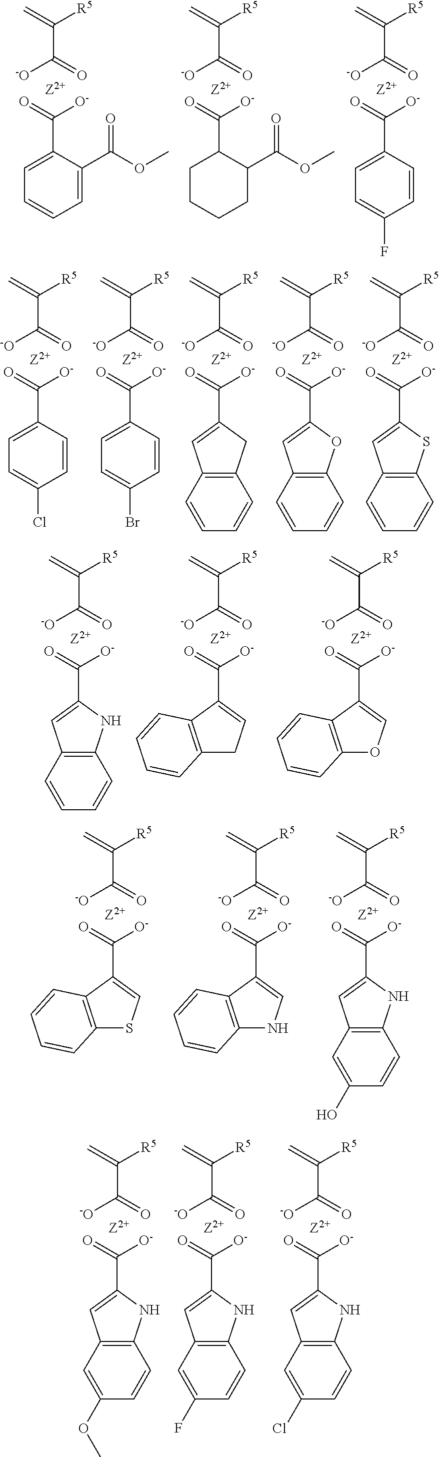

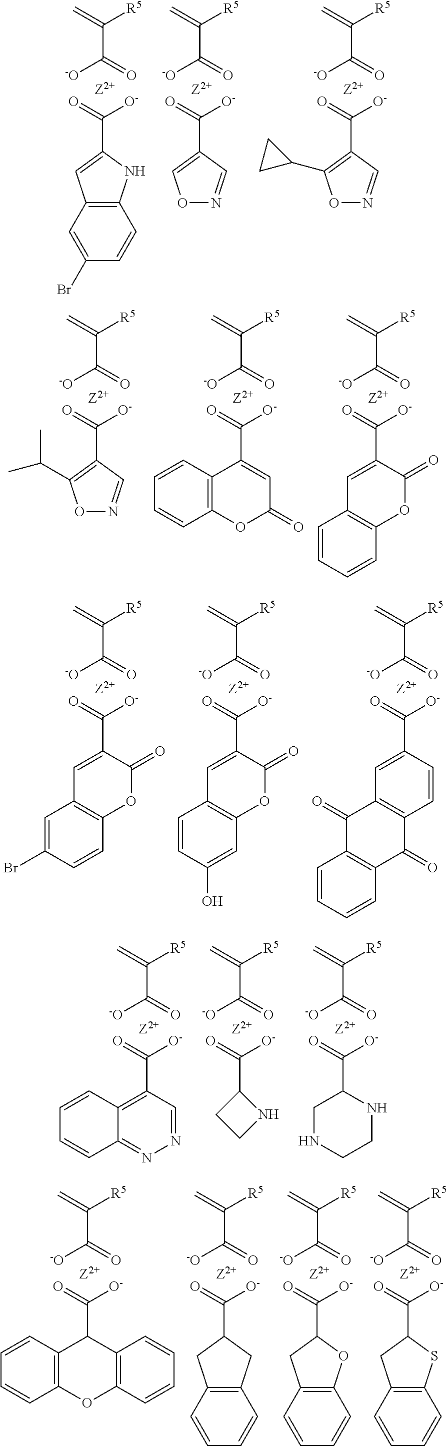

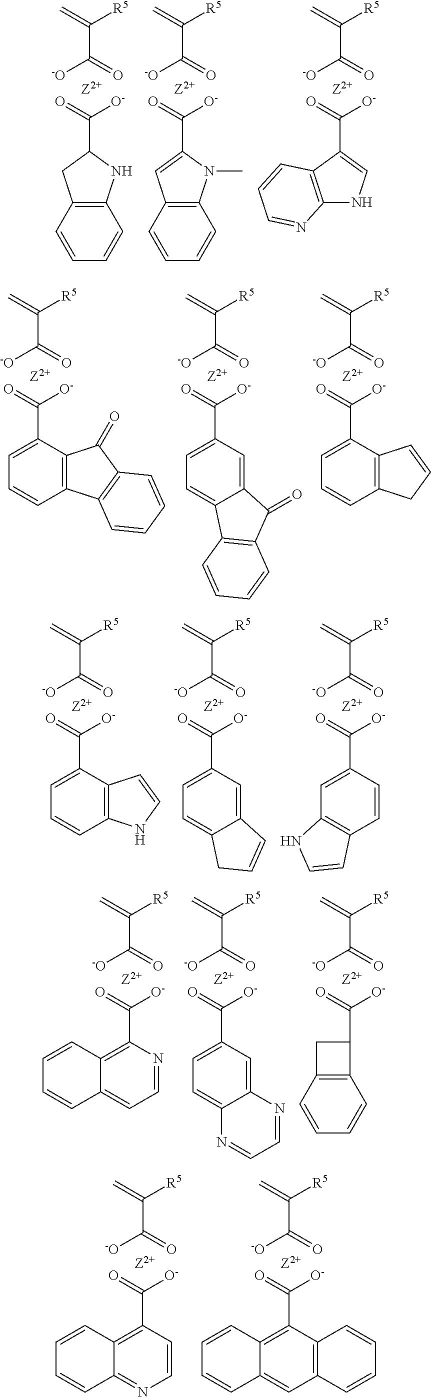

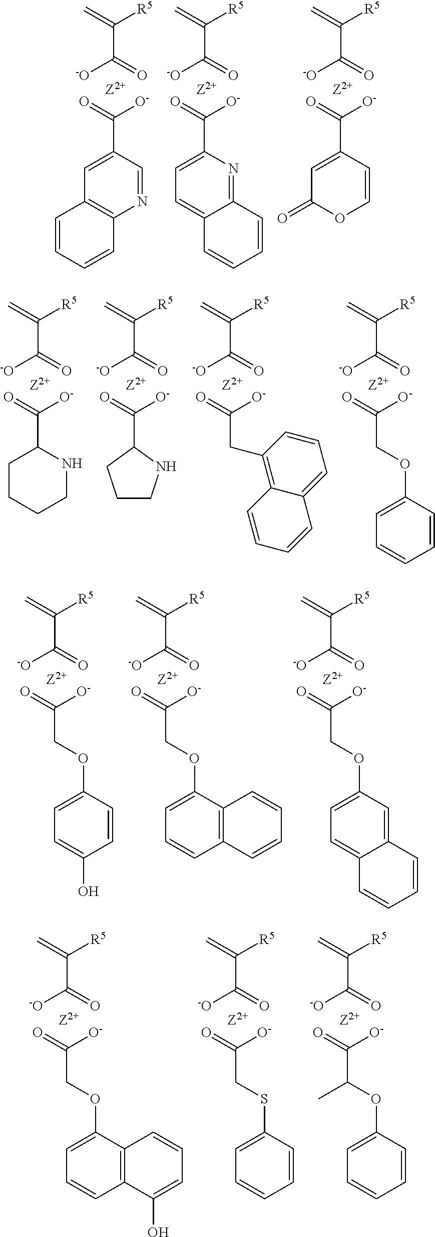

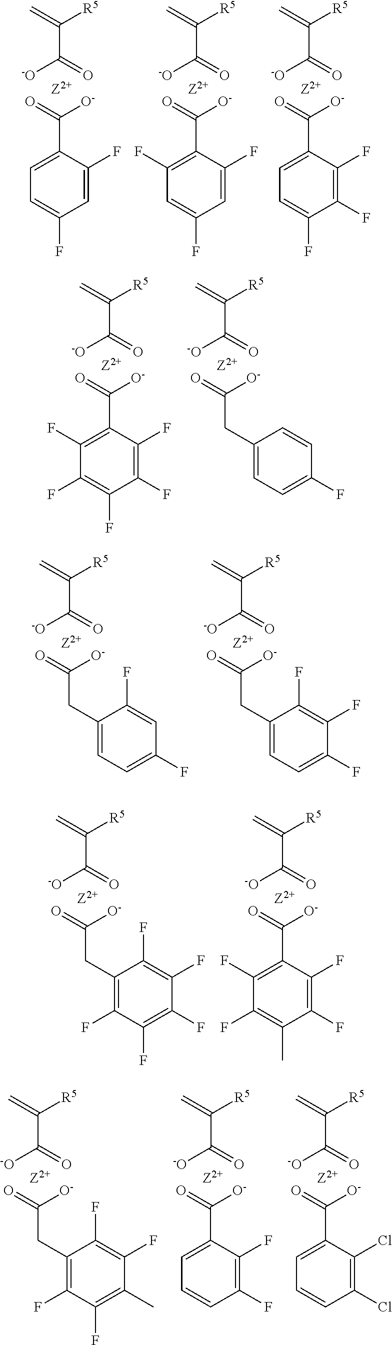

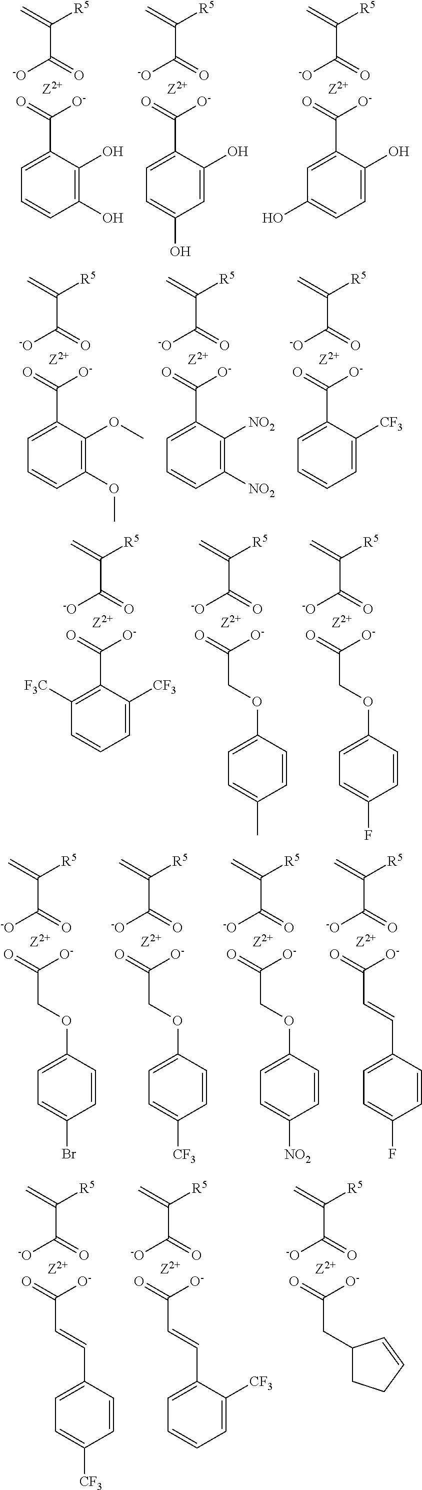

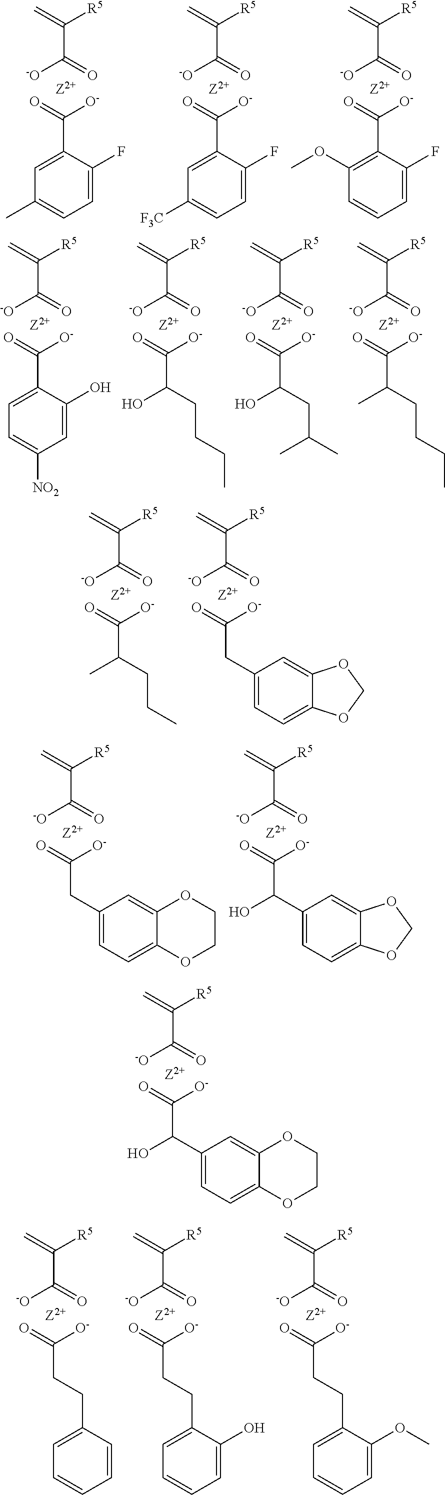

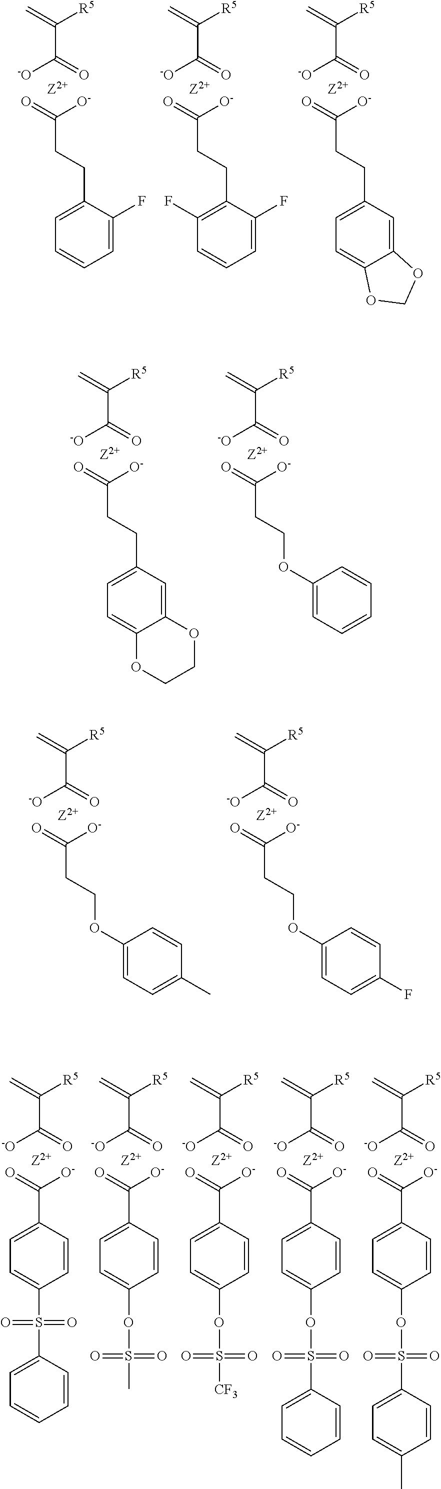

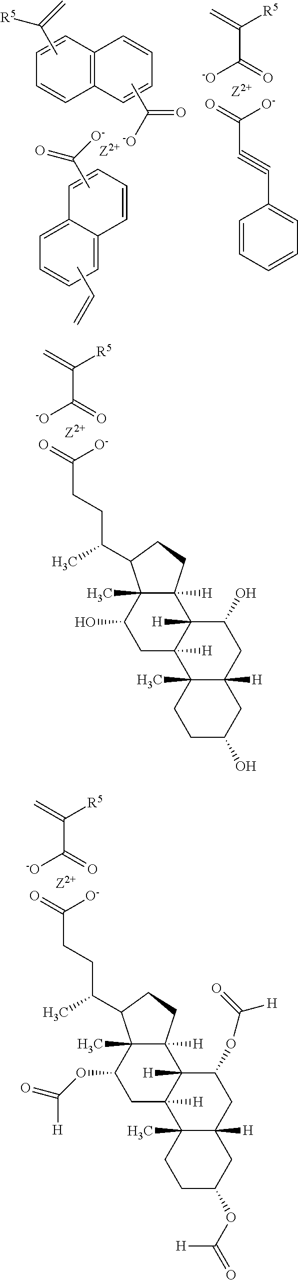

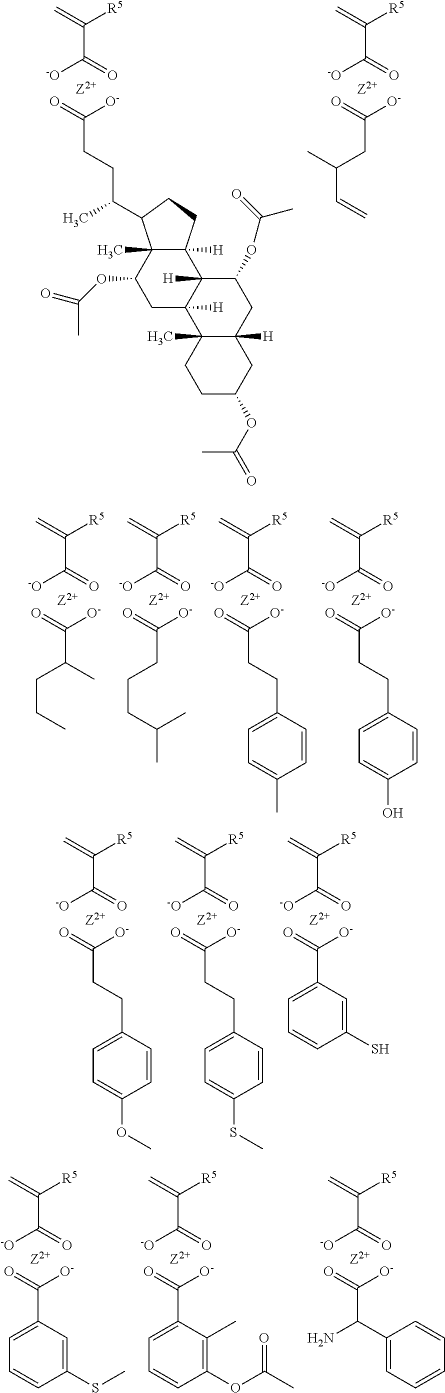

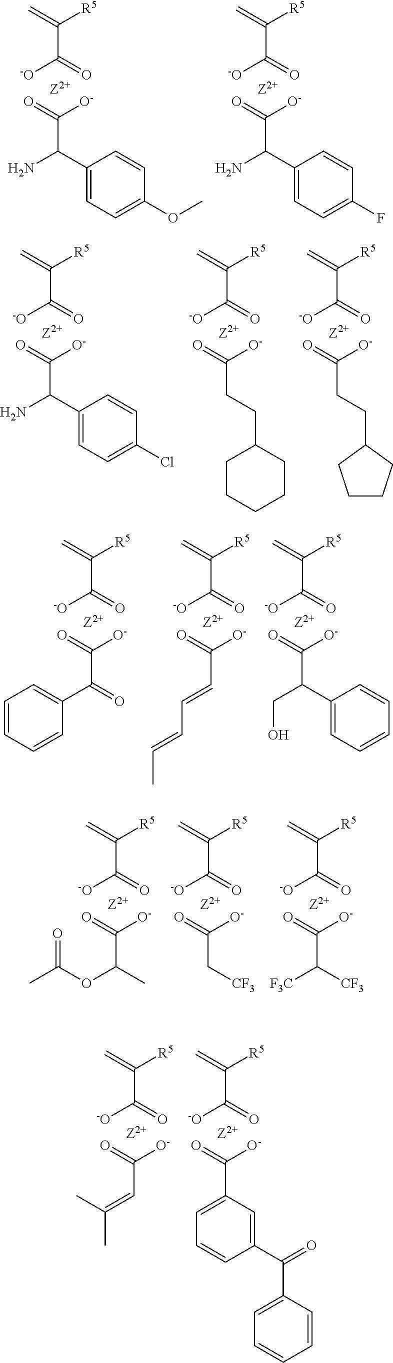

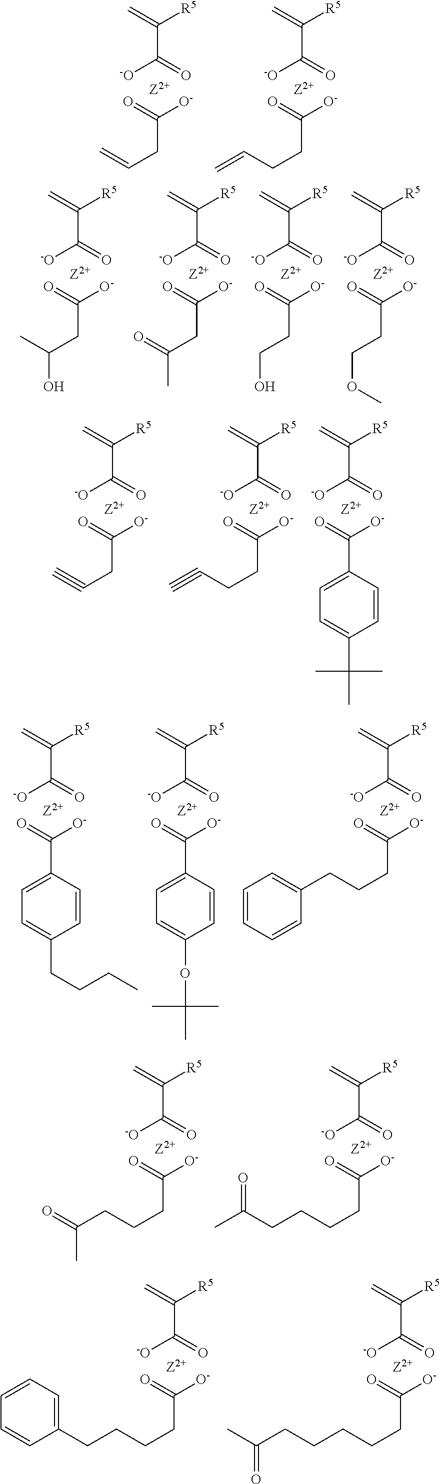

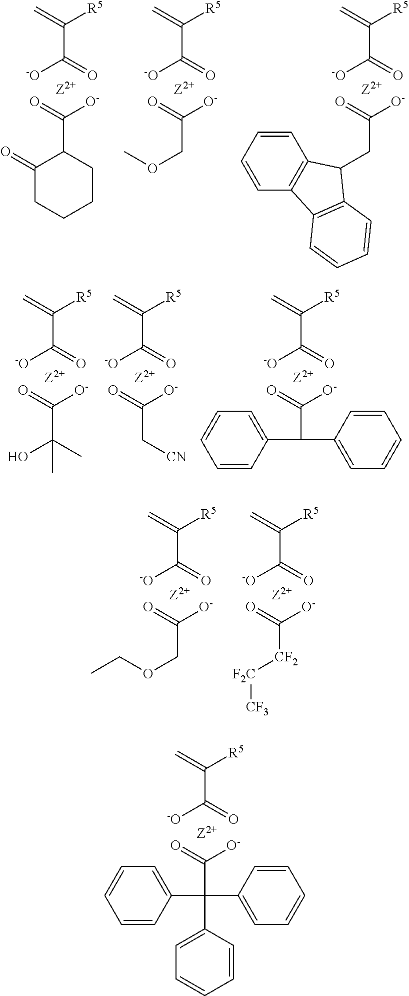

Herein R⁵ and Z are as defined above.

Examples of suitable monomers from which recurring units (b2) of the cesium salt of carboxylic acid in formula (1) are derived are shown below.

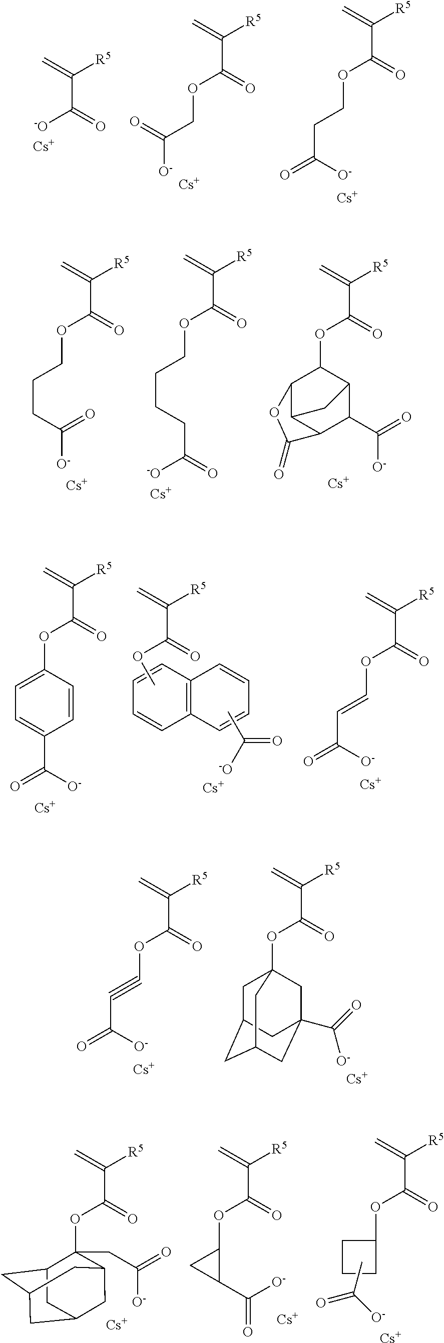

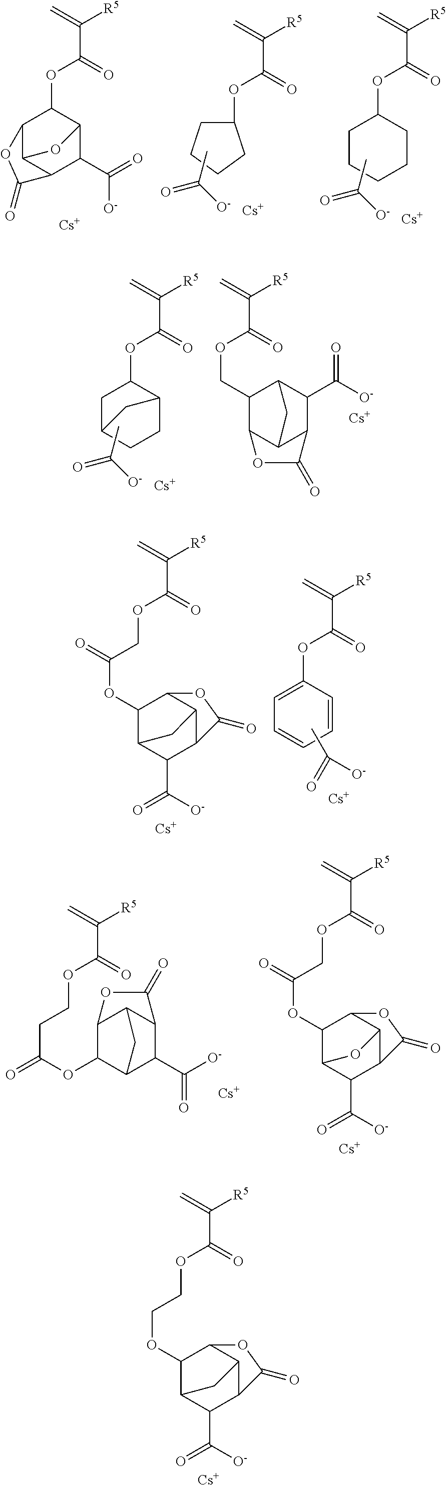

Herein R⁵ is as defined above.

Magnesium, copper and zinc which are generally divalent form salts with two molecules of carboxylic acid. While the two molecules of carboxylic acid may be the same or different, at least one must be (meth)acrylic acid, styrenecarboxylic acid or vinylnaphthalenecarboxylic acid having a polymerizable olefin. The other carboxylic acid need not have a polymerizable olefin and may be other than the above-mentioned combination.

In addition to the recurring units (a1), (a2), (b1) and (b2), the polymer may further comprise recurring units (c1), (c2) or (c3) of a sulfonium salt having the general formula (2).

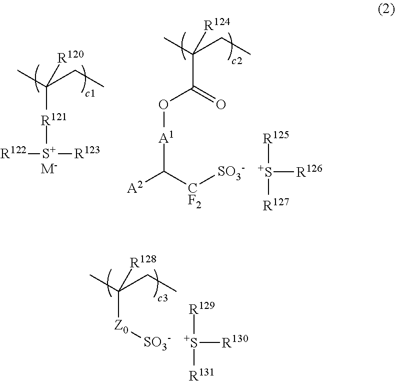

Herein R¹²⁰, R¹²⁴, and R¹²⁸ each are hydrogen or methyl. R¹²¹ is a single bond, phenylene, —O—R—, or —C(═O)—Y—R— wherein Y is oxygen or NH, and R is a straight, branched or cyclic C₁-C₆ alkylene group, C₃-C₁₀ alkenylene or phenylene group, which may contain a carbonyl (—CO—), ester (—COO—), ether (—O—) or hydroxyl moiety. R¹²², R¹²³, R¹²⁵, R¹²⁶, R¹²⁷, R¹²⁹ R¹³⁰, and R¹³¹ are each independently a straight, branched or cyclic C₁-C₁₂ alkyl group which may contain a carbonyl, ester or ether moiety, or a C₆-C₁₂ aryl, C₇-C₂₀ aralkyl, or thiophenyl group. A¹ is a single bond, -A⁰-C(═O)—O— or -A⁰-O—C(═O)— wherein A⁰ is a straight, branched or cyclic C₁-C₁₂ alkylene group which may contain a carbonyl, ester or ether moiety. A² is hydrogen or CF₃. Z₀ is a single bond, methylene, ethylene, phenylene, fluorophenylene, —O—R¹³²—, or —C(═O)—Z₁—R¹³²— wherein Z₁ is oxygen or NH, and R¹³² is a straight, branched or cyclic C₁-C₆ alkylene group, alkenylene, phenylene, fluorophenylene, or trifluoromethyl-substituted phenylene group, which may contain a carbonyl, ester, ether or hydroxyl moiety. M⁻ is a non-nucleophilic counter ion, c1, c2 and c3 are in the range of 0≦c1≦0.3, 0≦c2≦0.3, 0≦c3≦0.3, and 0≦c1+c2+c3≦0.3.

The binding of the acid generator with the polymer is effective for shortening the distance of acid diffusion and reducing edge roughness. In the embodiment wherein the polymer having recurring units (c1), (c2) or (c3) of a sulfonium salt copolymerized therein is used, the addition of a separate acid generator may be omitted.

Now that the resist composition is based on a polymer comprising acid labile group-bearing recurring units (a1) and/or (a2) and magnesium, copper or zinc-bearing recurring units (b1) and/or cesium-bearing recurring units (b2), the resist composition is effective for controlling acid diffusion, improving contrast, improving electric conductivity and hence, preventing electrostatic charging during image writing. Particularly when exposed to short-wavelength high-energy radiation and EB, the resist composition is effective for forming a fine size pattern with a high resolution, minimal LER and satisfactory profile. When the polymer further comprising recurring units (c1), (c2) or (c3), that is, acid generator-binding polymer is used, a pattern with a very high accuracy can be formed because the bound acid generator generates an acid upon exposure, with which the acid labile group in recurring units (a1) or (a2) is eliminated so that the exposed region of resist may turn soluble in developer.

Accordingly, the resist composition has many advantages including a high dissolution contrast, a high resolution, a high sensitivity, exposure latitude, process adaptability, a good pattern profile after exposure, and minimized LER. Because of these advantages, the resist composition is fully viable in practice and best suited as the micropatterning resist material for the fabrication of VLSIs. The resist composition, typically chemically amplified positive resist composition is used not only in the lithography for forming semiconductor circuits, but also in the formation of mask circuit patterns, micromachines, and thin-film magnetic head circuits.

Of the recurring units in the polymer, the acid labile group-bearing recurring units, that is, recurring units (a1) in formula (1) are units in which the hydrogen atom of carboxyl group, especially the hydrogen atom of hydroxyl group on (meth)acrylate is substituted by an acid labile group. Examples of the monomer from which the acid labile group-bearing recurring units are derived are given below.

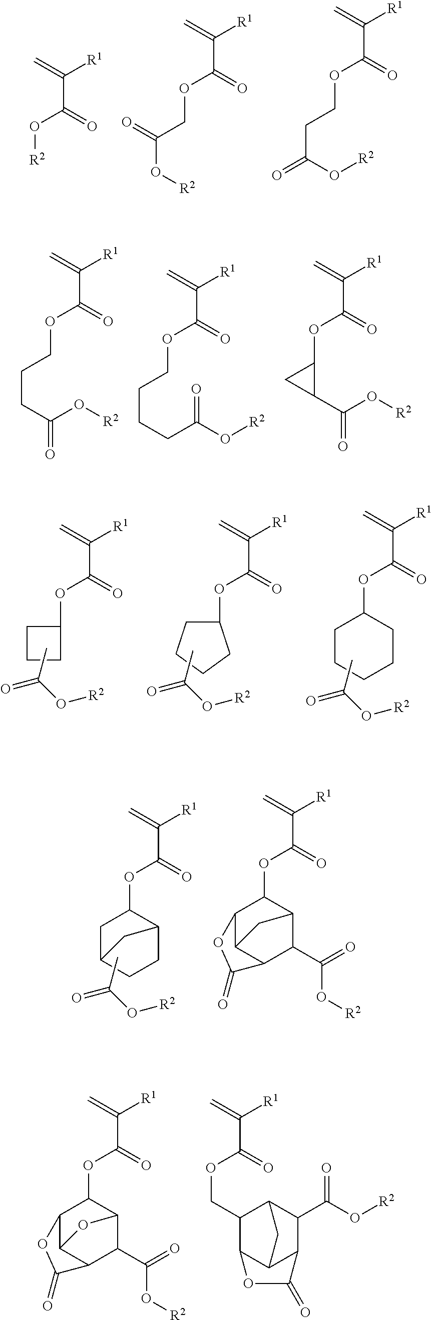

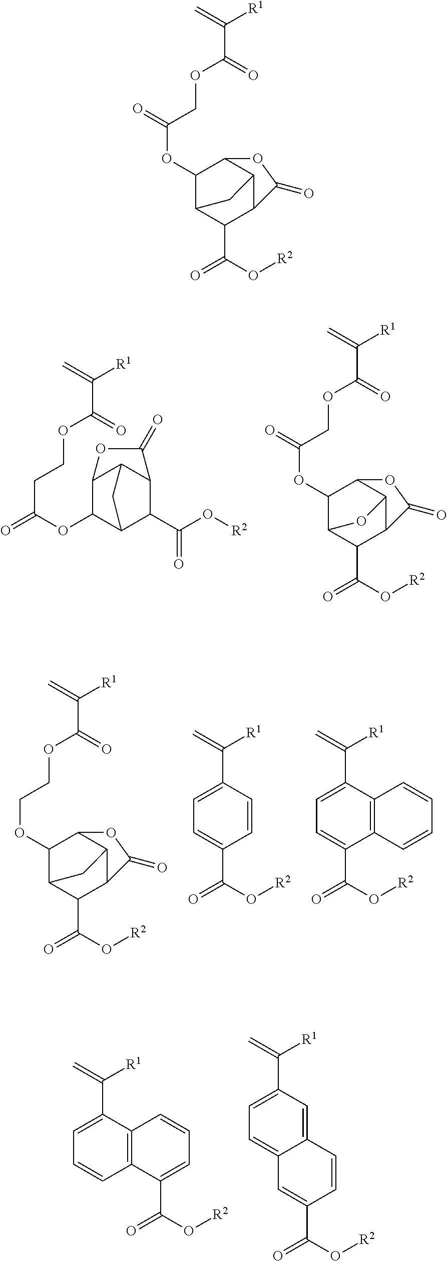

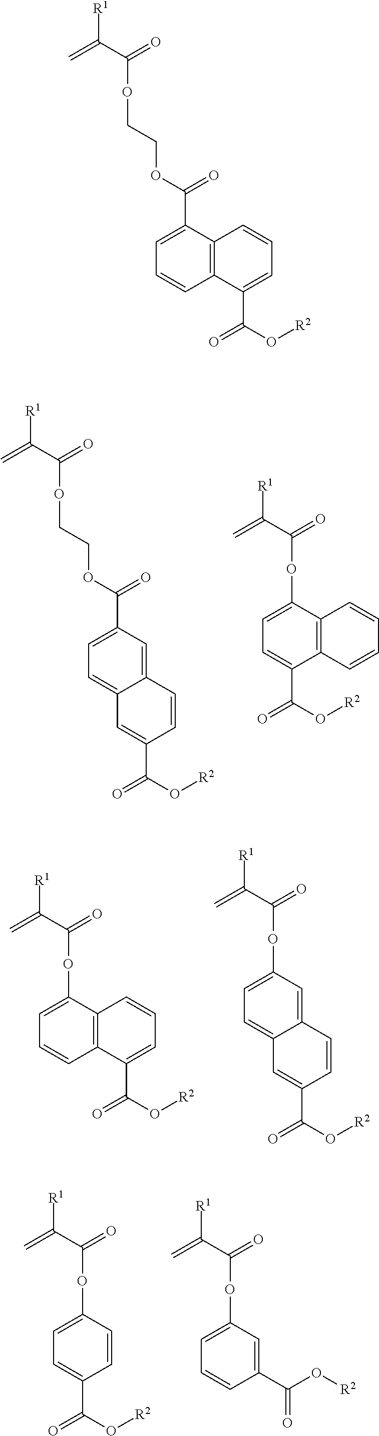

Herein R¹ and R² are as defined above.

The other acid labile group-bearing recurring units, that is, recurring units (a2) in formula (1) are units in which the hydrogen atom of phenolic hydroxyl group, especially the hydrogen atom of hydroxyl group on hydroxystyrene or hydroxyphenyl (meth)acrylate is substituted by an acid labile group. Examples of the monomer from which these units are derived are given below.

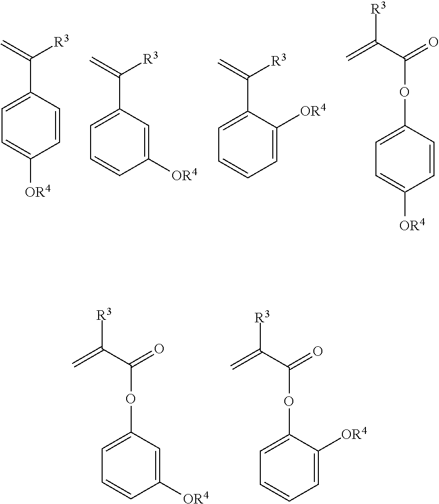

Herein R³ and R⁴ are as defined above.

The acid labile group represented by R² and R⁴ may be selected from a variety of such groups. The acid labile groups may be the same or different and preferably include groups of the following formulae (A-1) to (A-3).

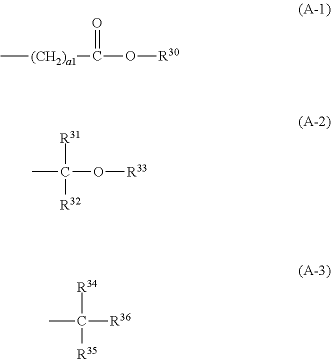

In formula (A-1), R³⁰ is a tertiary alkyl group of 4 to 20 carbon atoms, preferably 4 to 15 carbon atoms, a trialkylsilyl group in which each alkyl moiety has 1 to 6 carbon atoms, an oxoalkyl group of 4 to 20 carbon atoms, or a group of formula (A-3). Exemplary tertiary alkyl groups are tert-butyl, tert-amyl, 1,1-diethylpropyl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, and 2-methyl-2-adamantyl. Exemplary trialkylsilyl groups are trimethylsilyl, triethylsilyl, and dimethyl-tert-butylsilyl. Exemplary oxoalkyl groups are 3-oxocyclohexyl, 4-methyl-2-oxooxan-4-yl, and 5-methyl-2-oxooxolan-5-yl. Letter a1 is an integer of 0 to 6.

In formula (A-2), R³¹ and R³² each are hydrogen or a straight, branched or cyclic alkyl group of 1 to 18 carbon atoms, preferably 1 to 10 carbon atoms. Exemplary alkyl groups include methyl, ethyl, propyl, isopropyl, n-butyl, sec-butyl, tert-butyl, cyclopentyl, cyclohexyl, 2-ethylhexyl, and n-octyl. R³³ is a monovalent hydrocarbon group of 1 to 18 carbon atoms, preferably 1 to 10 carbon atoms, which may contain a heteroatom such as oxygen, examples of which include straight, branched or cyclic alkyl groups and substituted forms of such alkyl groups in which some hydrogen atoms are replaced by hydroxyl, alkoxy, oxo, amino, alkylamino or the like. Illustrative examples of the substituted alkyl groups are shown below.

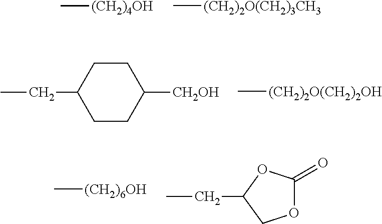

A pair of R³¹ and R³², R³¹ and R³³, or R³² and R³³ may bond together to form a ring with the carbon and oxygen atoms to which they are attached. Each of participant R³¹, R³² and R³³ is a straight or branched alkylene group of 1 to 18 carbon atoms, preferably 1 to 10 carbon atoms when they form a ring, while the ring preferably has 3 to 10 carbon atoms, more preferably 4 to 10 carbon atoms.

Examples of the acid labile groups of formula (A-1) include tert-butoxycarbonyl, tert-butoxycarbonylmethyl, tert-amyloxycarbonyl, tert-amyloxycarbonylmethyl, 1,1-diethylpropyloxycarbonyl, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonylmethyl, 1-ethoxyethoxycarbonylmethyl, 2-tetrahydropyranyloxycarbonylmethyl, and 2-tetrahydrofuranyloxycarbonylmethyl groups.

Also included are substituent groups having the formulae (A-1)-1 to (A-1)-10.

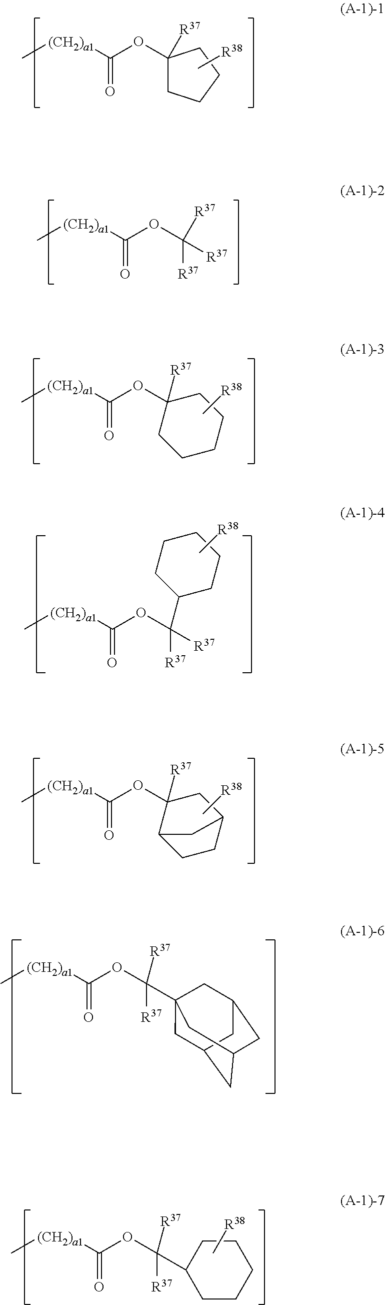

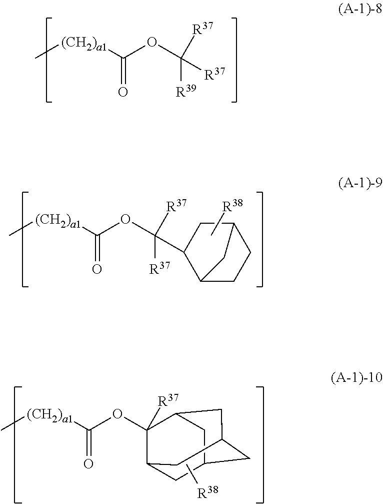

Herein R³⁷ is each independently a straight, branched or cyclic C₁-C₁₀ alkyl group or C₆-C₂₀ aryl group, R³⁸ is hydrogen or a straight, branched or cyclic C₁-C₁₀ alkyl group, R³⁹ is each independently a straight, branched or cyclic C₂-C₁₀ alkyl group or C₆-C₂₀ aryl group, and a1 is as defined above.

Of the acid labile groups of formula (A-2), the straight and branched ones are exemplified by the following groups having formulae (A-2)-1 to (A-2)-69.

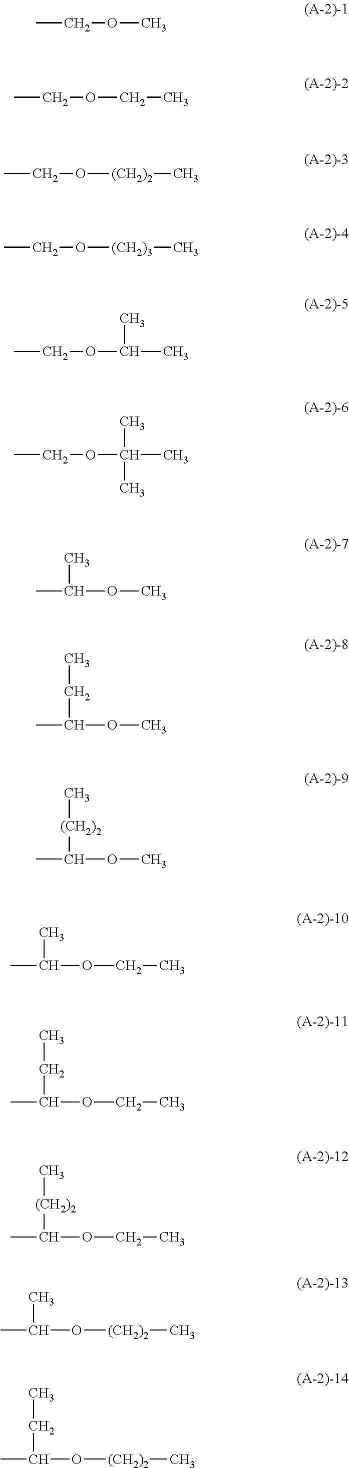

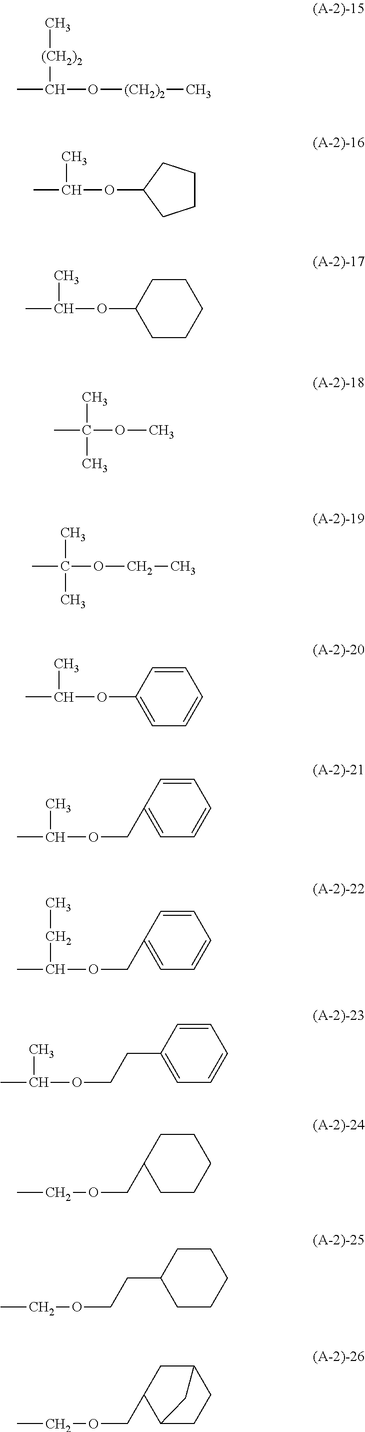

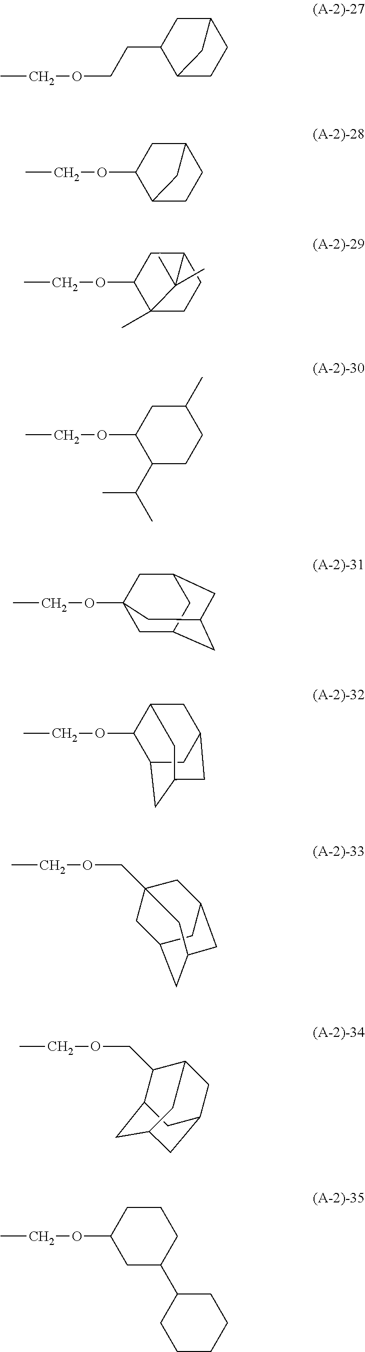

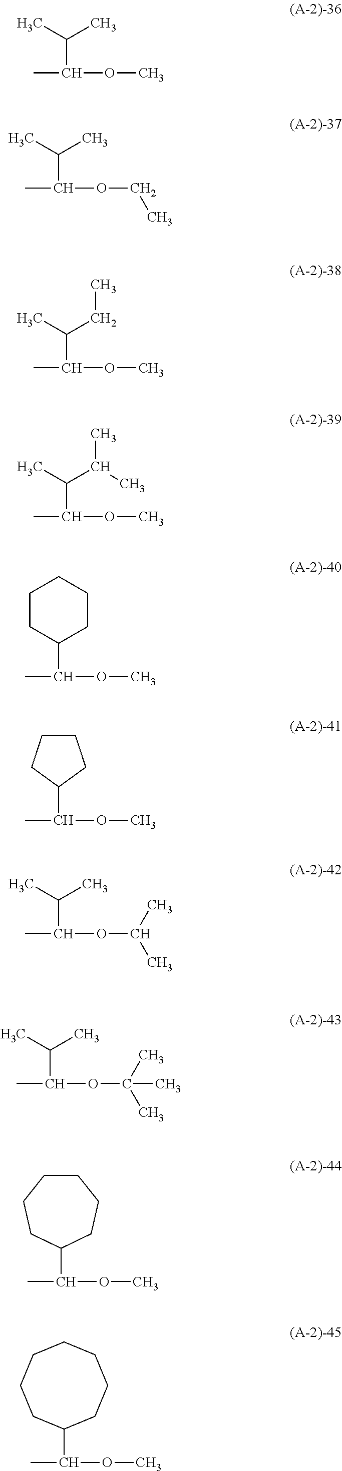

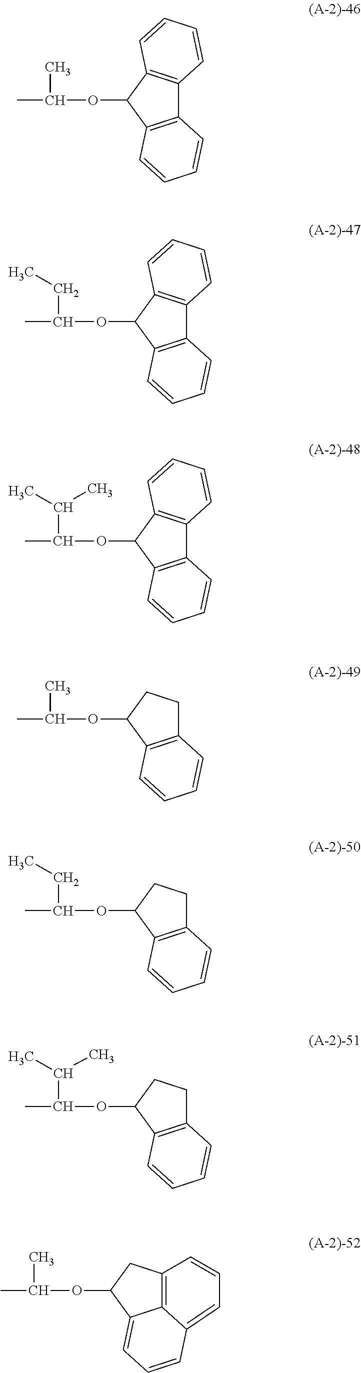

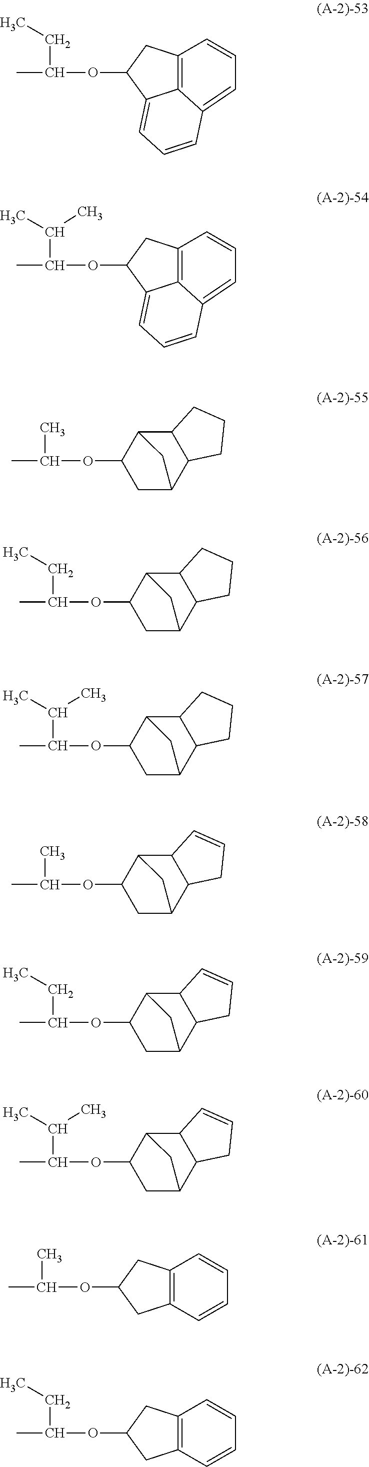

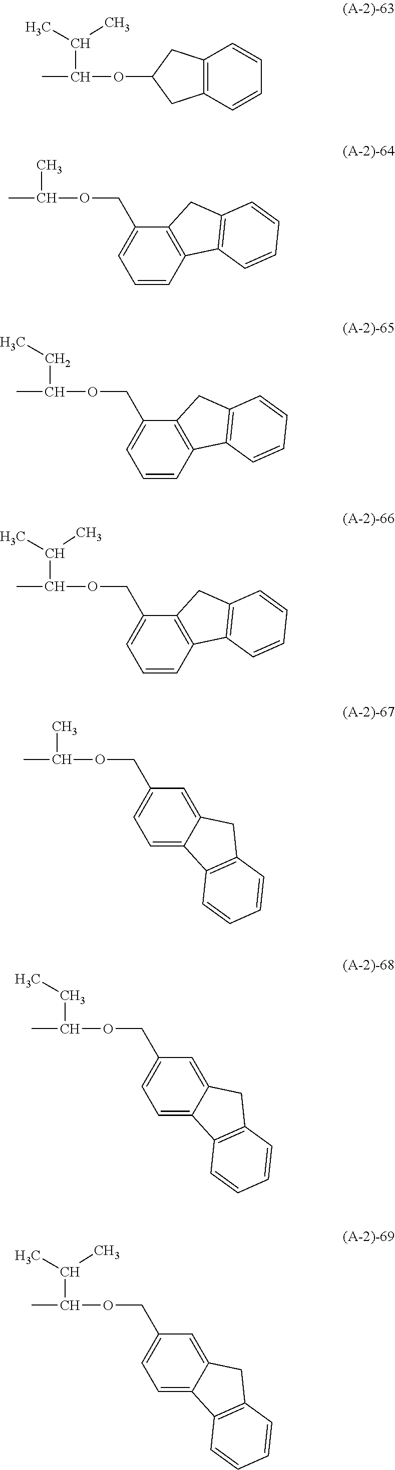

Of the acid labile groups of formula (A-2), the cyclic ones are, for example, tetrahydrofuran-2-yl, 2-methyltetrahydrofuran-2-yl, tetrahydropyran-2-yl, and 2-methyltetrahydropyran-2-yl.

Other examples of acid labile groups include those of the following formula (A-2a) or (A-2b) while the polymer may be crosslinked within the molecule or between molecules with these acid labile groups.

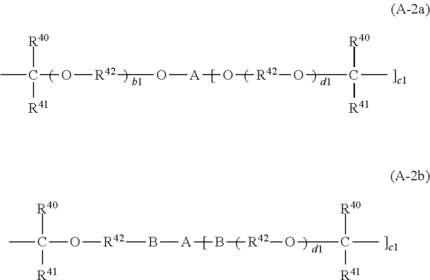

Herein R⁴⁰ and R⁴⁴ each are hydrogen or a straight, branched or cyclic C₁-C₈ alkyl group, or R⁴⁰ and R⁴¹, taken together, may form a ring with the carbon atom to which they are attached, and R⁴⁰ and R⁴⁴ are straight or branched C₁-C₈ alkylene groups when they form a ring. R⁴² is a straight, branched or cyclic C₁-C₁₀ alkylene group. Each of b1 and d1 is 0 or an integer of 1 to 10, preferably 0 or an integer of 1 to 5, and c1 is an integer of 1 to 7. “A” is a (c1+1)-valent aliphatic or alicyclic saturated hydrocarbon group, aromatic hydrocarbon group or heterocyclic group having 1 to 50 carbon atoms, which may be separated by a heteroatom or in which some hydrogen atoms attached to carbon atoms may be substituted by hydroxyl, carboxyl, carbonyl moieties or fluorine atoms. “B” is —CO—O—, —NHCO—O— or —NHCONH—.

Preferably, “A” is selected from divalent to tetravalent, straight, branched or cyclic C₁-C₂₀ alkylene, alkyltriyl and alkyltetrayl groups, and C₆-C₃₀ arylene groups, which may contain a heteroatom or in which some hydrogen atoms attached to carbon atoms may be substituted by hydroxyl, carboxyl, acyl moieties or halogen atoms. The subscript c1 is preferably an integer of 1 to 3.

The crosslinking acetal groups of formulae (A-2a) and (A-2b) are exemplified by the following formulae (A-2)-70 through (A-2)-77.

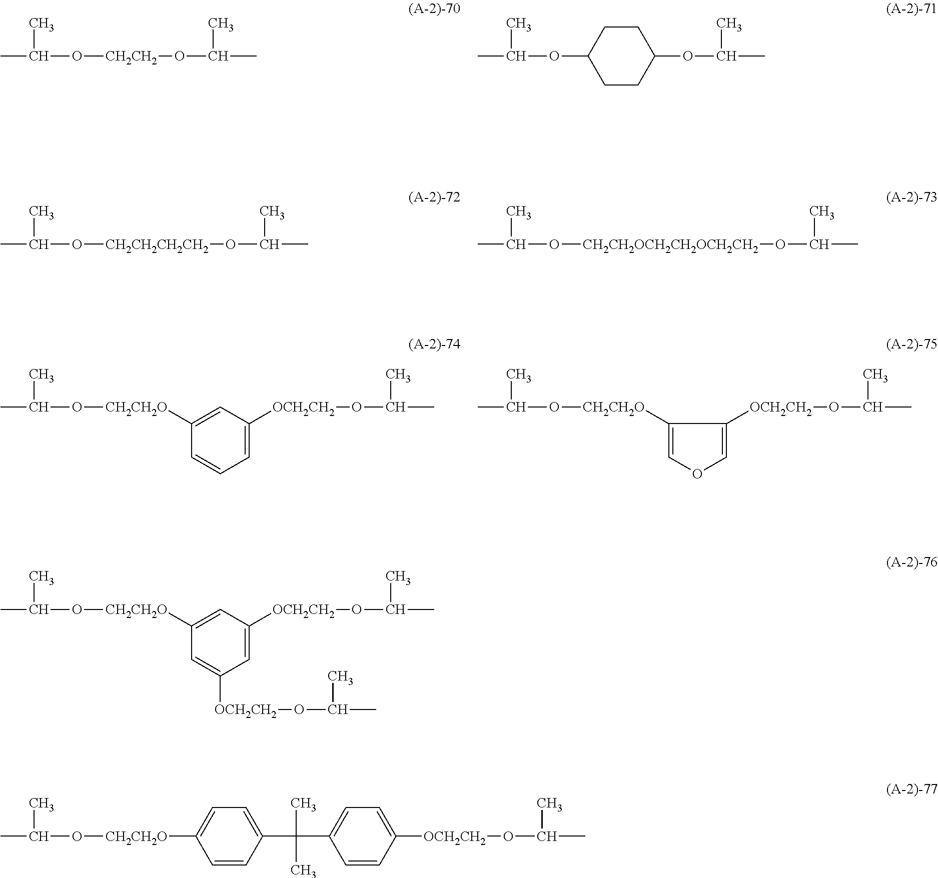

In formula (A-3), R³⁴, R³⁵ and R³⁶ each are a monovalent hydrocarbon group, typically a straight, branched or cyclic C₁-C₂₀ alkyl group or straight, branched or cyclic C₂-C₂₀ alkenyl group, which may contain a heteroatom such as oxygen, sulfur, nitrogen or fluorine. A pair of R³⁴ and R³⁵, R³⁴ and R³⁶, or R³⁵ and R³⁶ may bond together to form a C₃-C₂₀ aliphatic ring with the carbon atom to which they are attached.

Exemplary tertiary alkyl groups of formula (A-3) include tert-butyl, triethylcarbyl, 1-ethylnorbornyl, 1-methylcyclohexyl, 1-ethylcyclopentyl, 2-(2-methyl)adamantyl, 2-(2-ethyl)adamantyl, and tert-amyl.

Other exemplary tertiary alkyl groups include those of the following formulae (A-3)-1 to (A-3)-18.

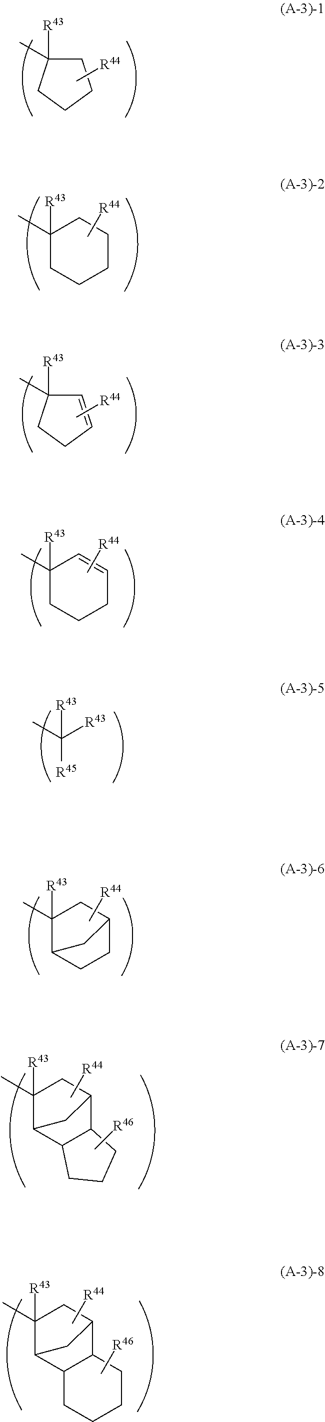

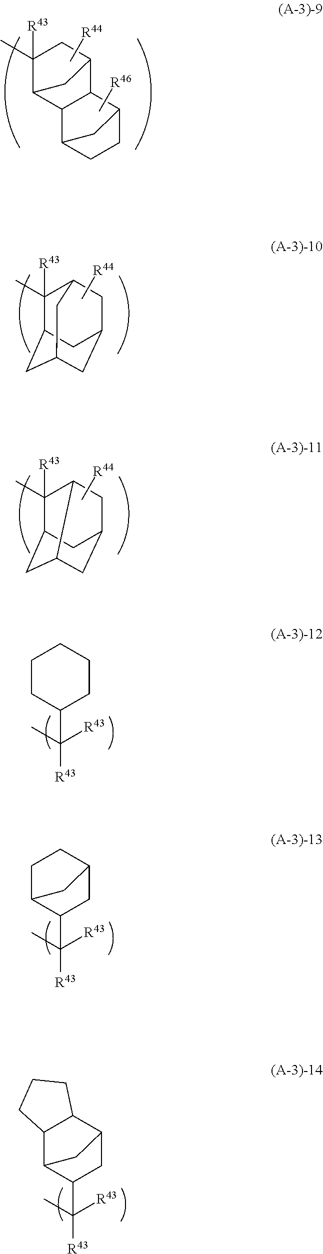

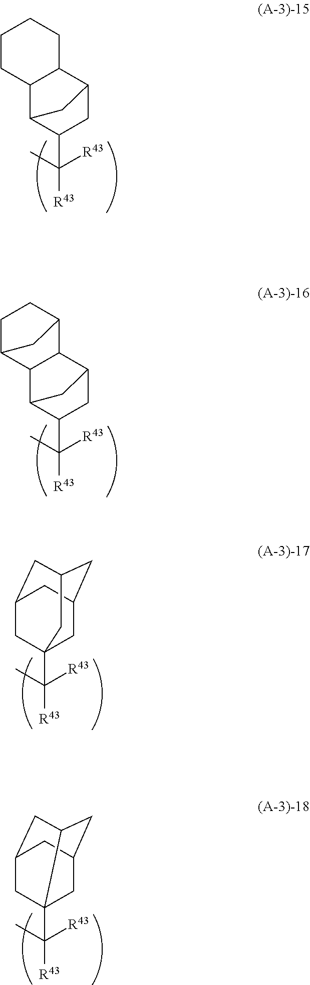

Herein R⁴³ is each independently a straight, branched or cyclic C₁-C₈ alkyl group or C₆-C₂₀ aryl group, typically phenyl, R⁴⁴ and R⁴⁶ each are hydrogen or a straight, branched or cyclic C₁-C₂₀ alkyl group, and R⁴⁵ is a C₆-C₂₀ aryl group, typically phenyl.

The polymer may be crosslinked within the molecule or between molecules with groups having R⁴⁷ which is a di- or multi-valent alkylene or arylene group, as shown by the following formulae (A-3)-19 and (A-3)-20.

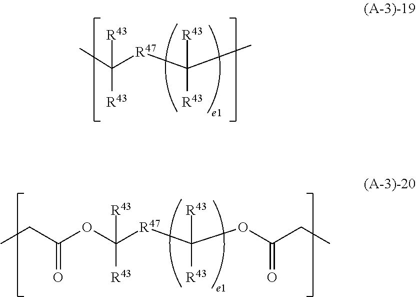

Herein R⁴³ is as defined above, R⁴⁷ is a straight, branched or cyclic C₁-C₂₀ alkylene group or arylene group, typically phenylene, which may contain a heteroatom such as oxygen, sulfur or nitrogen, and e1 is an integer of 1 to 3.

Of recurring units having acid labile groups of formula (A-3), recurring units of (meth)acrylate having an exo-form structure represented by the formula (A-3)-21 are preferred as recurring unit (a1).

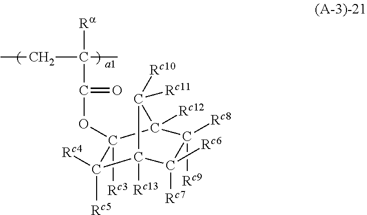

Herein, R^{α} is hydrogen or methyl; R^{c3} is a straight, branched or cyclic C₁-C₈ alkyl group or an optionally substituted C₆-C₂₀ aryl group; R^{c4} to R^{c9}, R^{c12} and R^{c13} are each independently hydrogen or a monovalent C₁-C₁₅ hydrocarbon group which may contain a heteroatom; and R^{c10} and R^{c11} are hydrogen or a monovalent C₁-C₁₅ hydrocarbon group which may contain a heteroatom. Alternatively, a pair of R^{c4} and R^{c5}, R^{c6} and R^{c8}, R^{c6} and R^{c9}, R^{c7} and R^{c9}, R^{c7} and R^{c13}, R^{c8} and R^{c12}, R^{c10} and R^{c11}, or R^{c11} and R^{c12}, taken together, may form a ring, and in that event, each ring-forming R is a divalent C₁-C₁₅ hydrocarbon group which may contain a heteroatom. Also, a pair of R^{c4} and R^{c13}, R^{c10} and R^{c13}, or R^{c6} and R^{c8} which are attached to vicinal carbon atoms may bond together directly to form a double bond. The formula also represents an enantiomer.

The ester form monomers from which recurring units having an exo-form structure represented by formula (A-3)-21 are derived are described in U.S. Pat. No. 6,448,420 (JP-A 2000-327633). Illustrative non-limiting examples of suitable monomers are given below.

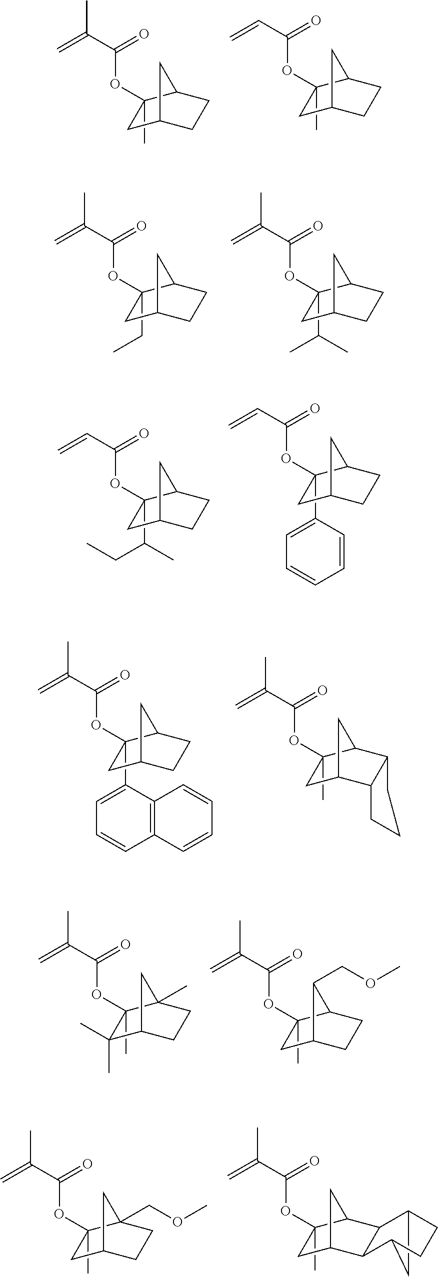

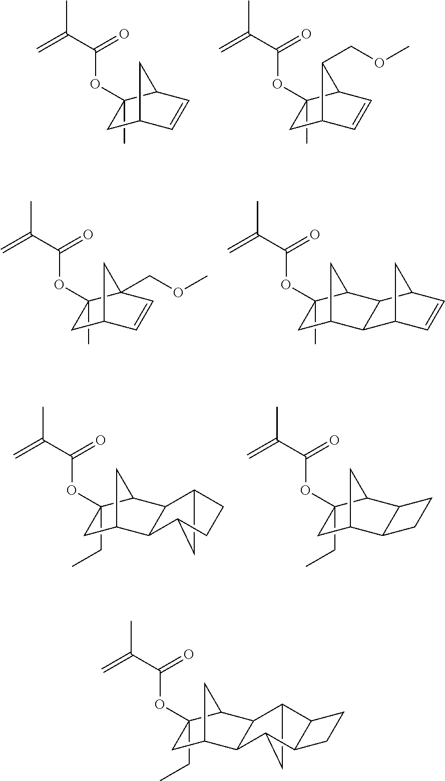

Also included in the acid labile groups of formula (A-3) in recurring units (a1) are acid labile groups of (meth)acrylate having furandiyl, tetrahydrofurandiyl or oxanorbornanediyl as represented by the following formula (A-3)-22.

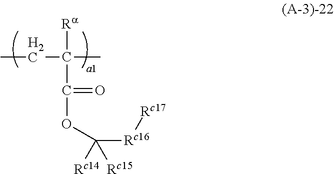

Herein, R^{α} is as defined above; R^{c14} and R^{c15} are each independently a monovalent, straight, branched or cyclic C₁-C₁₀ hydrocarbon group, or R^{c14} and R^{c15}, taken together, may form an aliphatic hydrocarbon ring with the carbon atom to which they are attached. R^{c16} is a divalent group selected from furandiyl, tetrahydrofurandiyl and oxanorbornanediyl. R^{c17} is hydrogen or a monovalent, straight, branched or cyclic C₁-C₁₀ hydrocarbon group which may contain a heteroatom.

Examples of the monomers from which the recurring units substituted with acid labile groups having furandiyl, tetrahydrofurandiyl and oxanorbornanediyl are derived are shown below. Note that Me is methyl and Ac is acetyl.

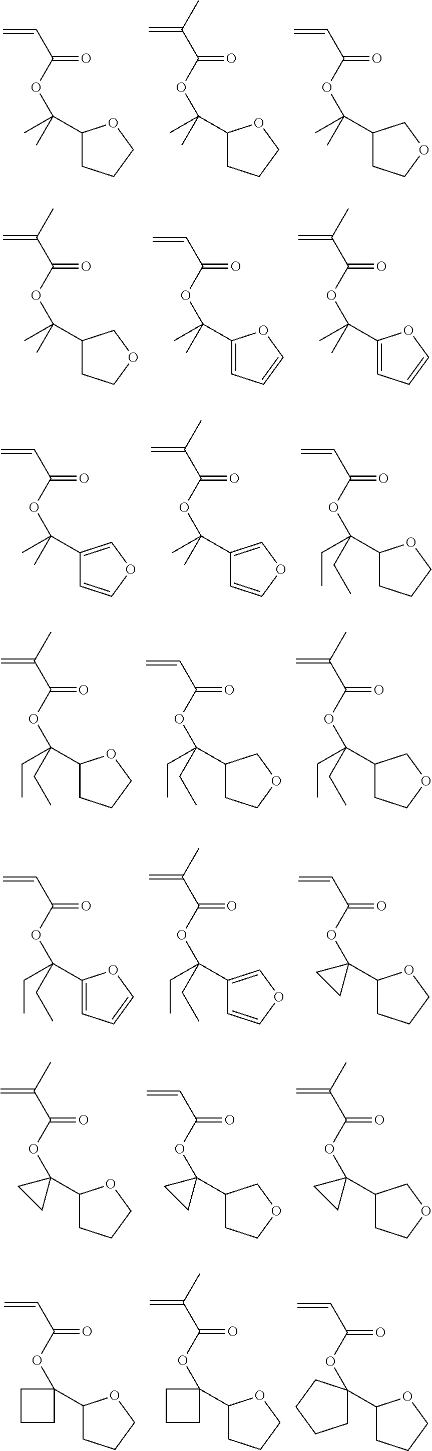

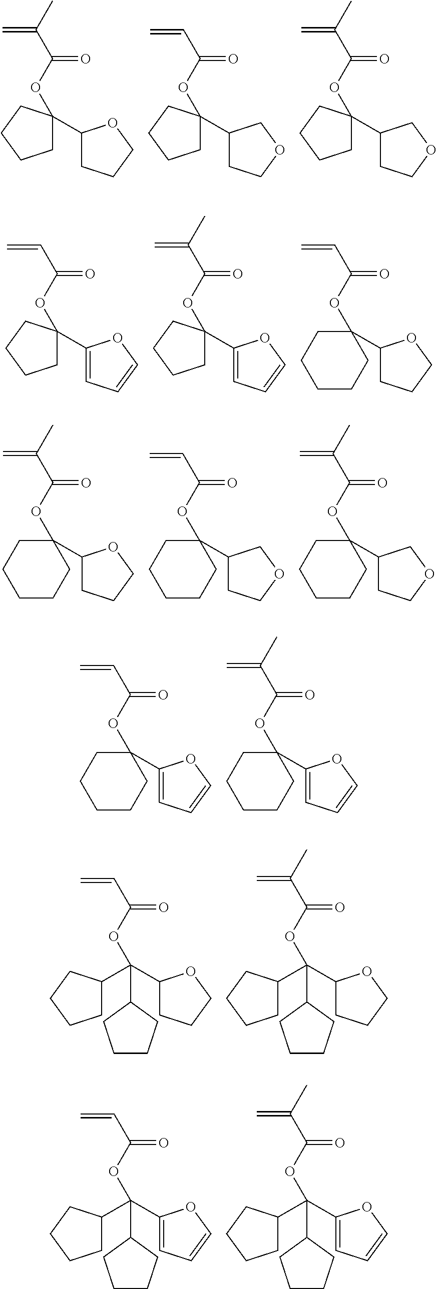

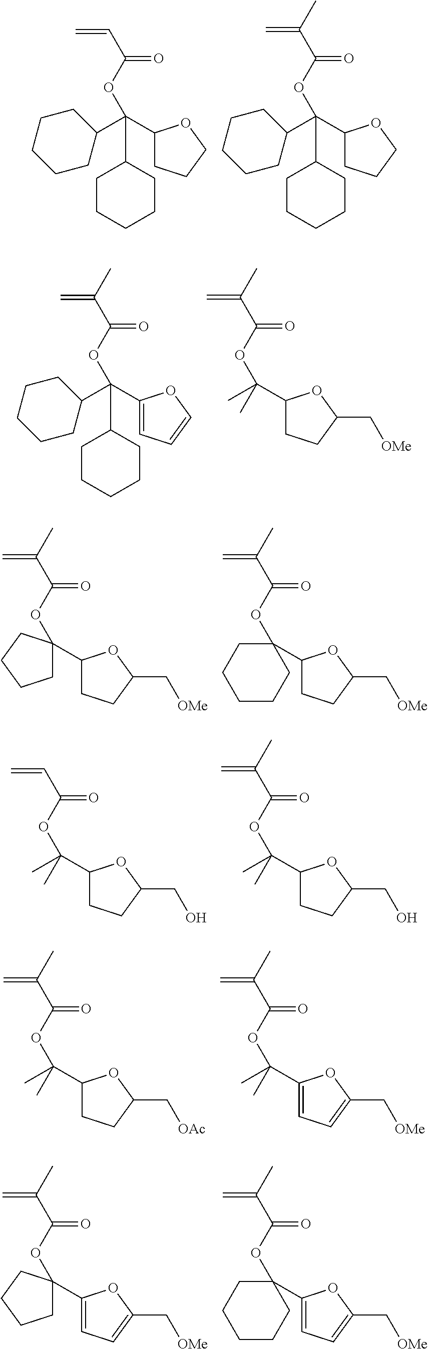

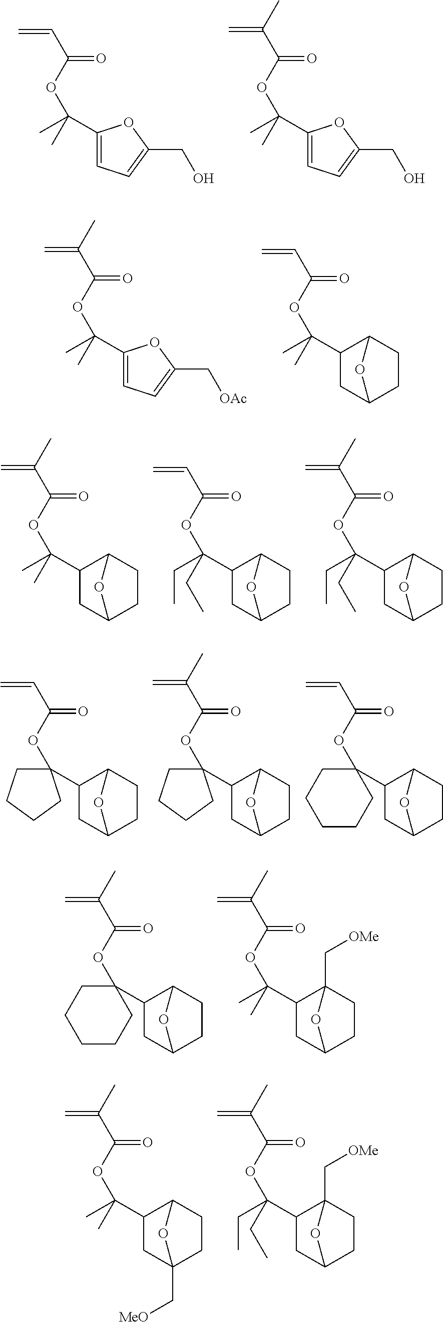

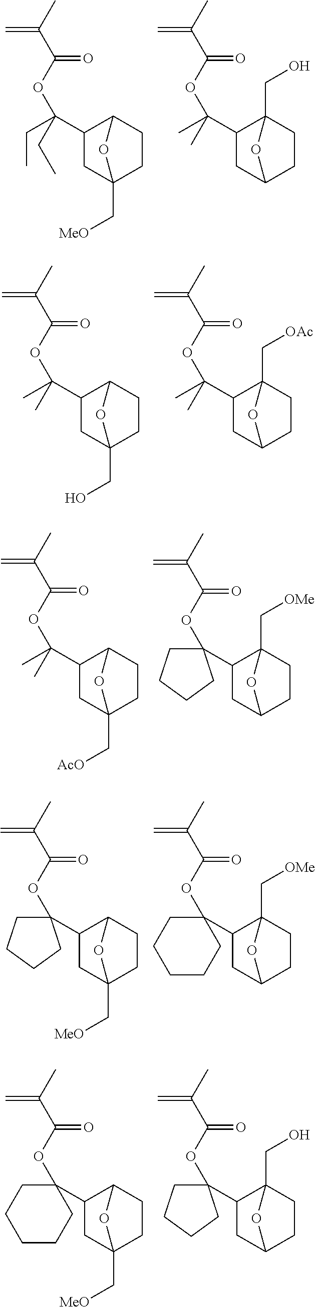

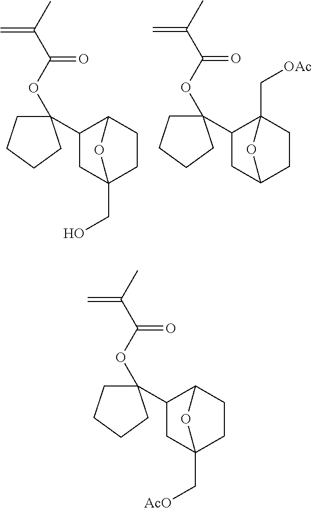

The acid labile group R² in recurring units (a1) may be a group having the general formula (A-3)-23.

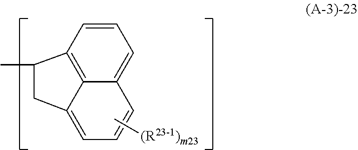

Herein R²³⁻¹ is hydrogen, a C₁-C₄ alkyl, alkoxy, alkanoyl or alkoxycarbonyl, C₆-C₁₀ aryl, halogen or cyano group, and m23 is an integer of 1 to 4.

Examples of the monomer from which recurring units (a1) having an acid labile group of formula (A-3)-23 substituted thereon are derived are shown below.

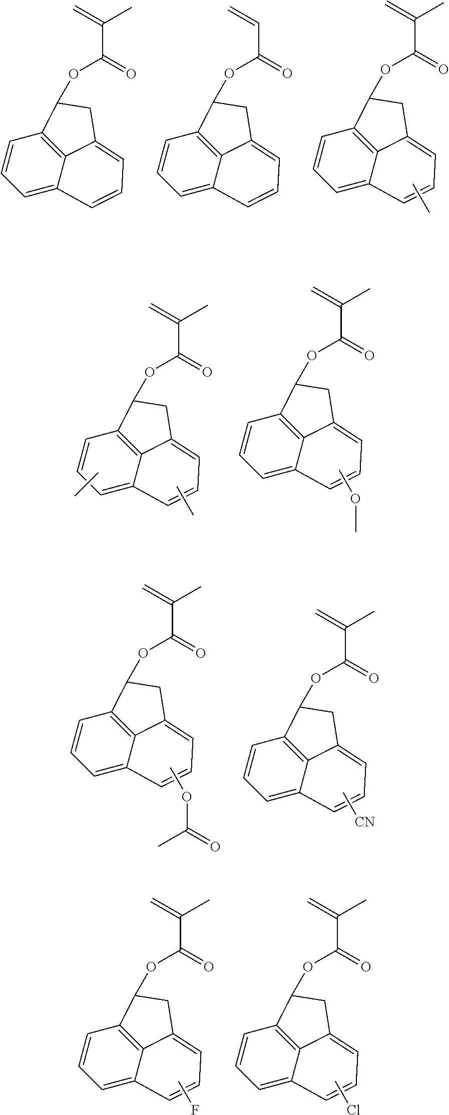

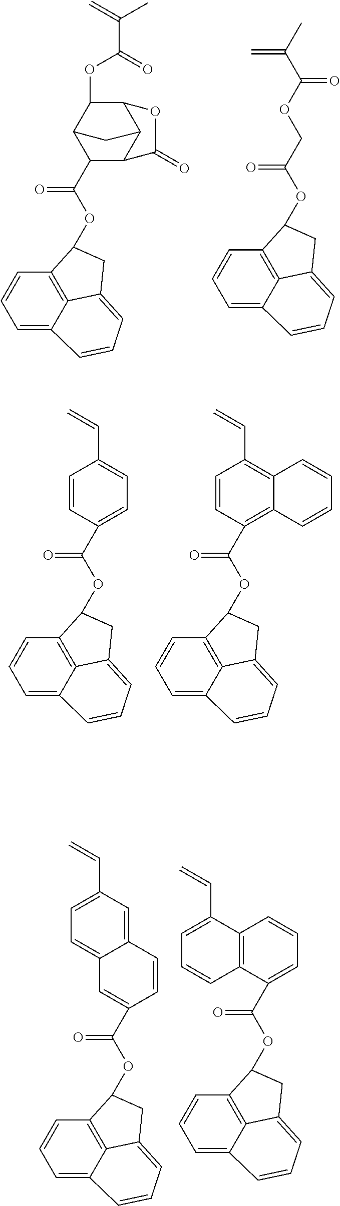

The acid labile group R² in recurring units (a1) may be a group having the general formula (A-3)-24.

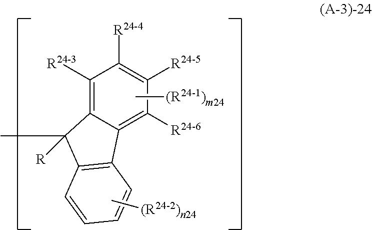

Herein R²⁴¹ and R²⁴² each are hydrogen, a C₁-C₄ alkyl, alkoxy, alkanoyl or alkoxycarbonyl, hydroxyl, C₆-C₁₀ aryl, halogen or cyano group, R is hydrogen, a straight, branched or cyclic C₁-C₁₂ alkyl group, C₂-C₁₂ alkenyl group, C₂-C₁₂ alkynyl group, or C₆-C₁₀ aryl group which may contain oxygen or sulfur, R²⁴⁻³, R²⁴⁻⁴, R²⁴⁻⁵, and R²⁴⁻⁶ are hydrogen or a pair of R²⁴⁻³ and R²⁴⁻⁴, R²⁴⁻⁴ and R²⁴⁵, or R²⁴⁵ and R²⁴⁶, taken together, may form a benzene ring, and m24 and n24 each are an integer of 1 to 4.

Examples of the monomer from which recurring units (a1) having an acid labile group of formula (A-3)-24 substituted thereon are derived are shown below.

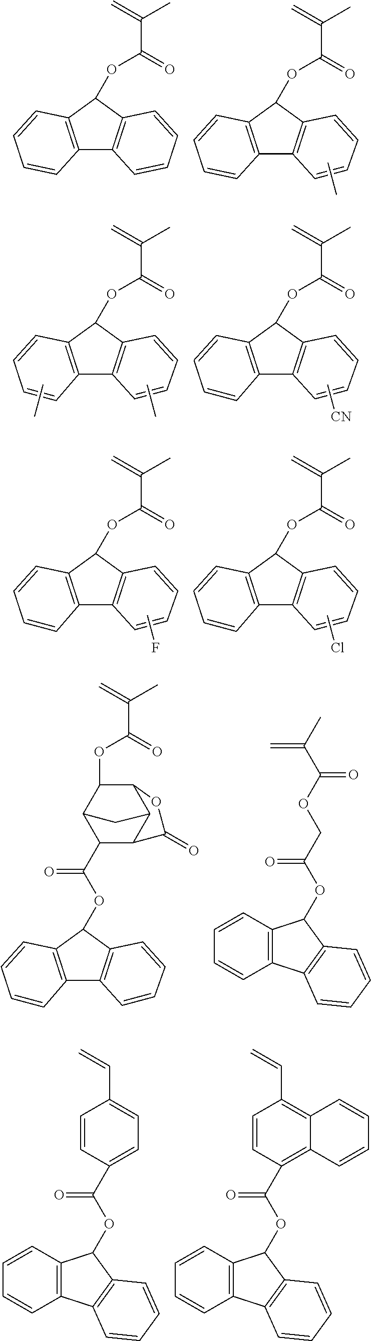

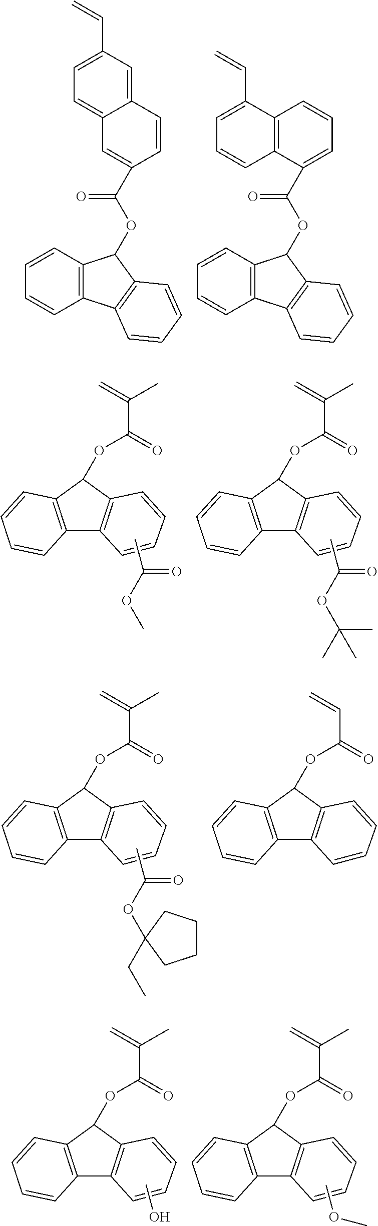

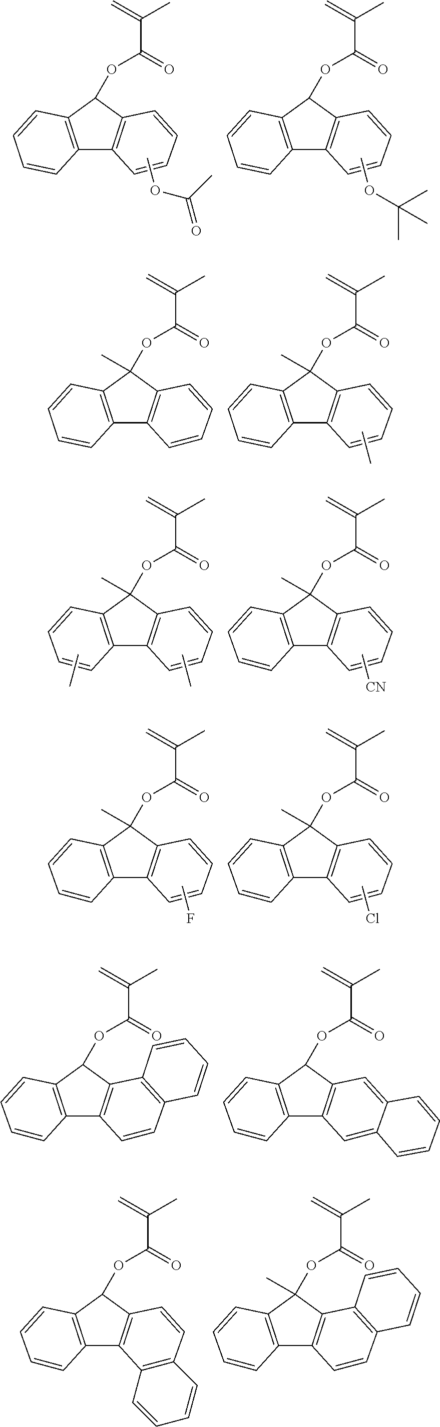

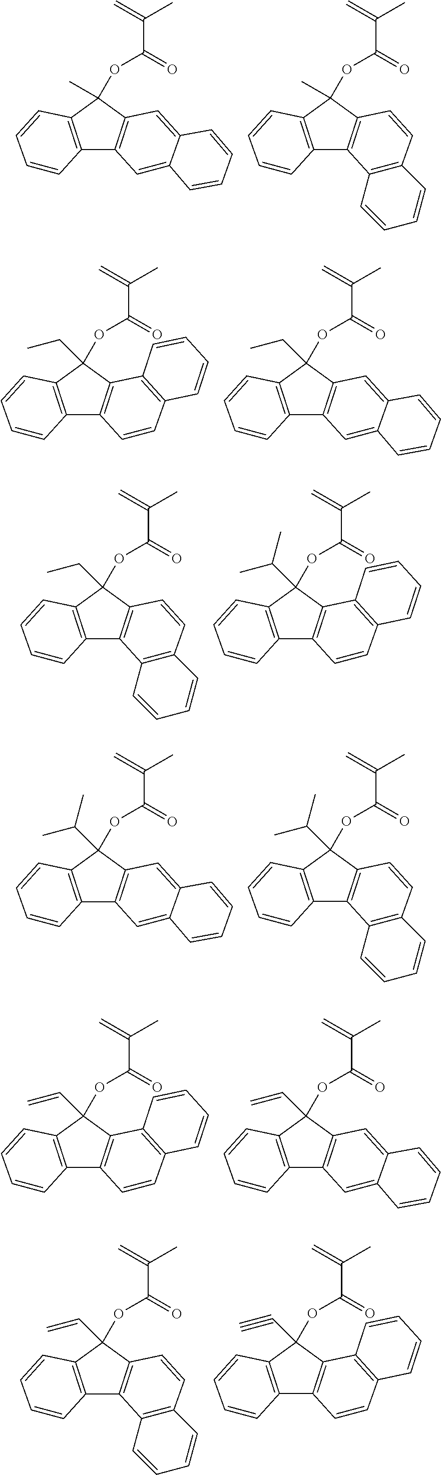

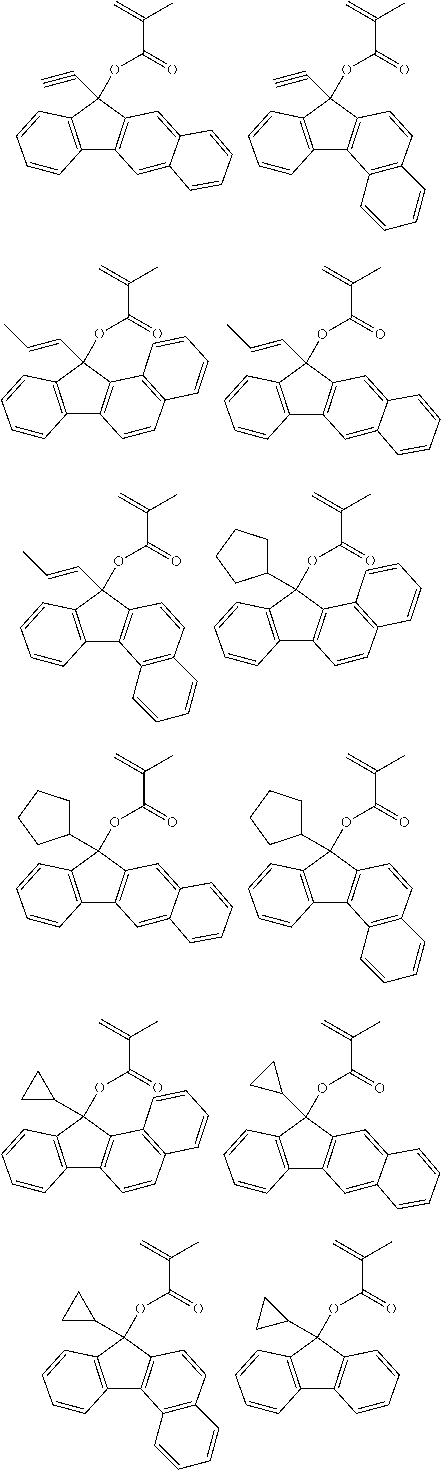

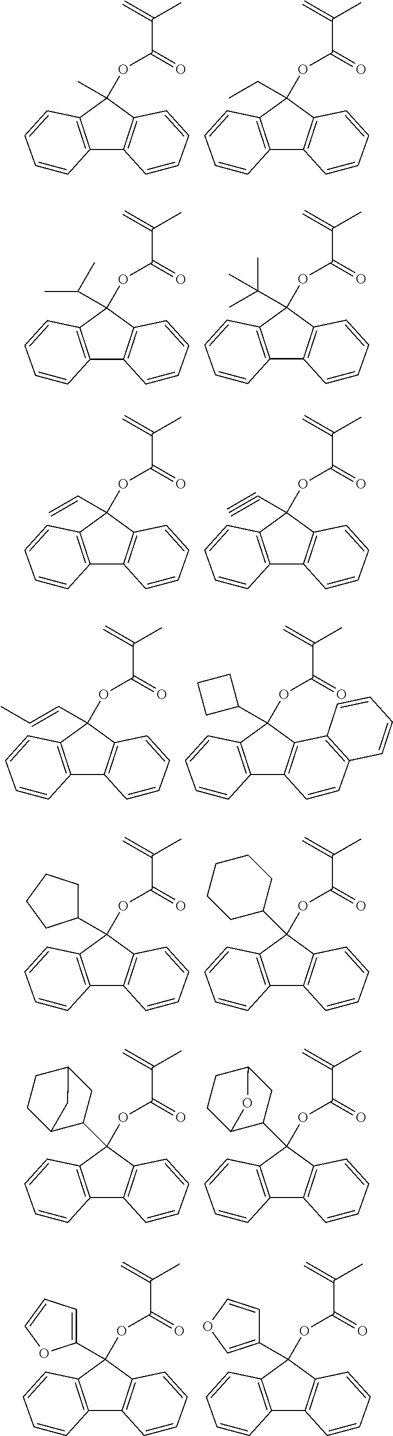

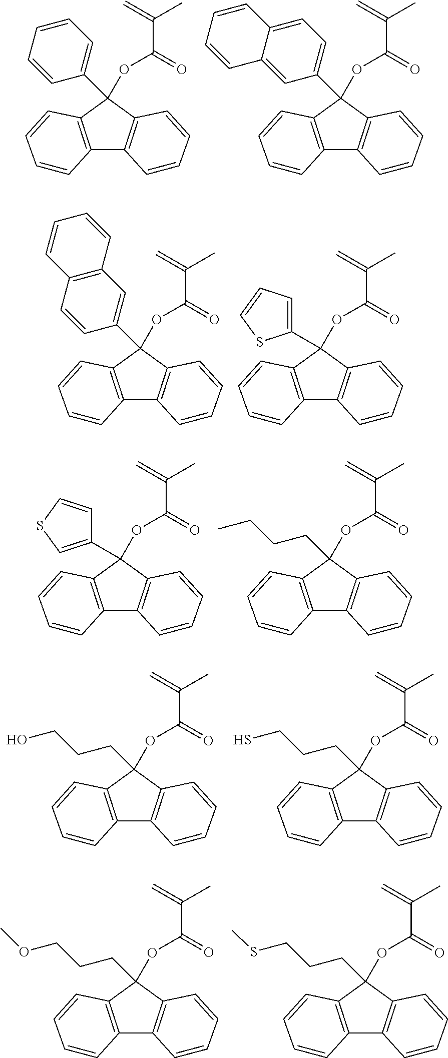

The acid labile group R² in recurring units (a1) may be a group having the general formula (A-3)-25.

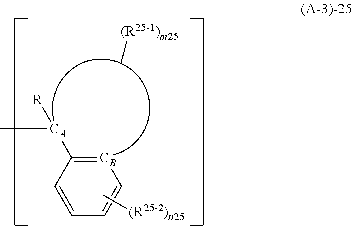

Herein R²⁵⁻¹ is each independently hydrogen or a straight, branched or cyclic C₁-C₆ alkyl group. When m25 is 2 or more, two R²⁵⁻¹ taken together may form a non-aromatic ring of 2 to 8 carbon atoms. The circle denotes a link between carbons C_{A} and C_{B}, selected from among ethylene, propylene, butylene and pentylene. R²⁵² is a C₁-C₁₀ alkyl, alkoxy, alkanoyl or alkoxycarbonyl, hydroxyl, nitro, C₆-C₁₀ aryl, halogen or cyano group. R is as defined above. R²⁵⁻¹ is not hydrogen when the circle is ethylene or propylene. The subscripts m25 and n25 are an integer of 1 to 4.

Examples of the monomer from which recurring units (a1) having an acid labile group of formula (A-3)-25 substituted thereon are derived are shown below.

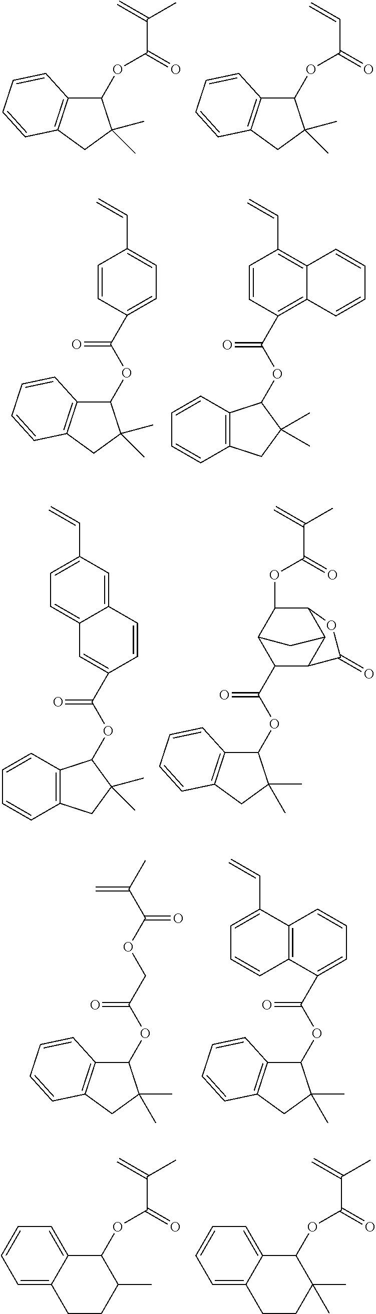

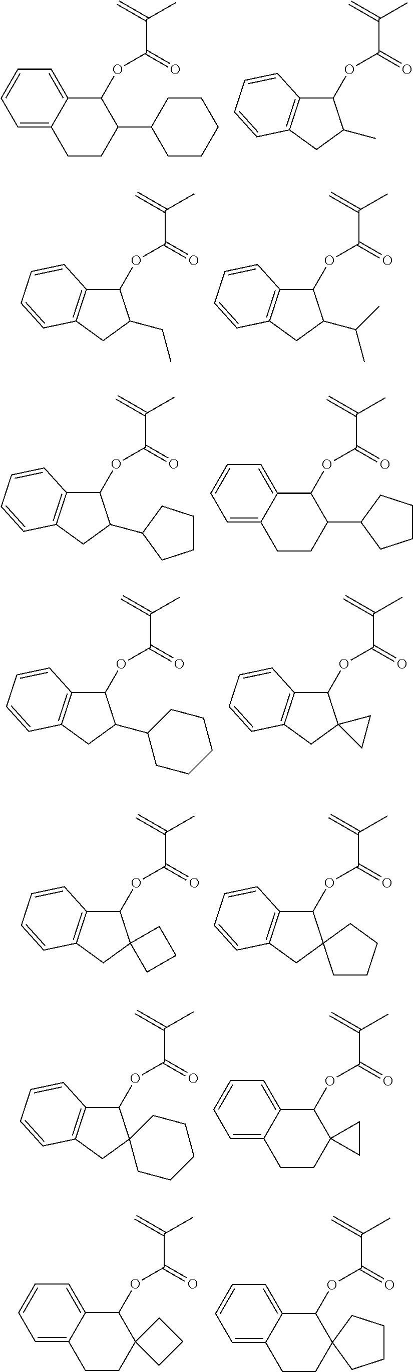

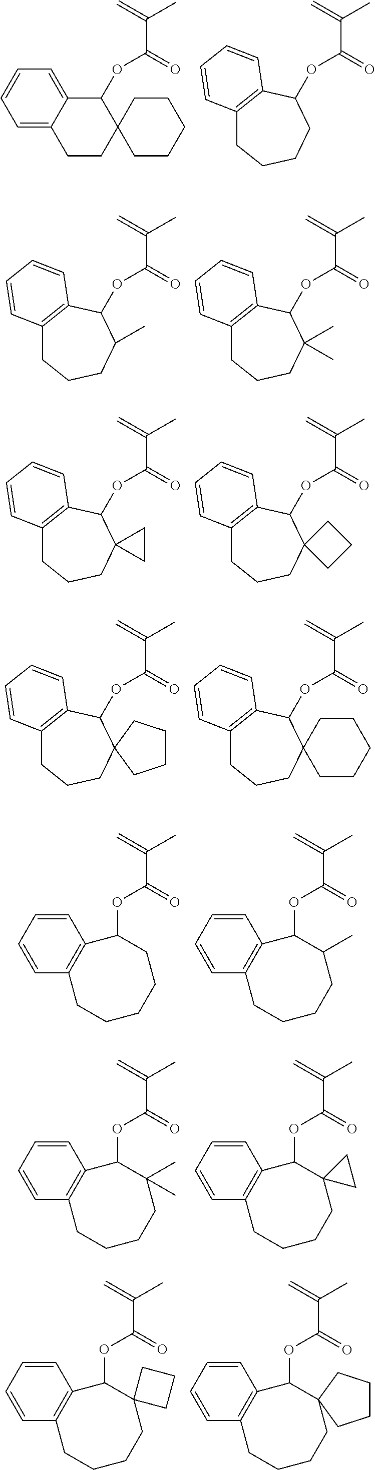

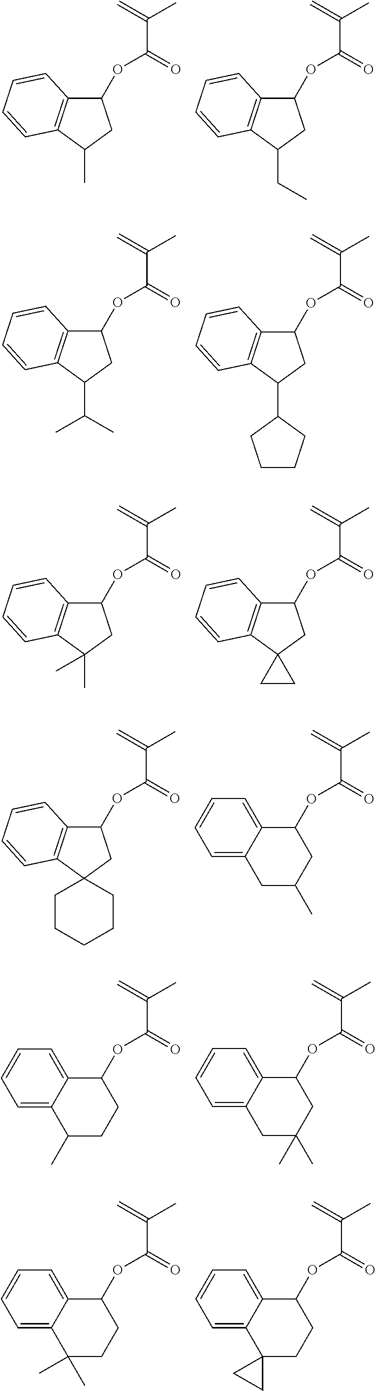

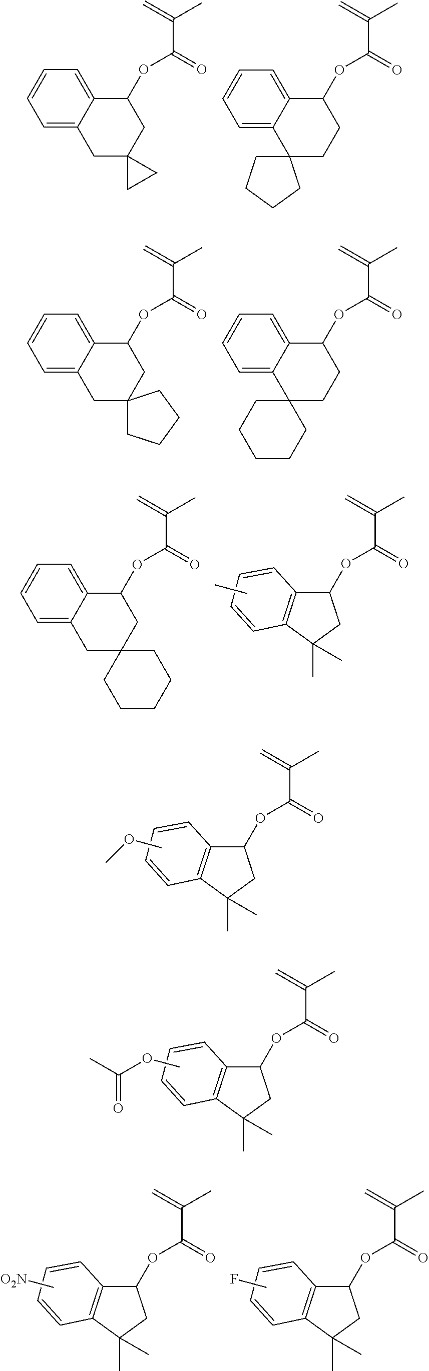

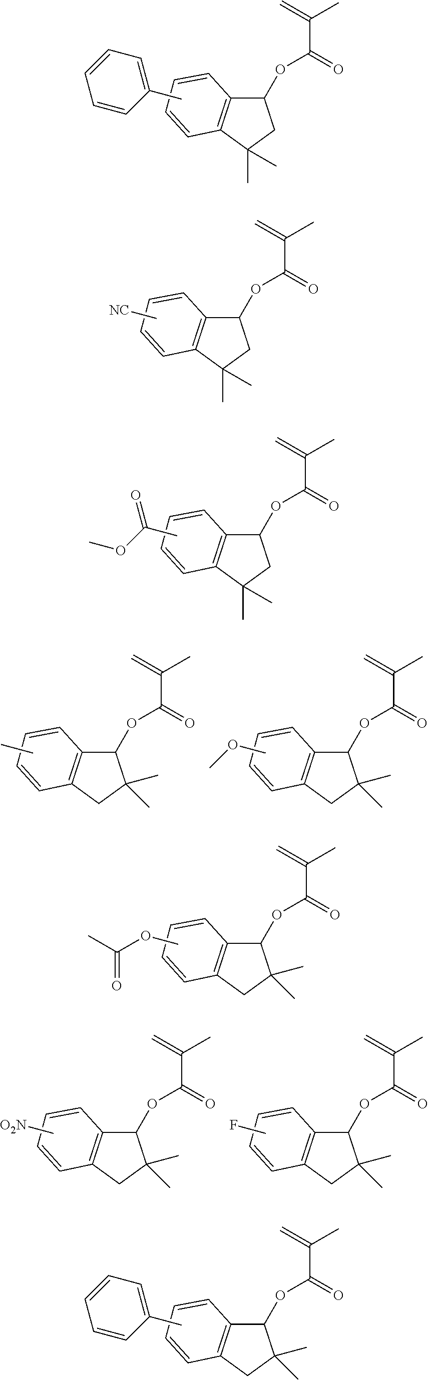

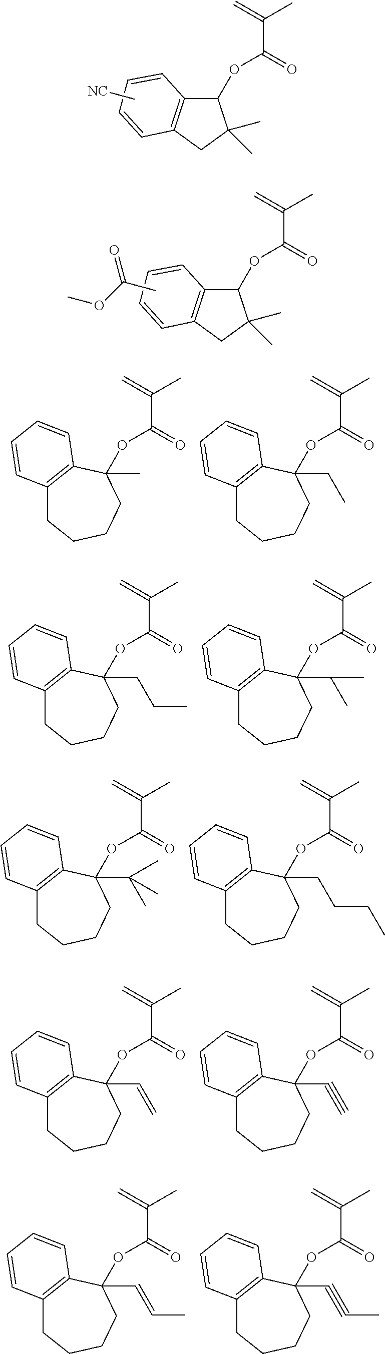

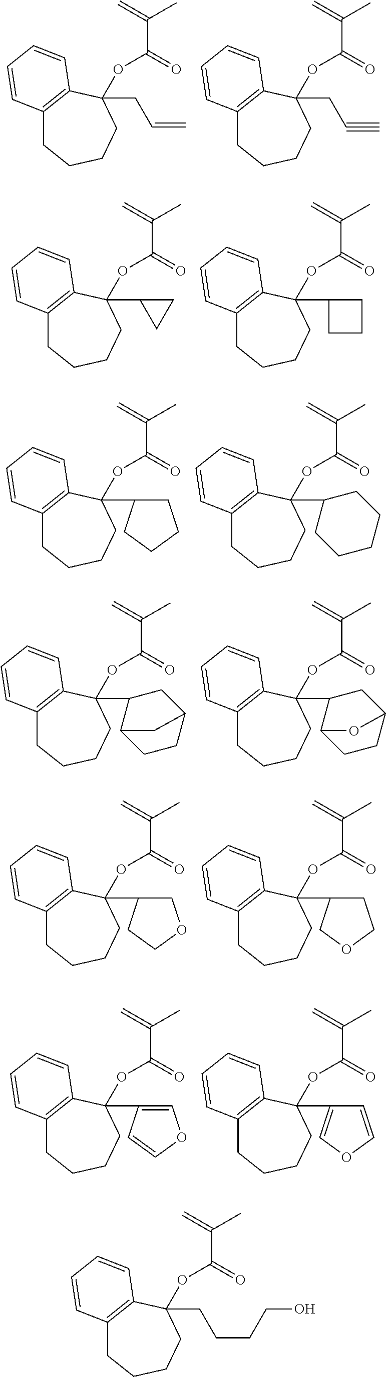

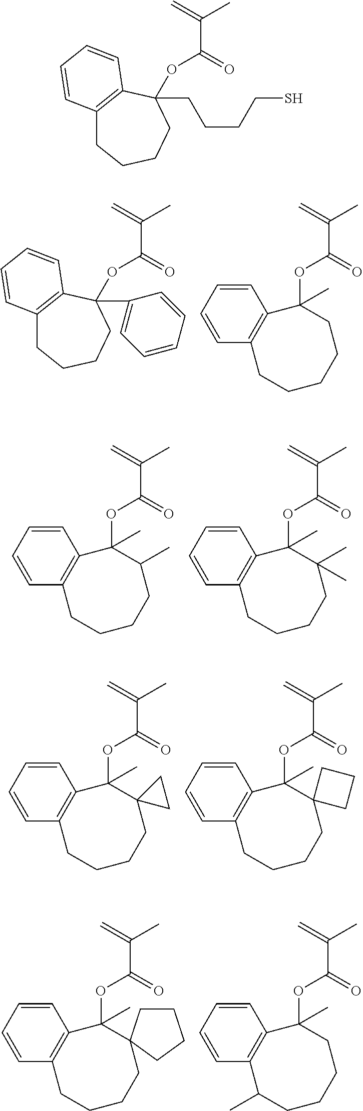

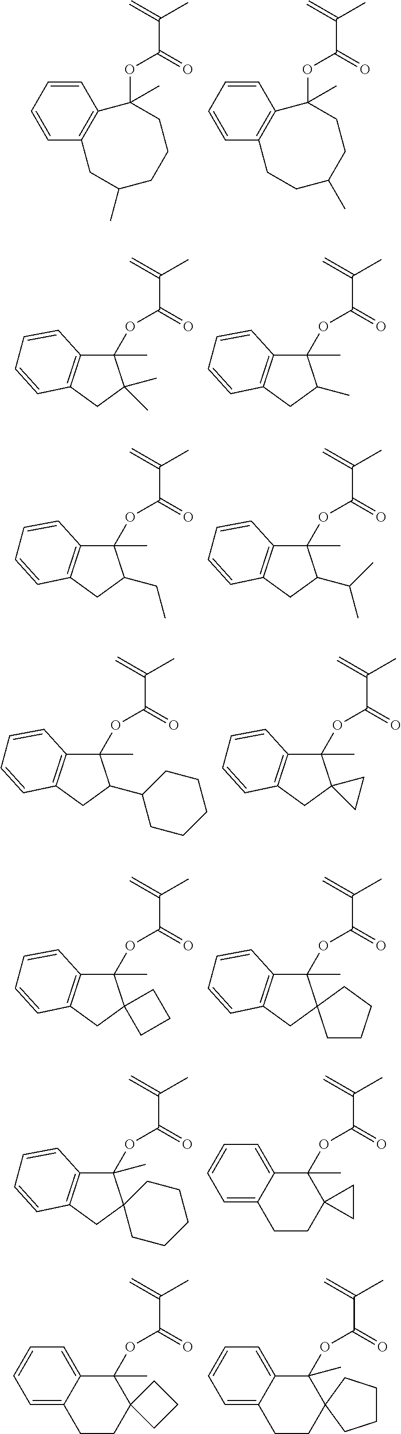

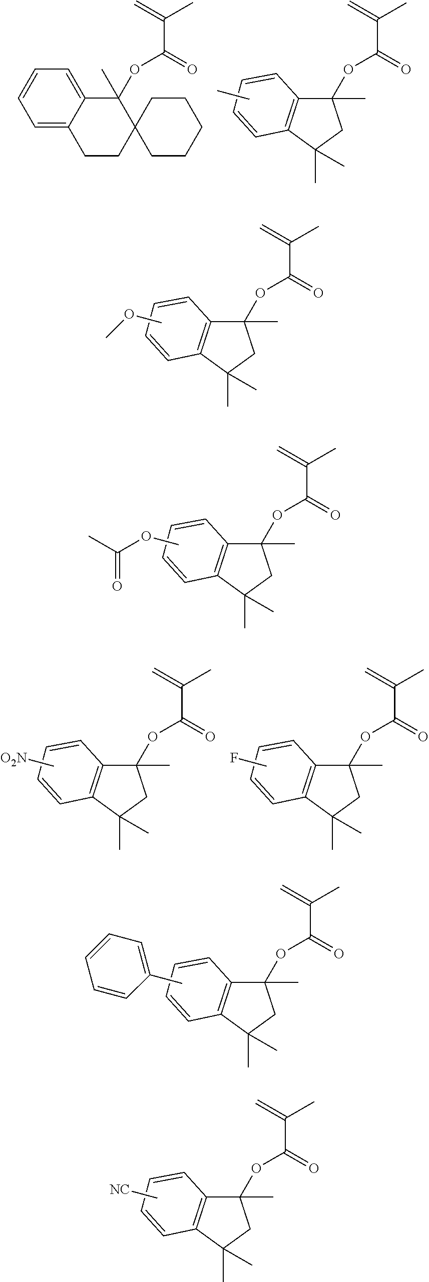

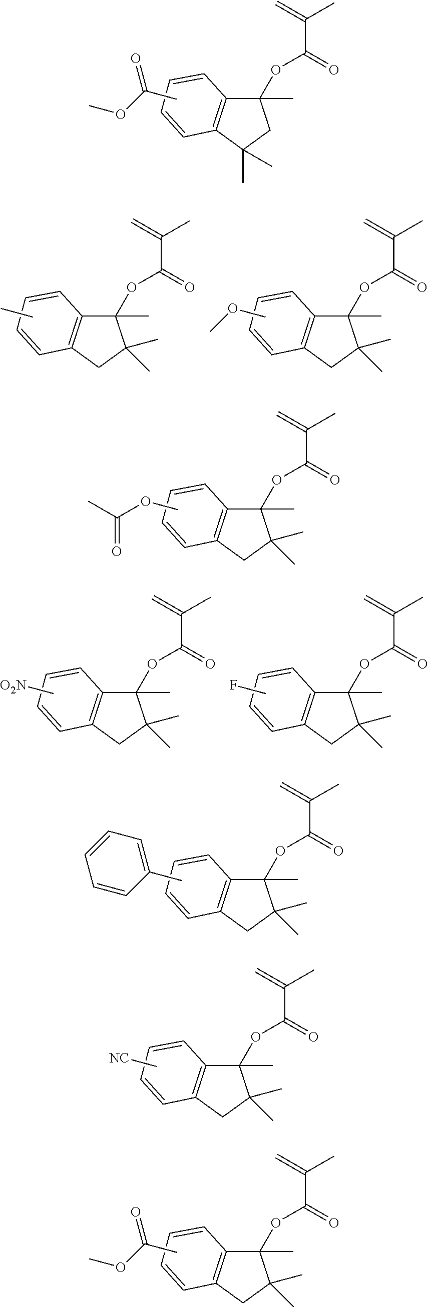

The acid labile group R² in recurring units (a1) may be a group having the general formula (A-3)-26.

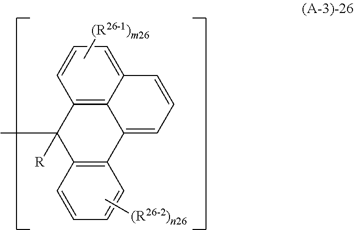

Herein R²⁶⁻¹ and R²⁶⁻² each are hydrogen, a C₁-C₄ alkyl, alkoxy, alkanoyl or alkoxycarbonyl, hydroxyl, nitro, C₆-C₁₀ aryl, halogen or cyano group, R is as defined above, and m26 and n26 are an integer of 1 to 4.

Examples of the monomer from which recurring units (a1) having an acid labile group of formula (A-3)-26 substituted thereon are derived are shown below.

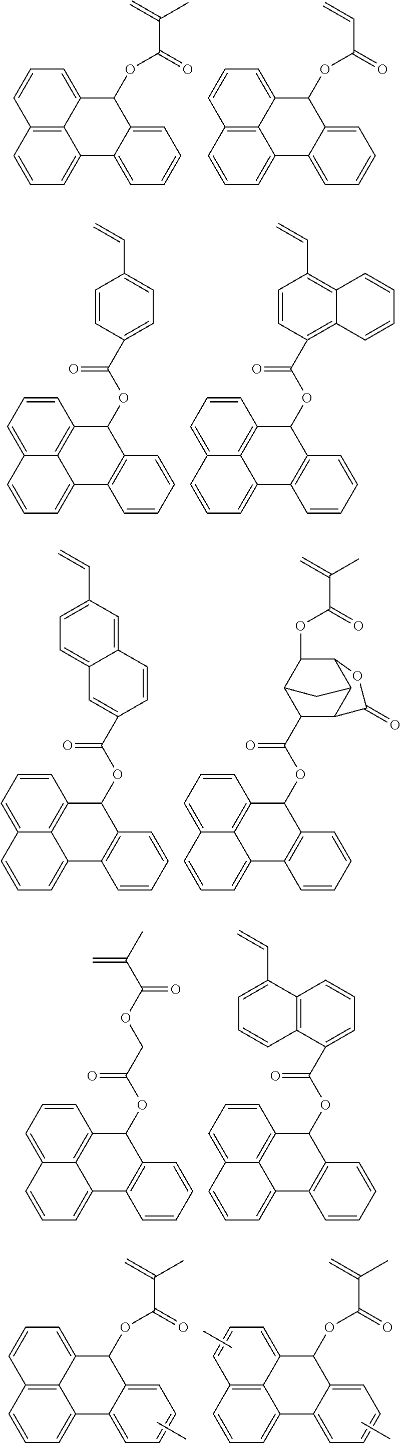

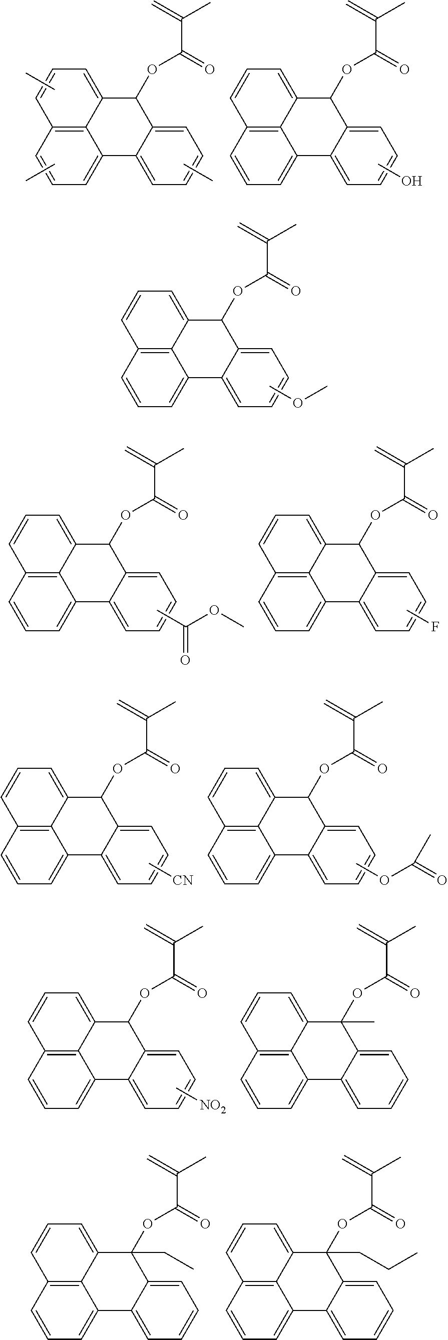

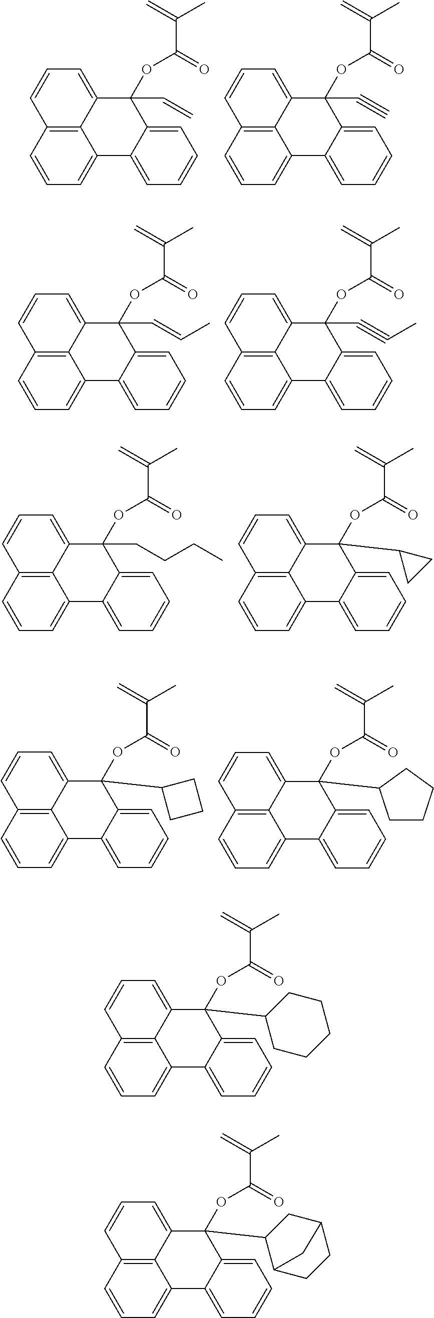

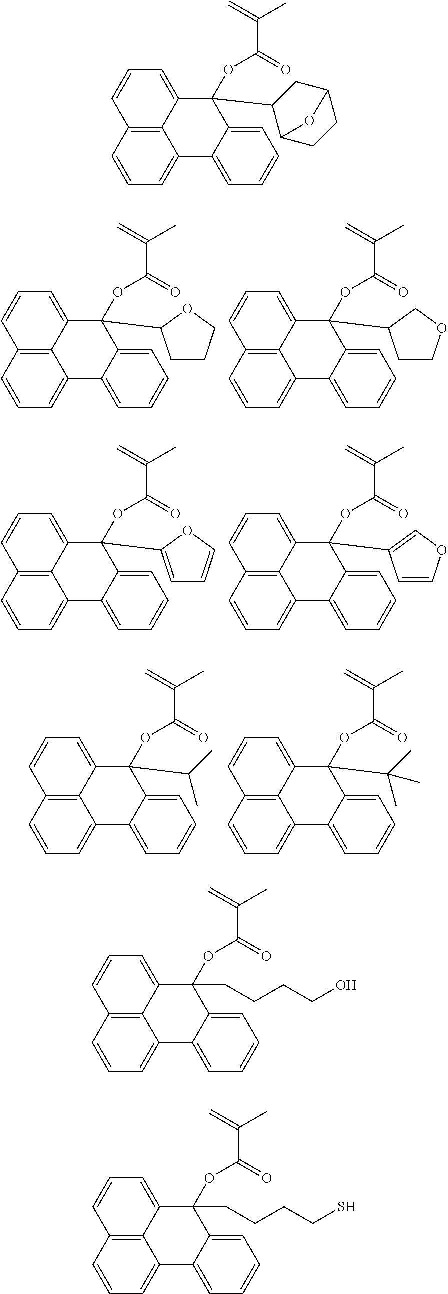

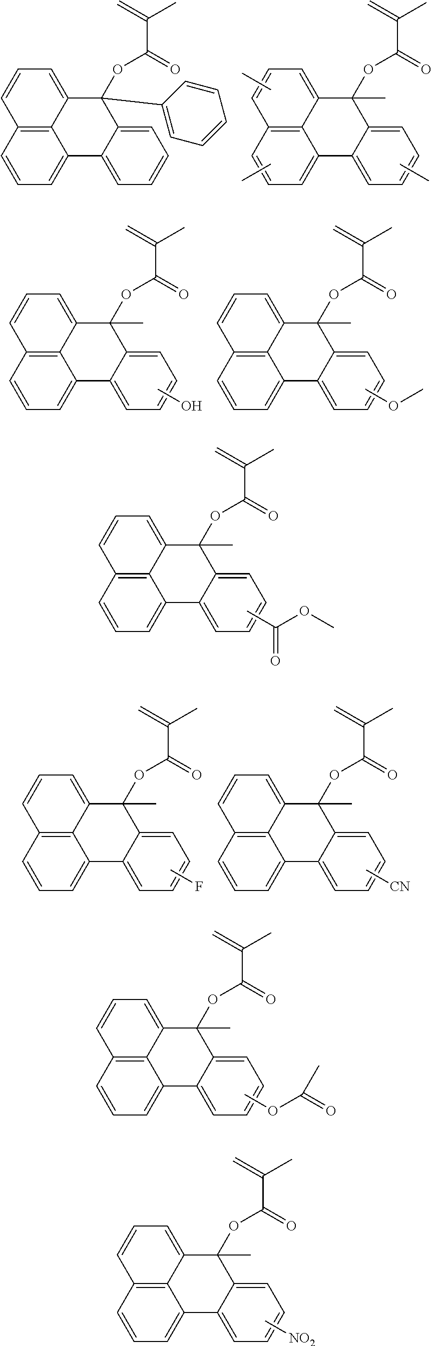

The acid labile group R² in recurring units (a1) may be a group having the general formula (A-3)-27.

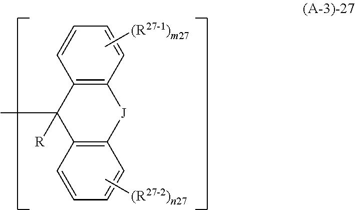

Herein R²⁷¹ and R²⁷² each are hydrogen, a C₁-C₄ alkyl, alkoxy, alkanoyl or alkoxycarbonyl, hydroxyl, C₆-C₁₀ aryl, halogen or cyano group, R is as defined above, J is methylene, ethylene, vinylene or —CH₂—S—, and m27 and n27 are an integer of 1 to 4.

Examples of the monomer from which recurring units (a1) having an acid labile group of formula (A-3)-27 substituted thereon are derived are shown below.

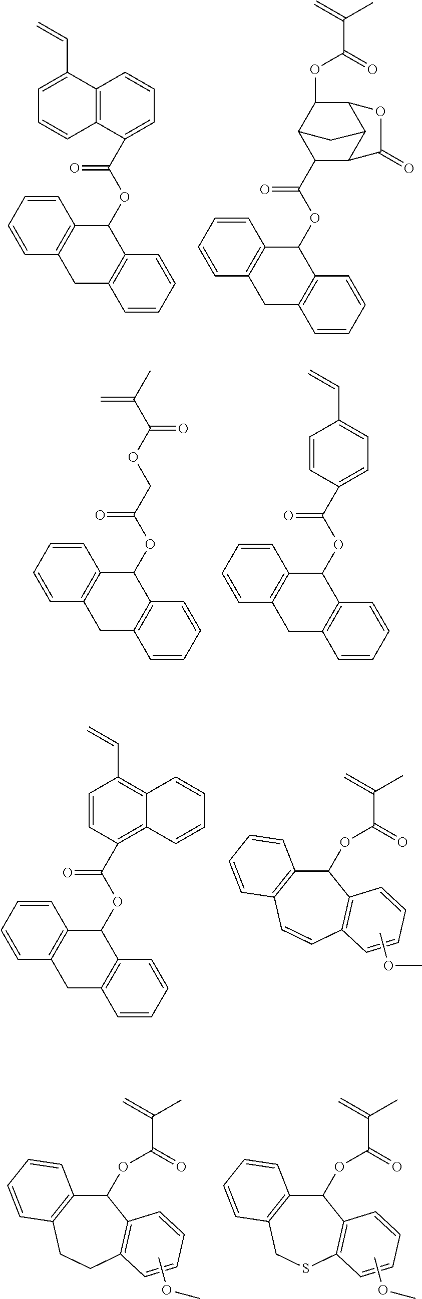

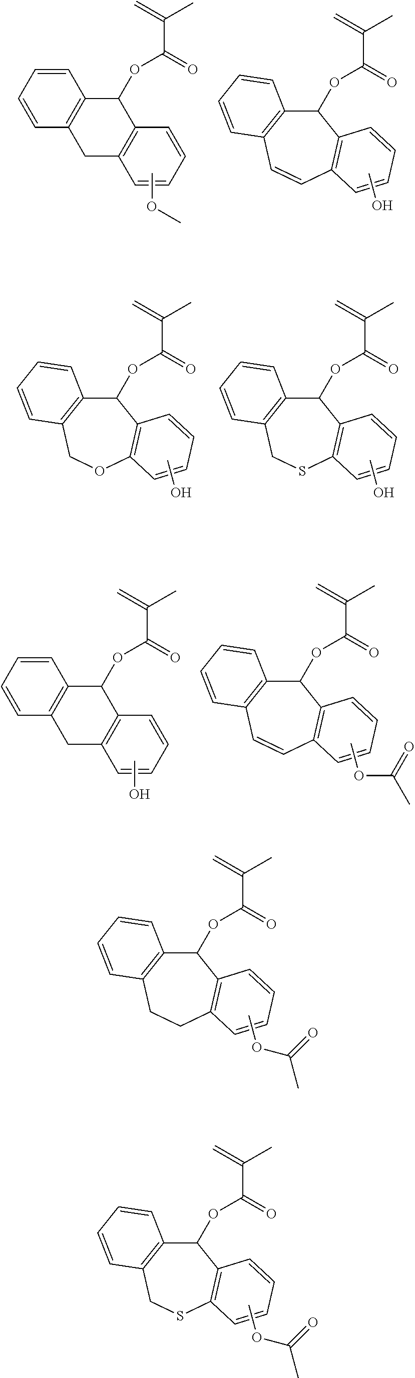

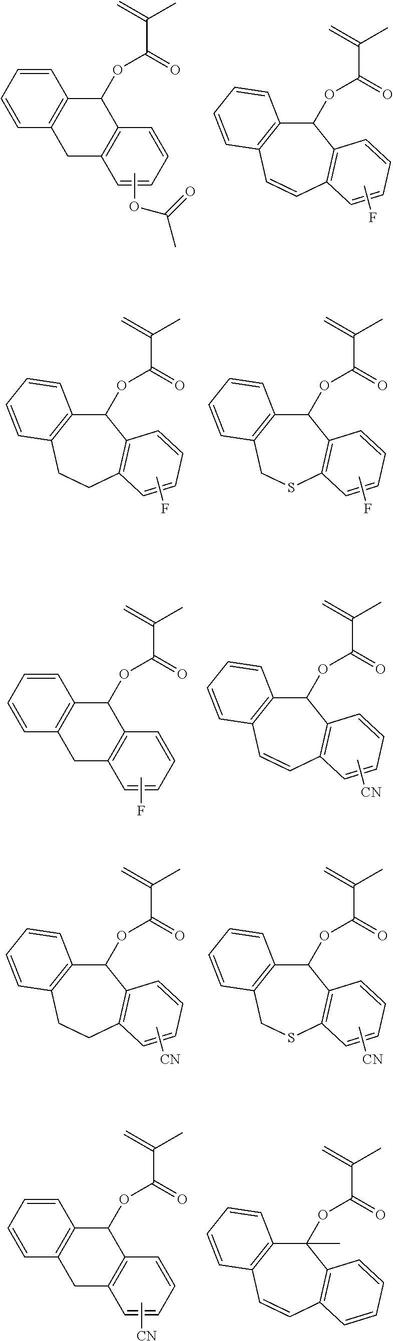

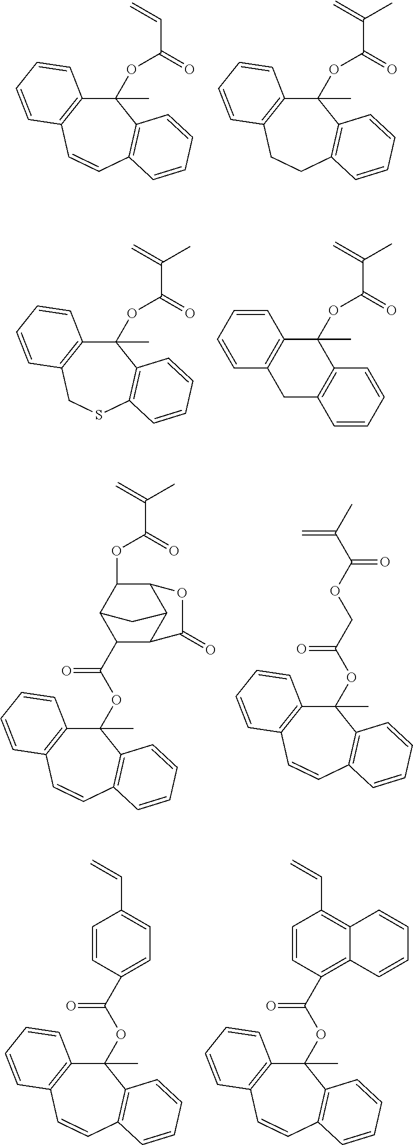

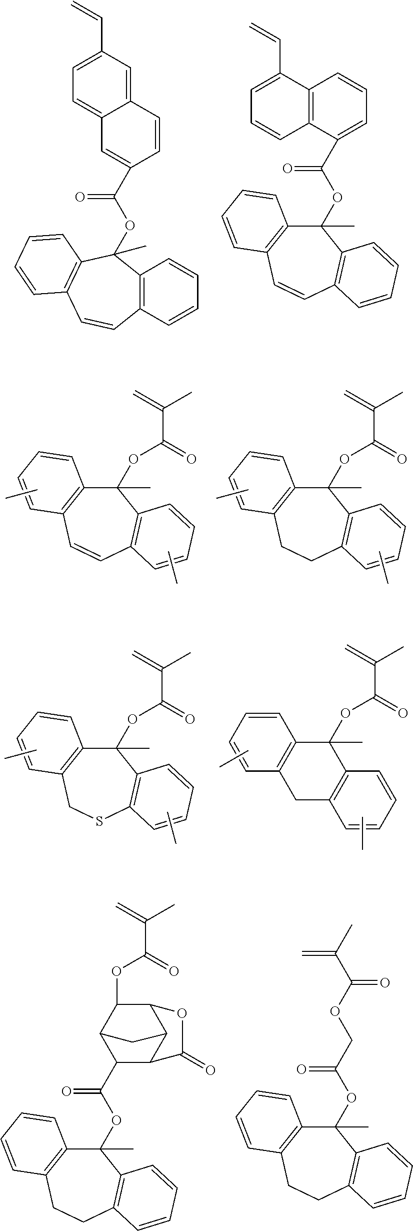

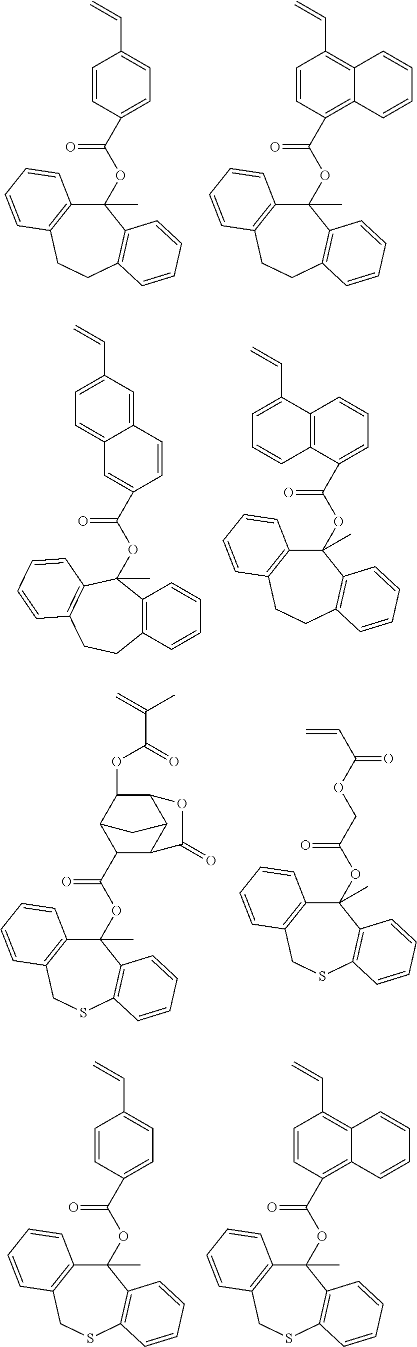

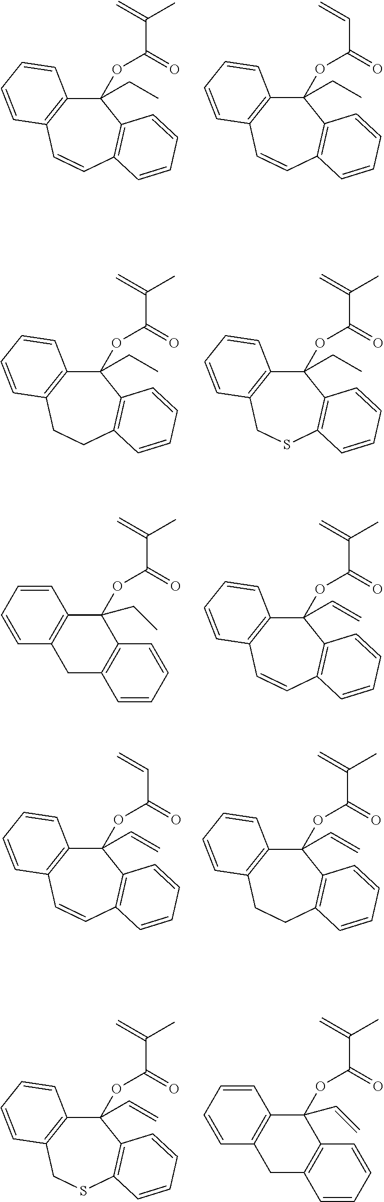

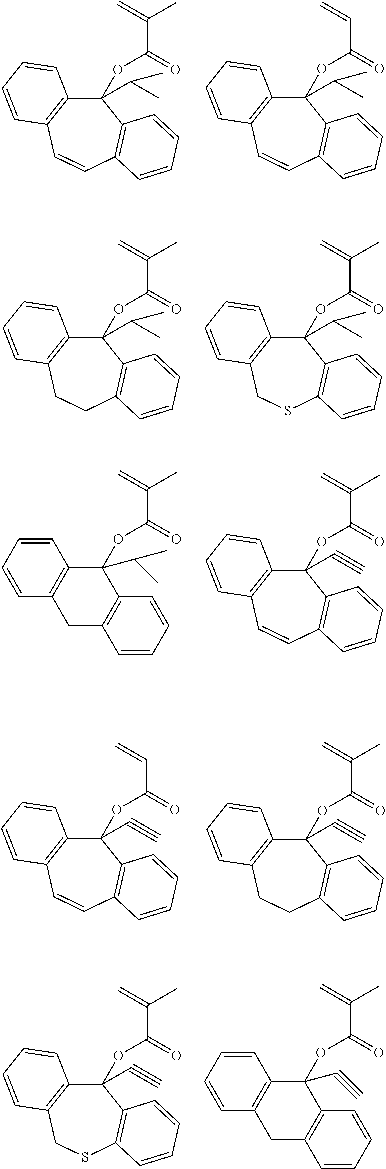

The acid labile group R² in recurring units (a1) may be a group having the general formula (A-3)-28.

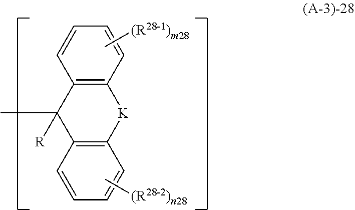

Herein R²⁸⁻¹ and R²⁸⁻² each are hydrogen, a C₁-C₄ alkyl, alkoxy, alkanoyl or alkoxycarbonyl, hydroxyl, C₆-C₁₀ aryl, halogen or cyano group, R is as defined above, K is carbonyl, ether, sulfide, —S(═O)— or —S(═O)₂—, and m28 and n28 are an integer of 1 to 4.

Examples of the monomer from which recurring units (a1) having an acid labile group of formula (A-3)-28 substituted thereon are derived are shown below.

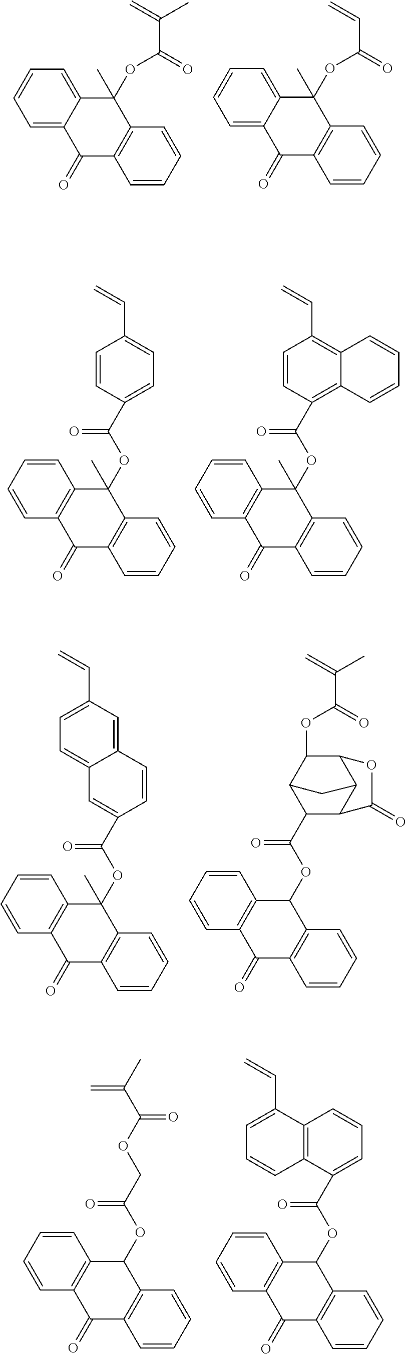

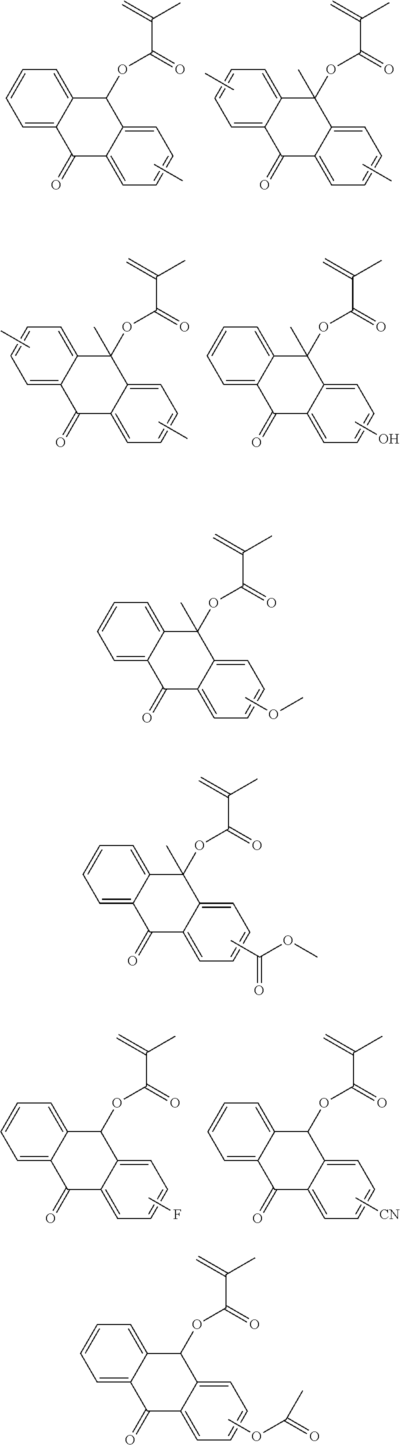

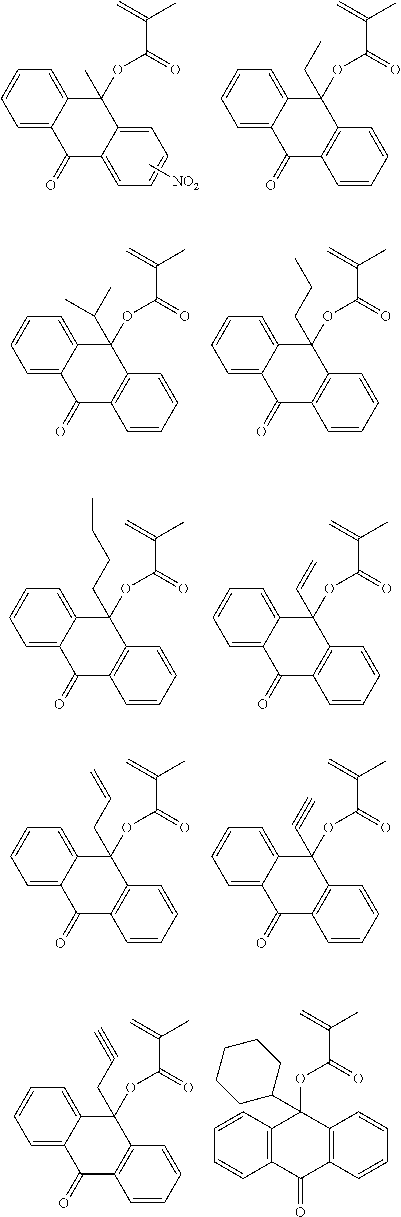

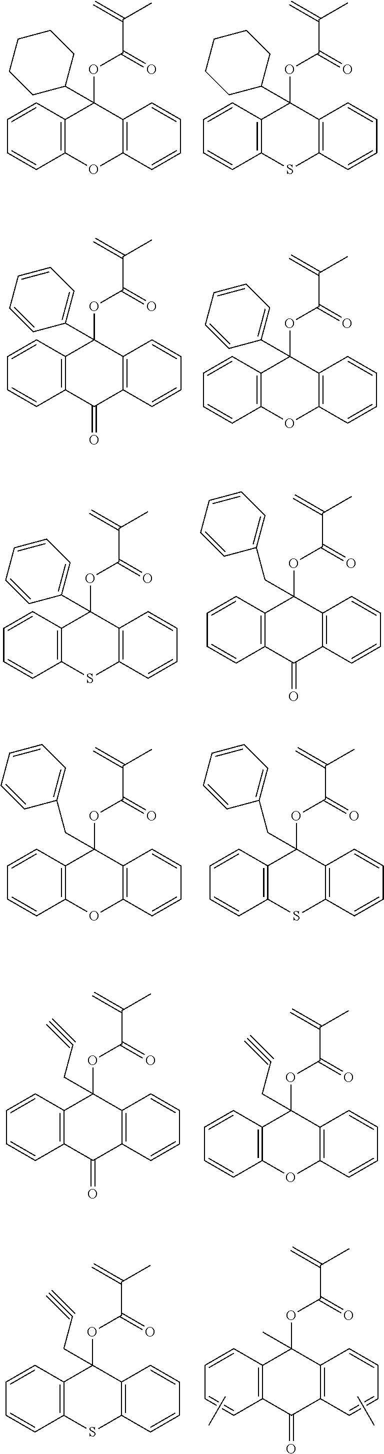

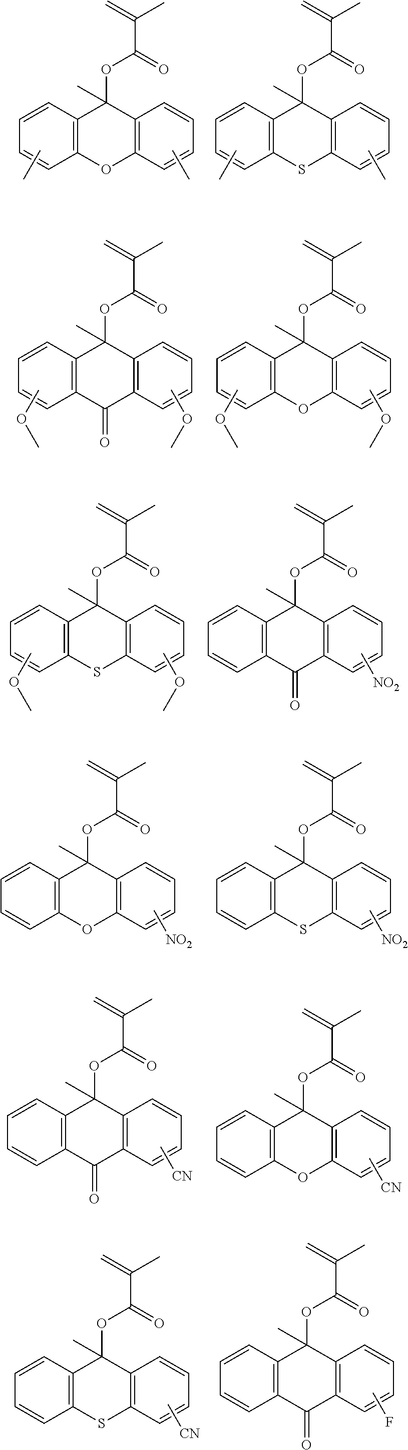

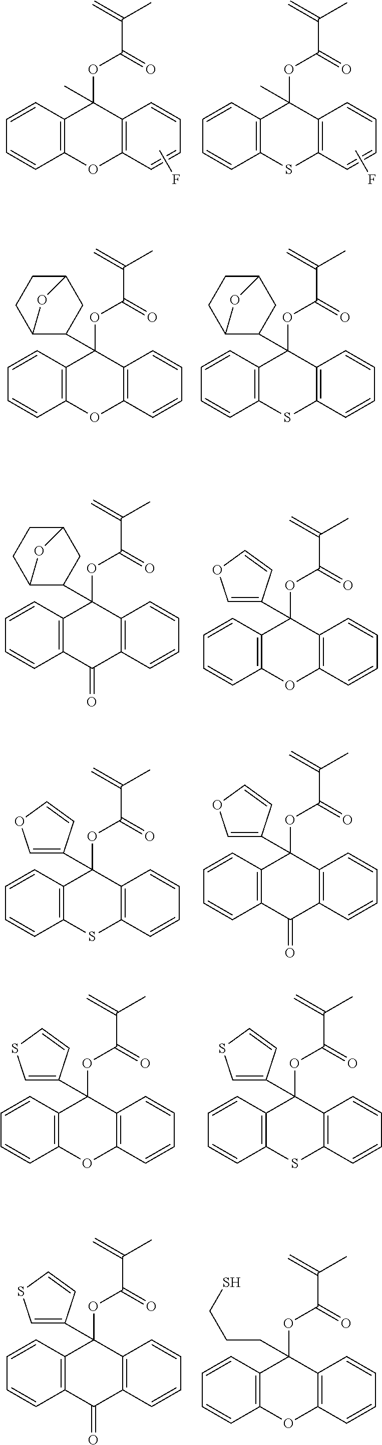

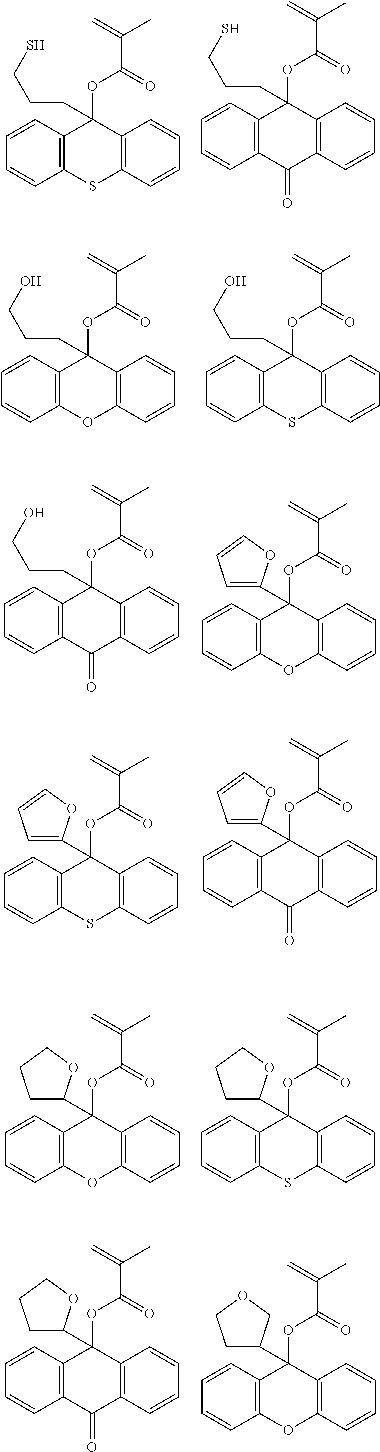

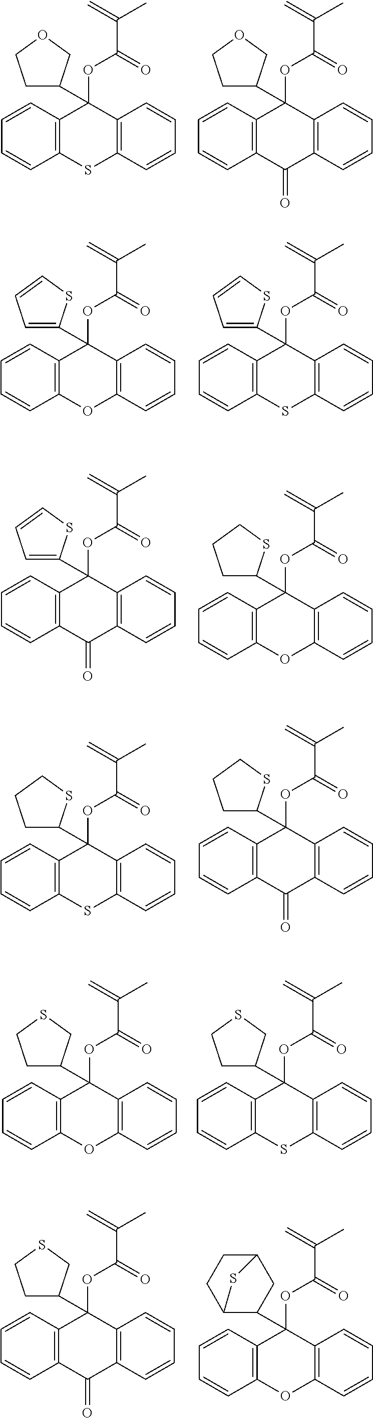

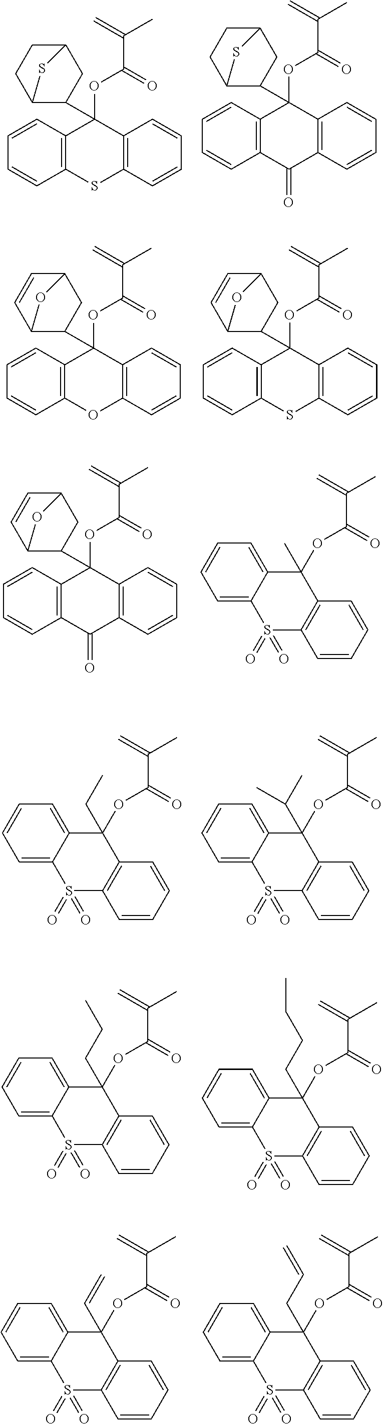

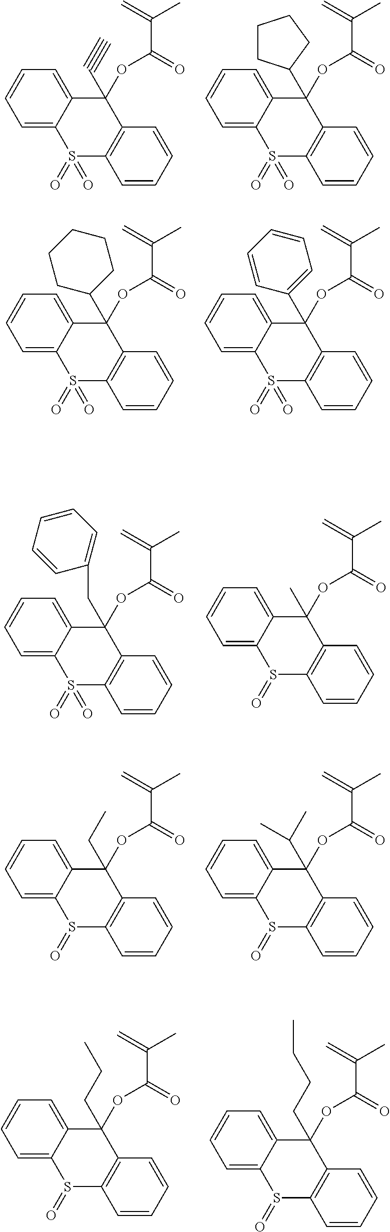

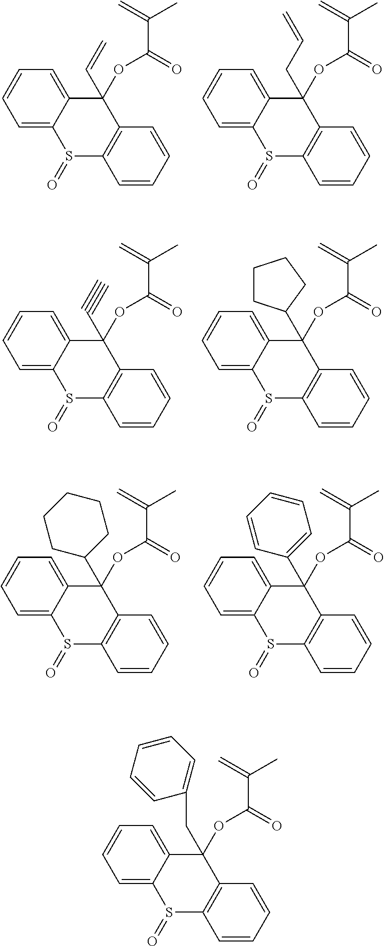

Examples of the monomer from which recurring units (c2) and (c3) of sulfonium salt in formula (2) are derived are shown below.

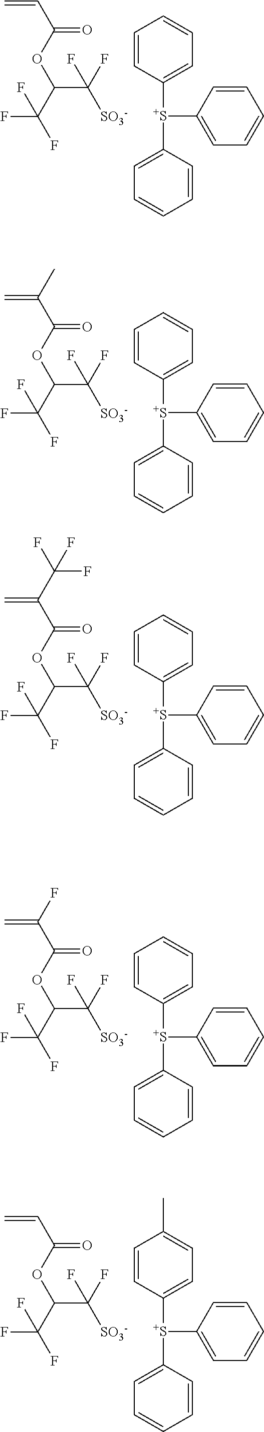

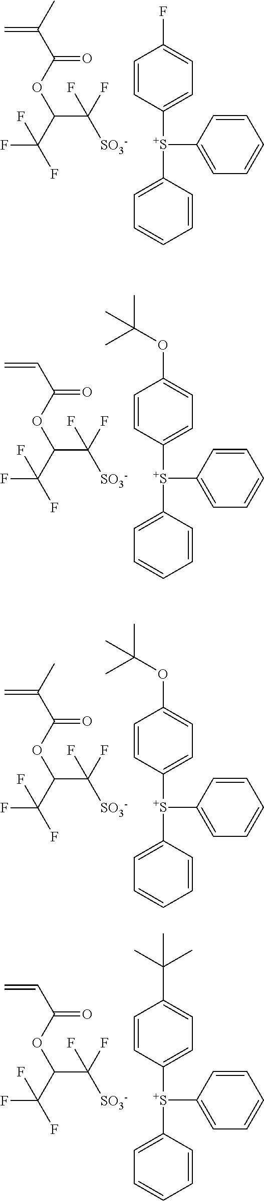

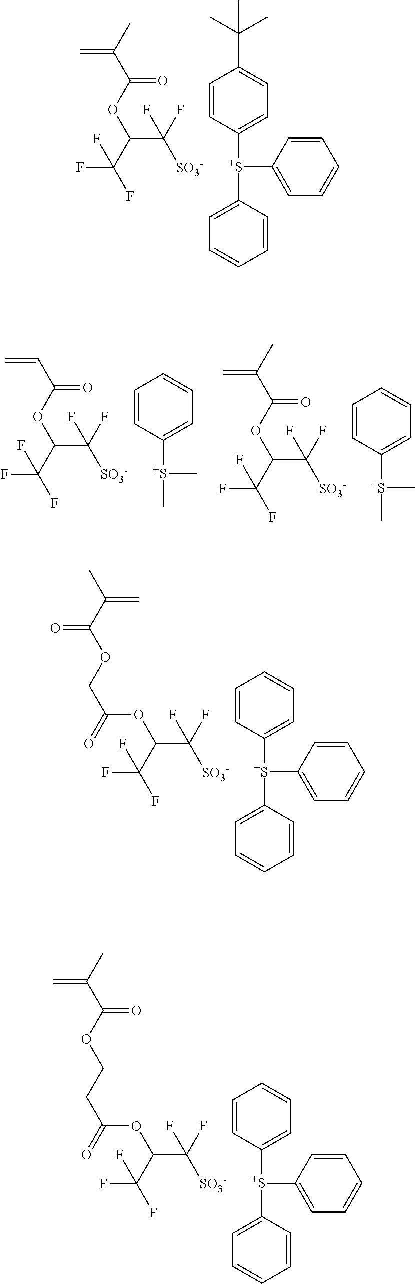

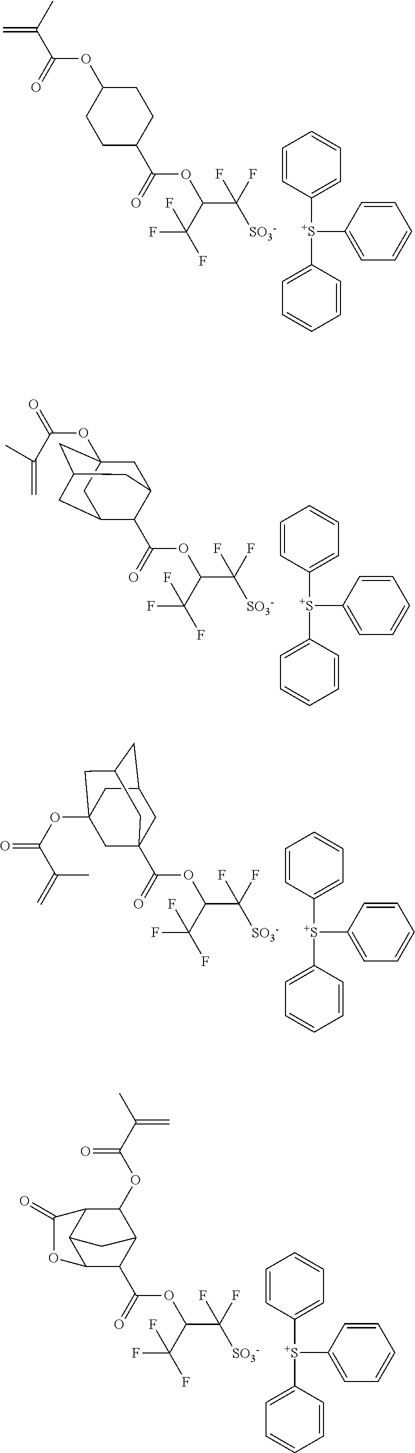

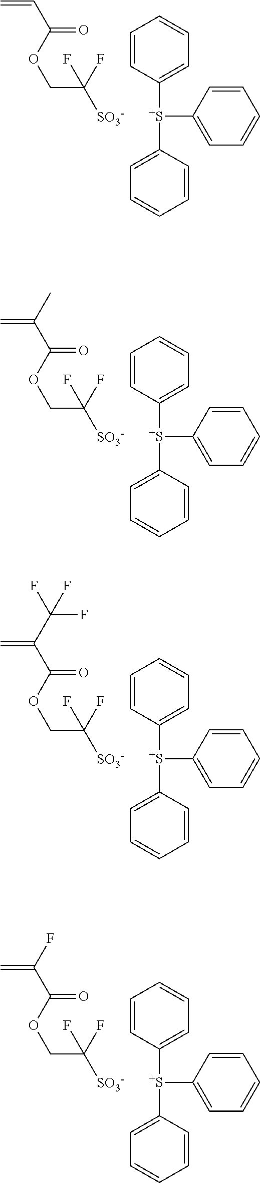

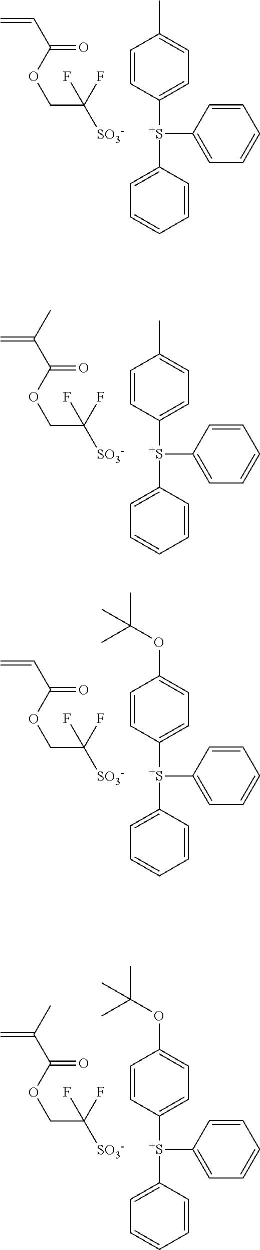

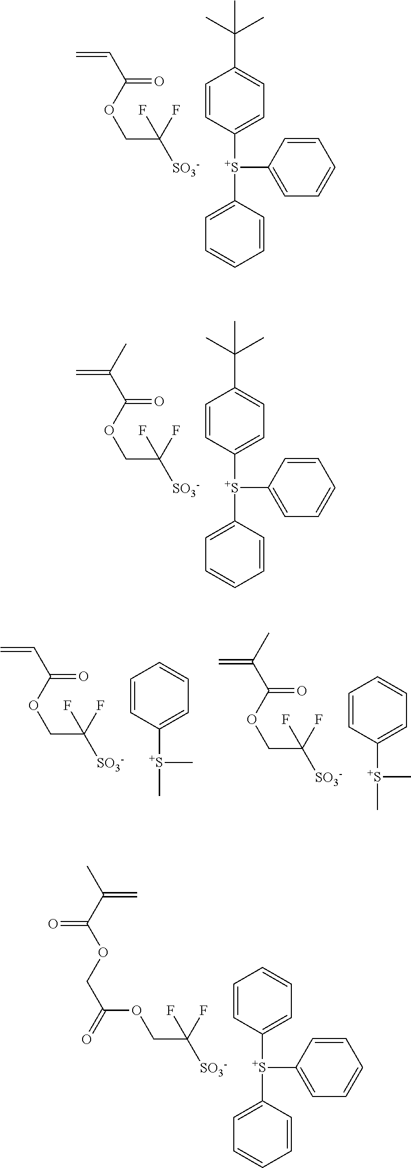

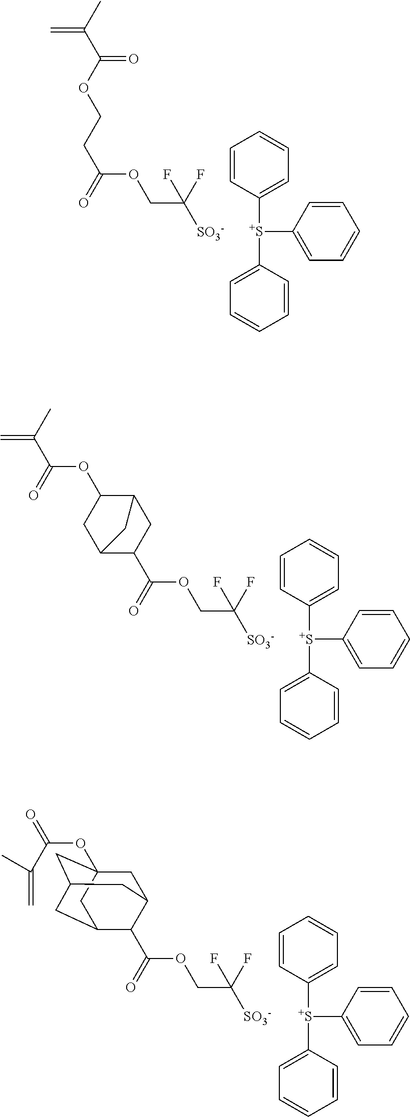

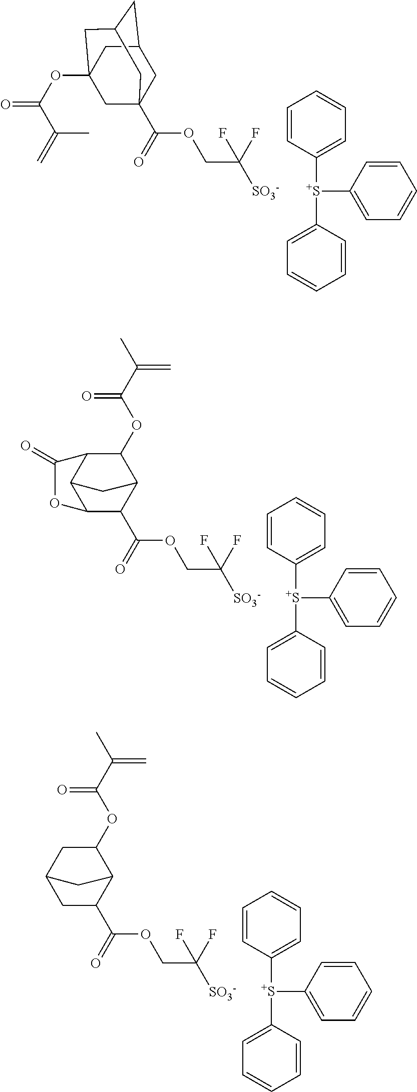

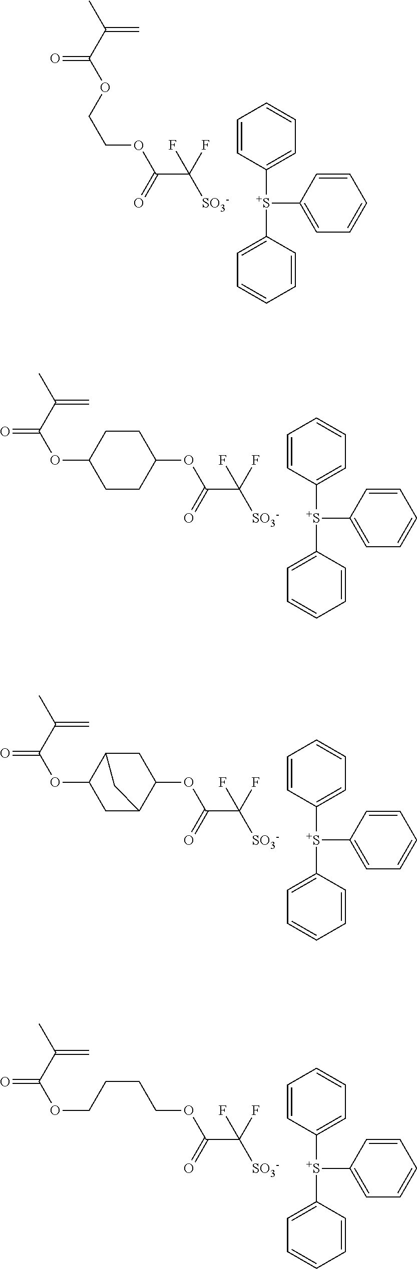

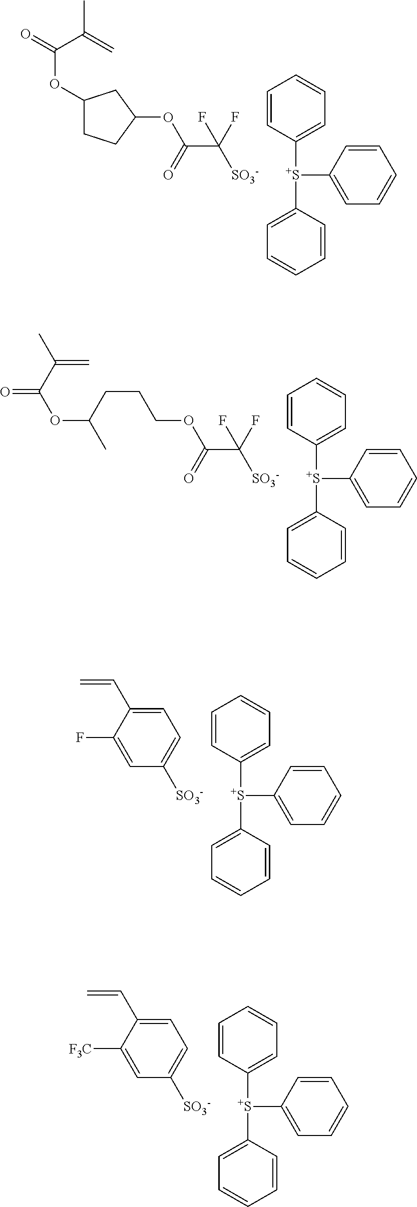

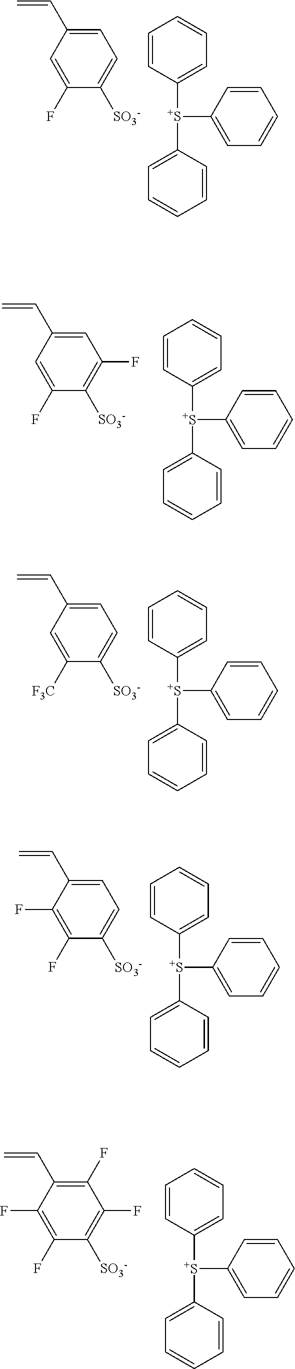

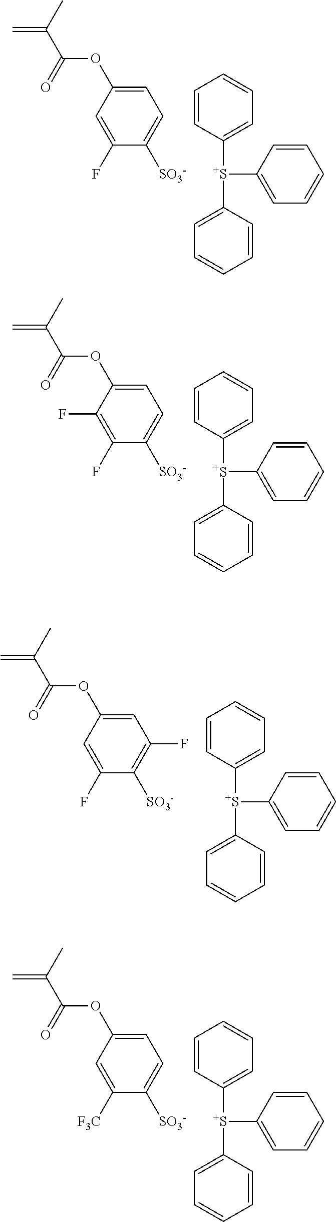

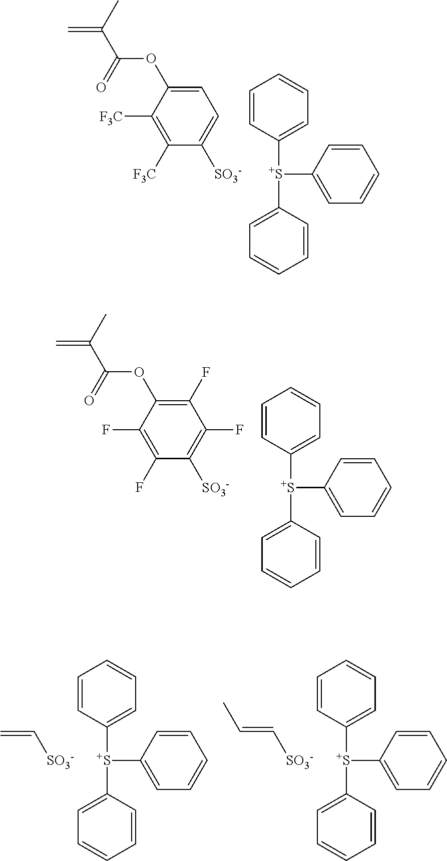

While the polymer is characterized by comprising, in copolymerized form, recurring units (a1) of acid labile group-substituted (meth)acrylic acid, styrenecarboxylic acid or vinylnaphthalenecarboxylic acid and/or recurring units (a2) having an acid labile group-substituted phenolic hydroxyl group, and recurring units (b1) of a magnesium, copper or zinc salt of (meth)acrylic acid, styrenecarboxylic acid or vinylnaphthalenecarboxylic acid and/or recurring units (b2) of a cesium salt of (meth)acrylic acid, styrenecarboxylic acid or vinylnaphthalenecarboxylic acid, recurring units (d) having a phenolic hydroxyl group as the adhesive group may be further copolymerized.

Examples of the monomer from which recurring units (d) having a phenolic hydroxyl group are derived are shown below.

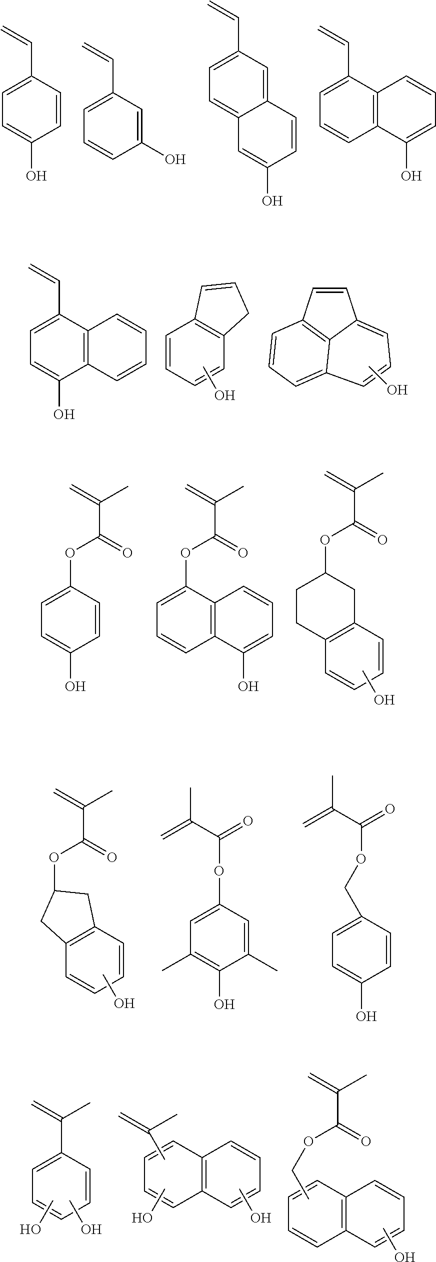

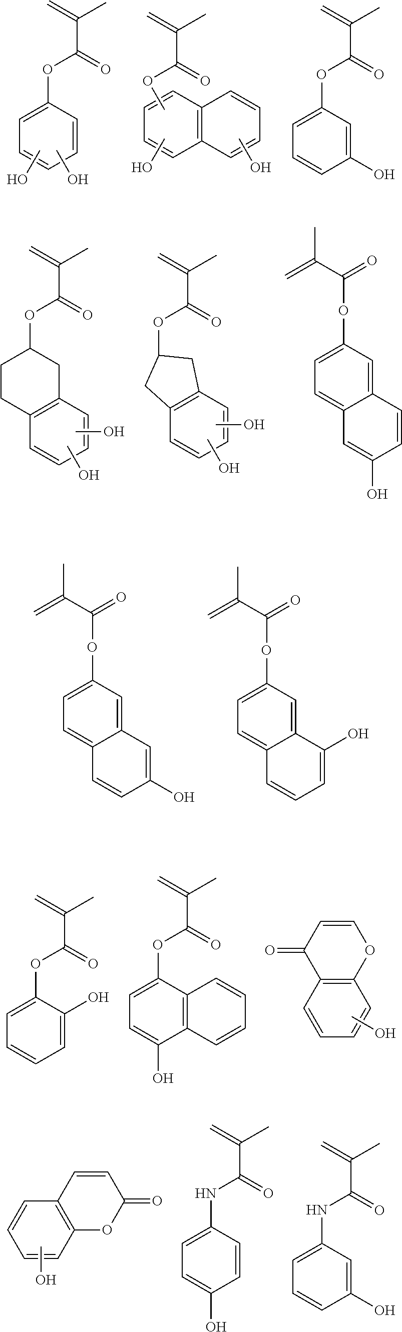

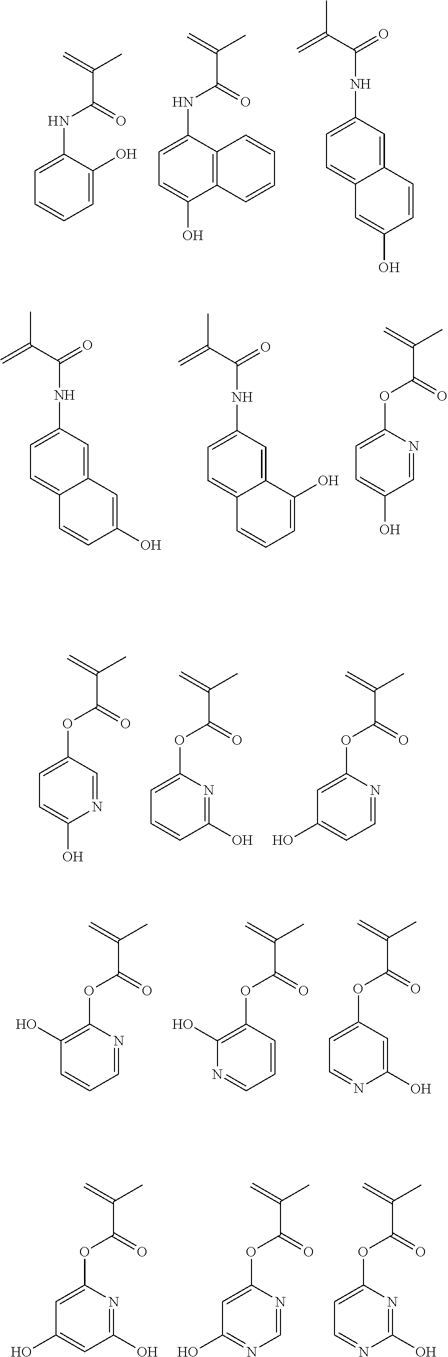

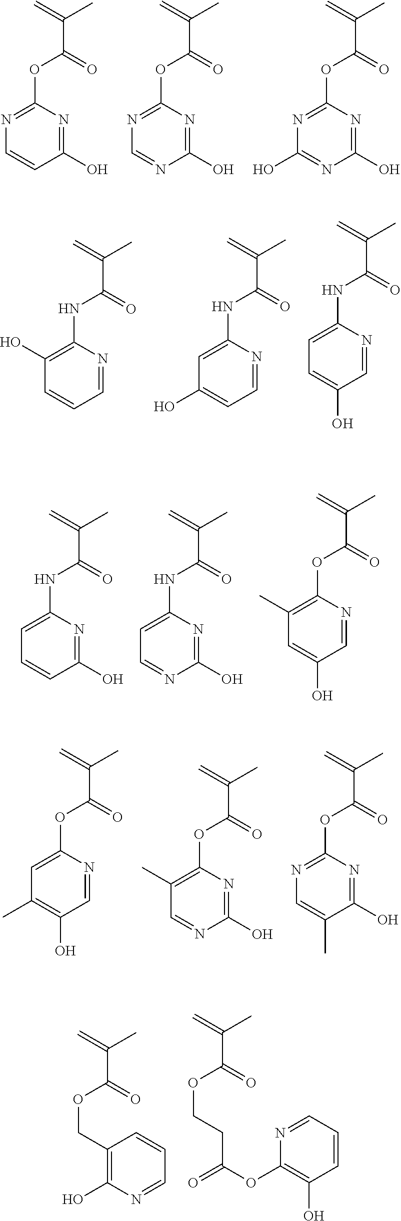

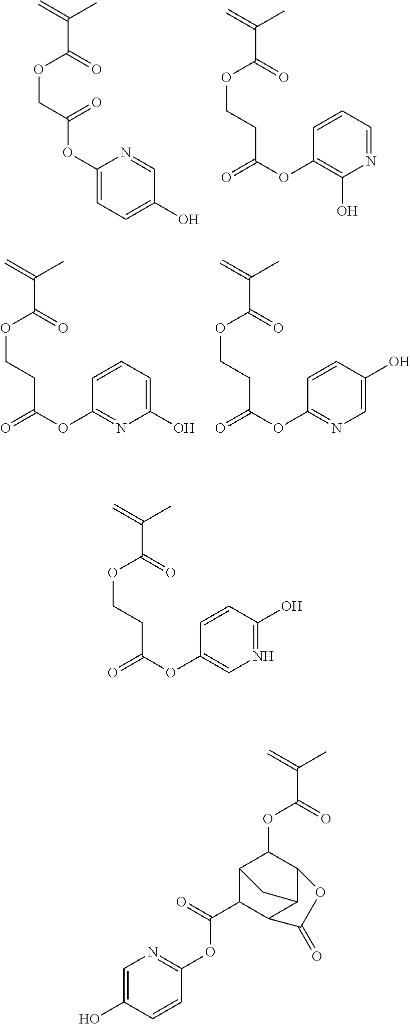

Recurring units (e) having another adhesive group may also be copolymerized. Examples of the other adhesive group include hydroxyl other than the phenolic hydroxyl, carboxyl, lactone ring, carbonate, thiocarbonate, carbonyl, cyclic acetal, ether, ester, sulfonic acid ester, cyano, amide, and —O—C(═O)-G- wherein G is sulfur or NH.

Examples of the monomer from which recurring units (e) having another adhesive group are derived are shown below.

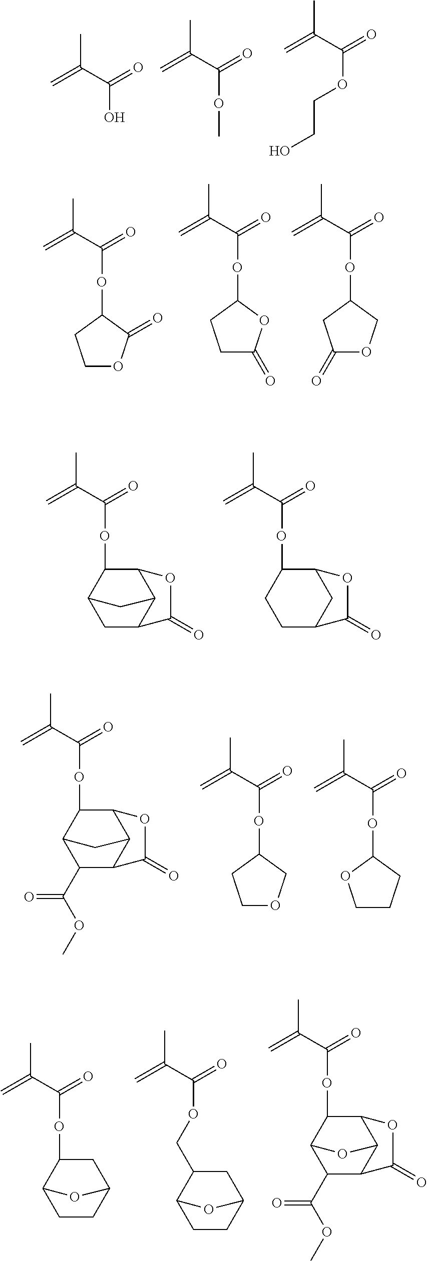

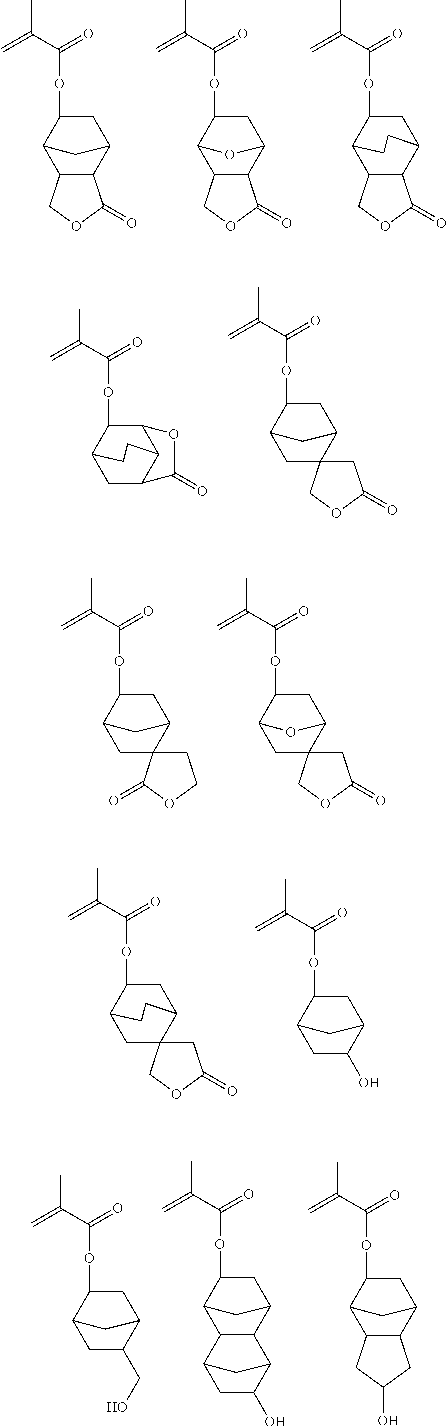

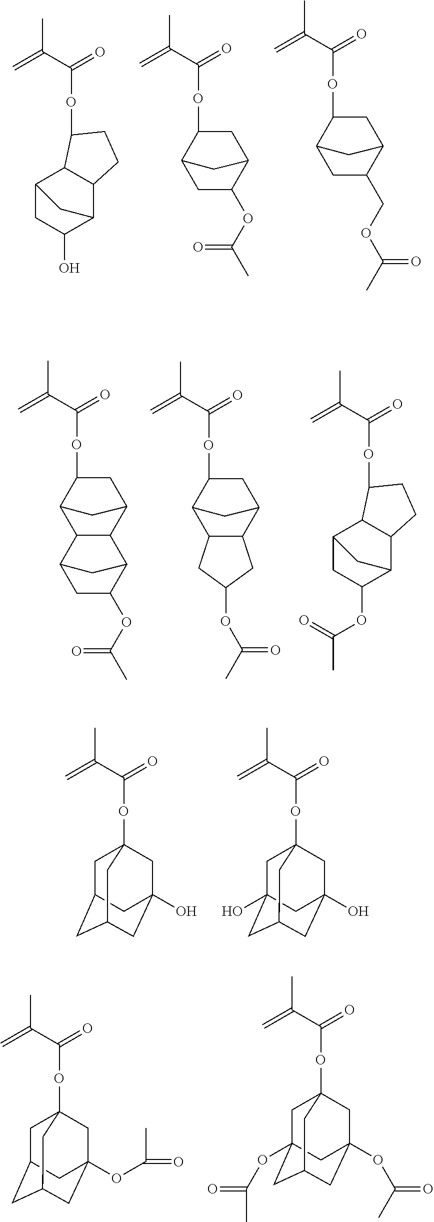

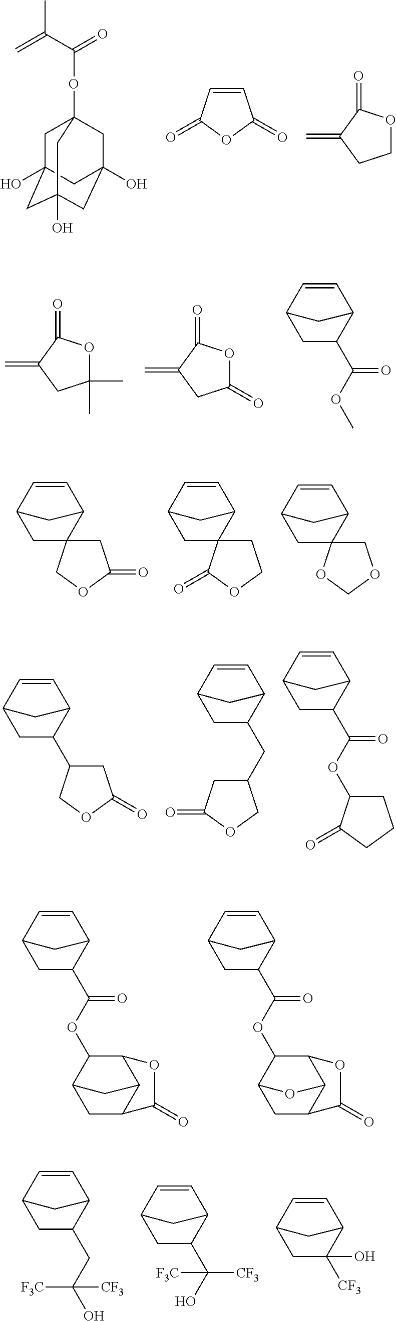

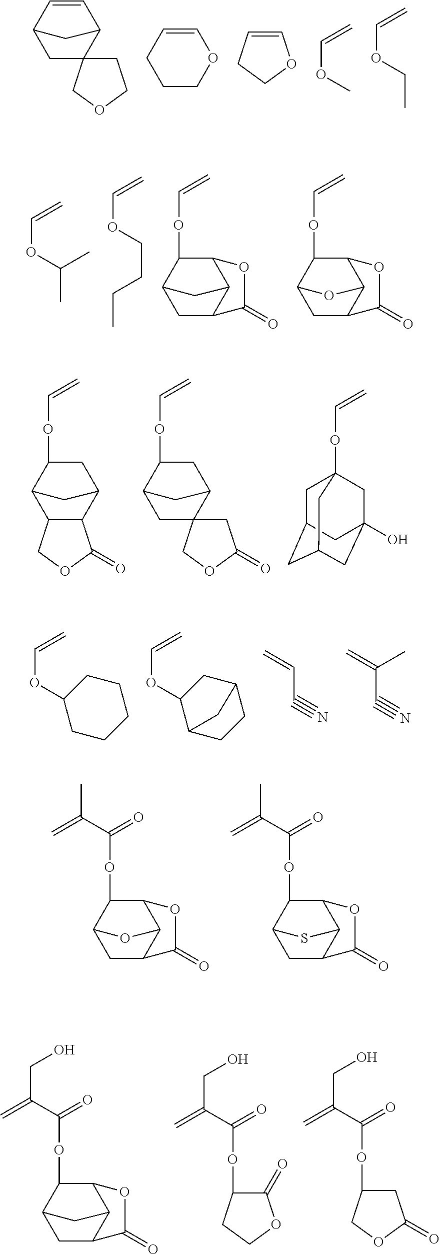

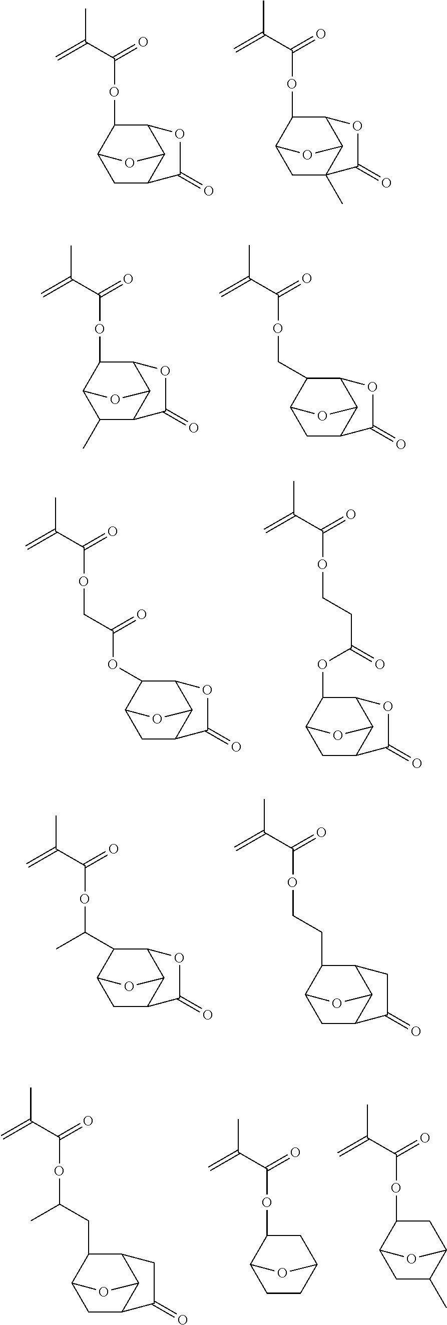

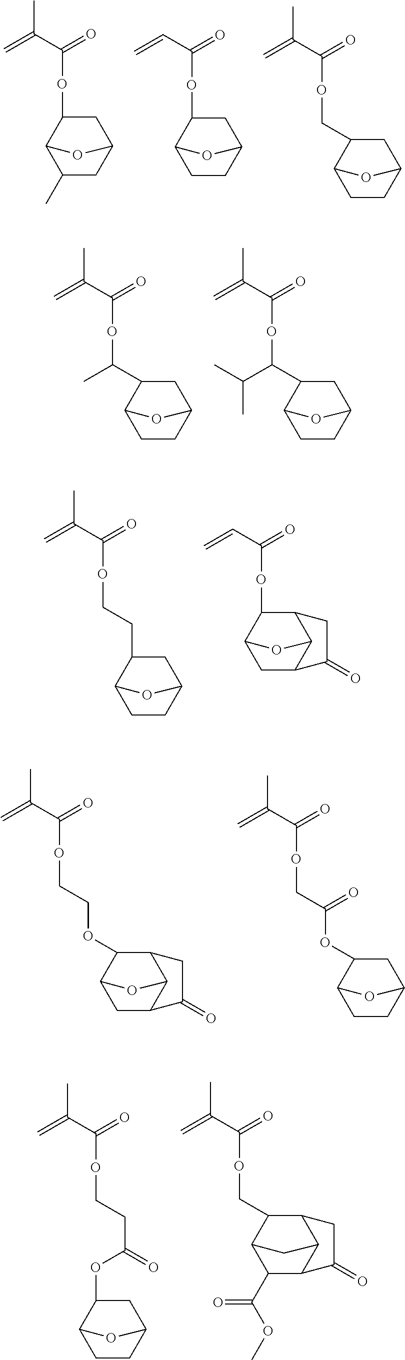

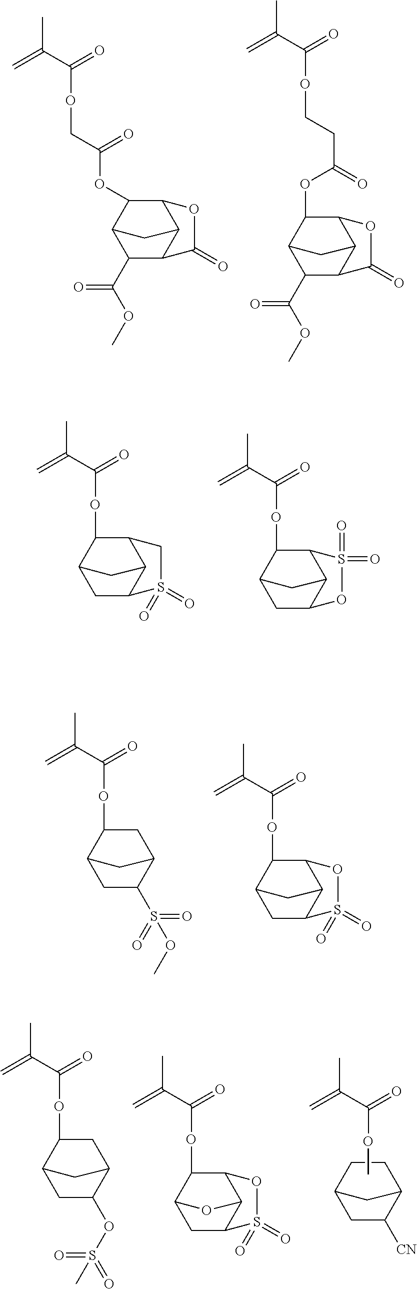

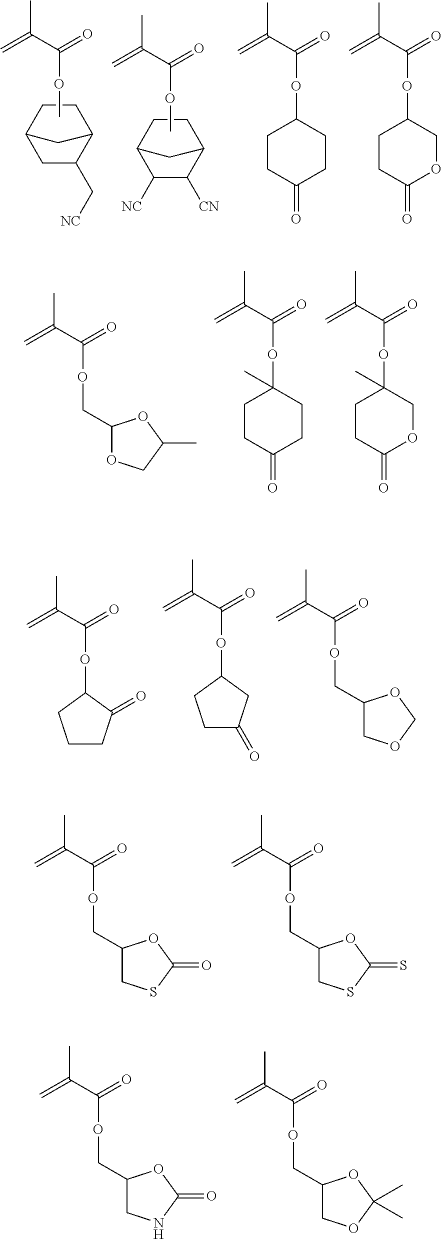

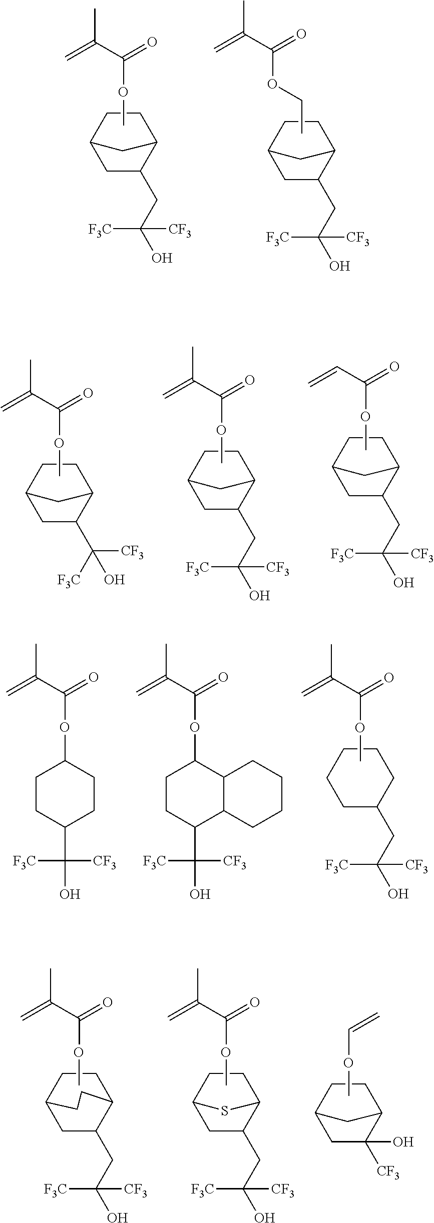

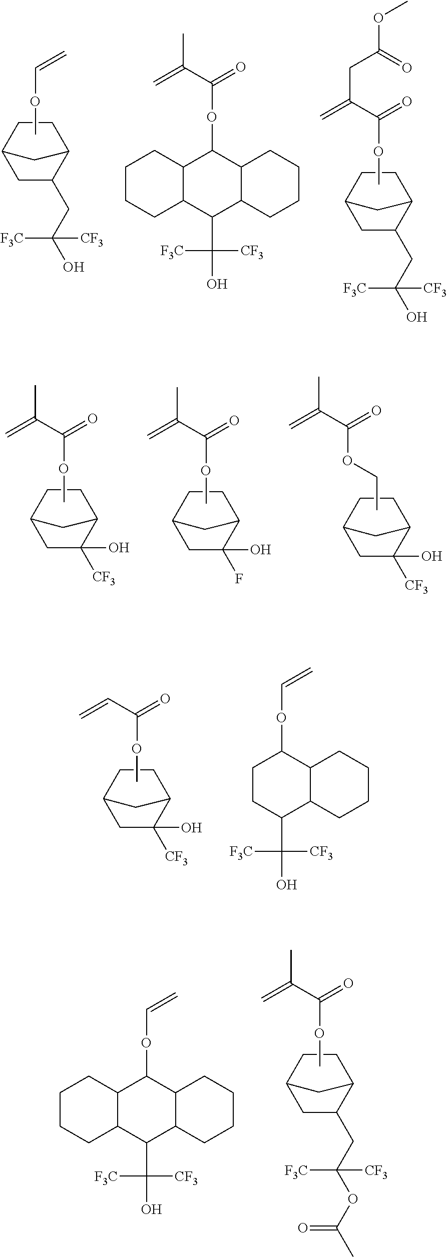

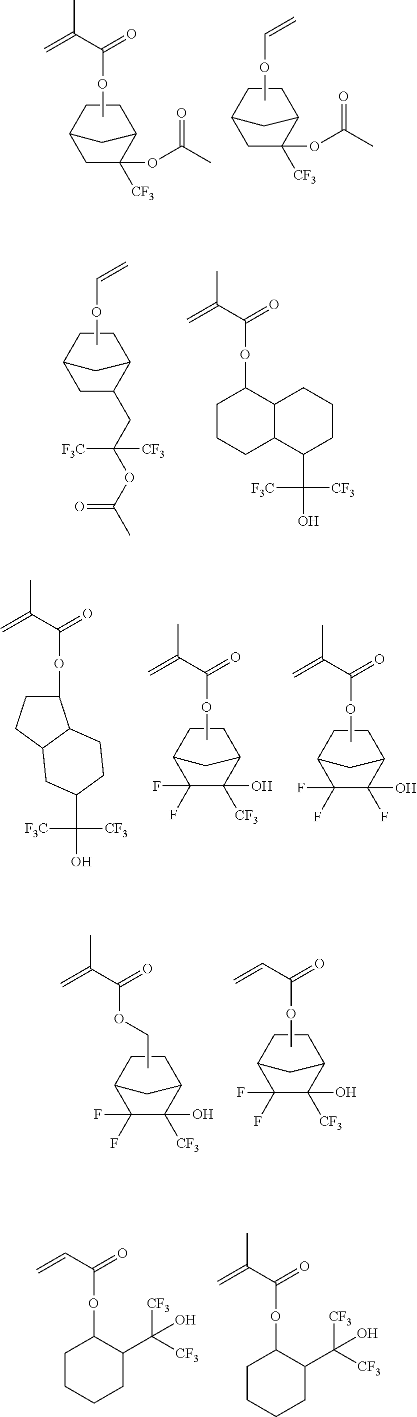

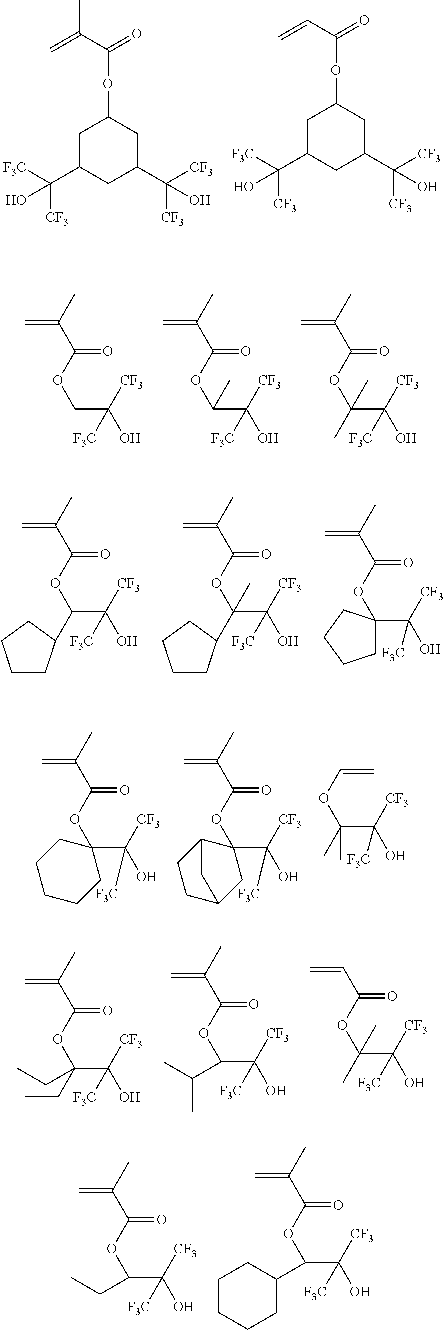

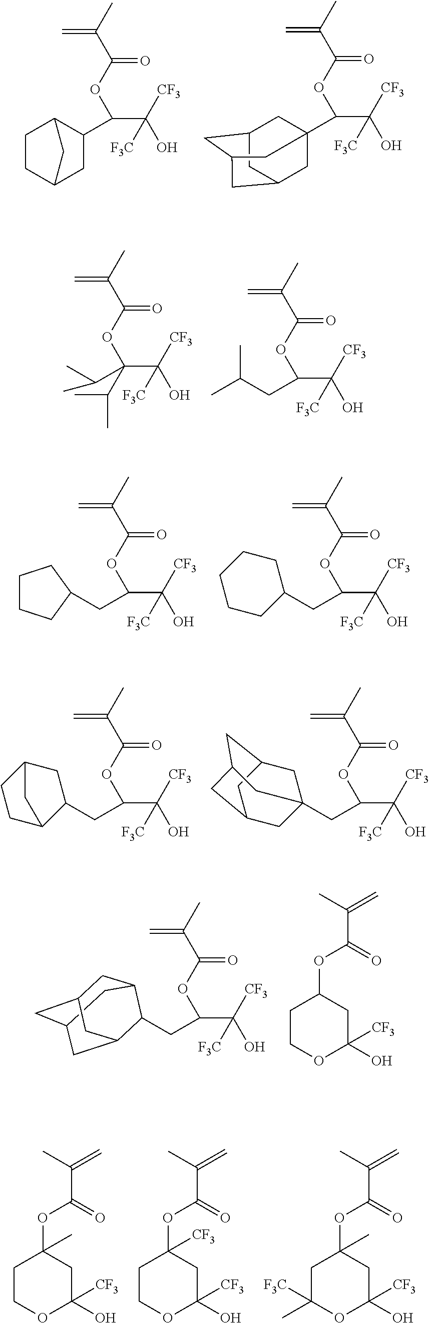

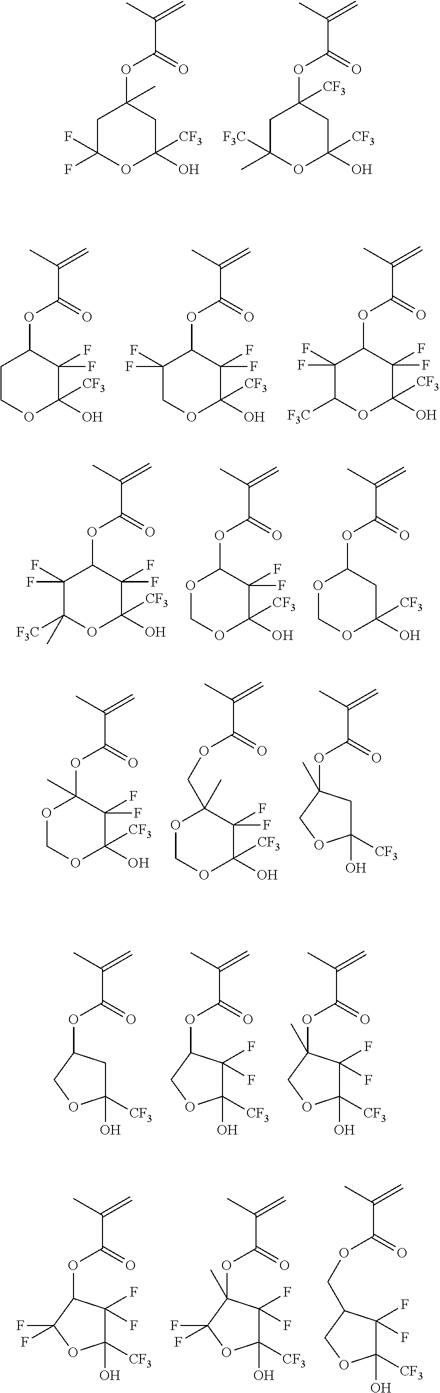

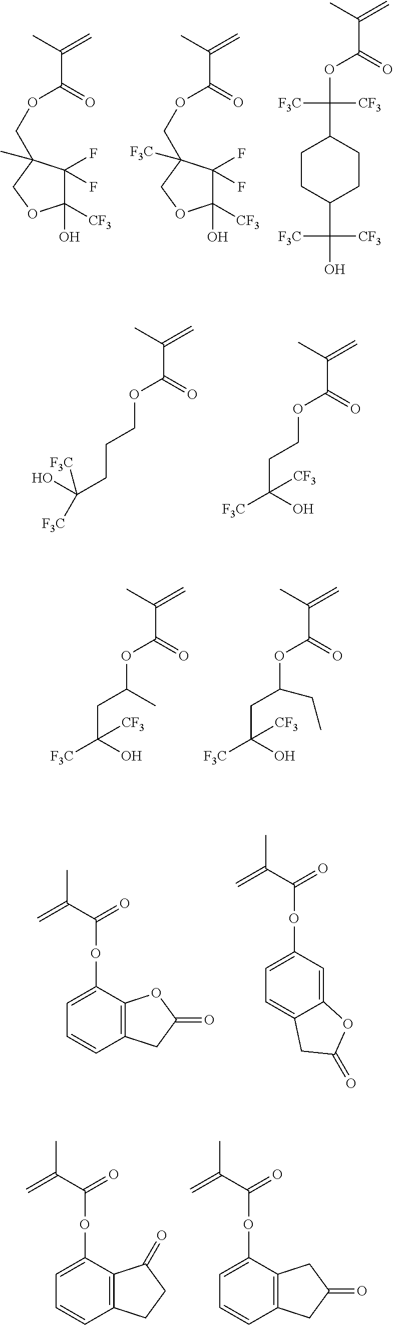

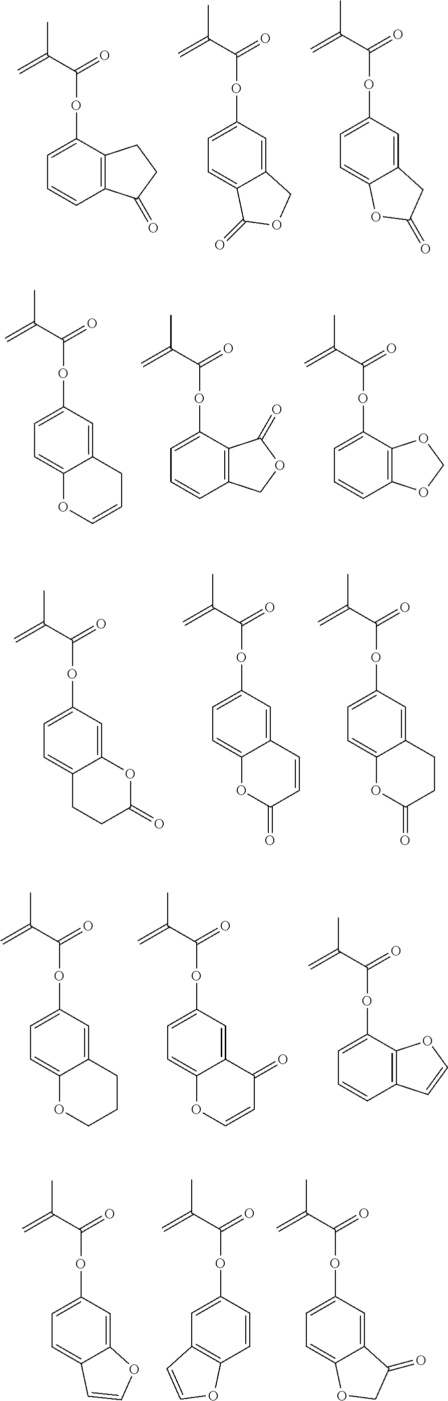

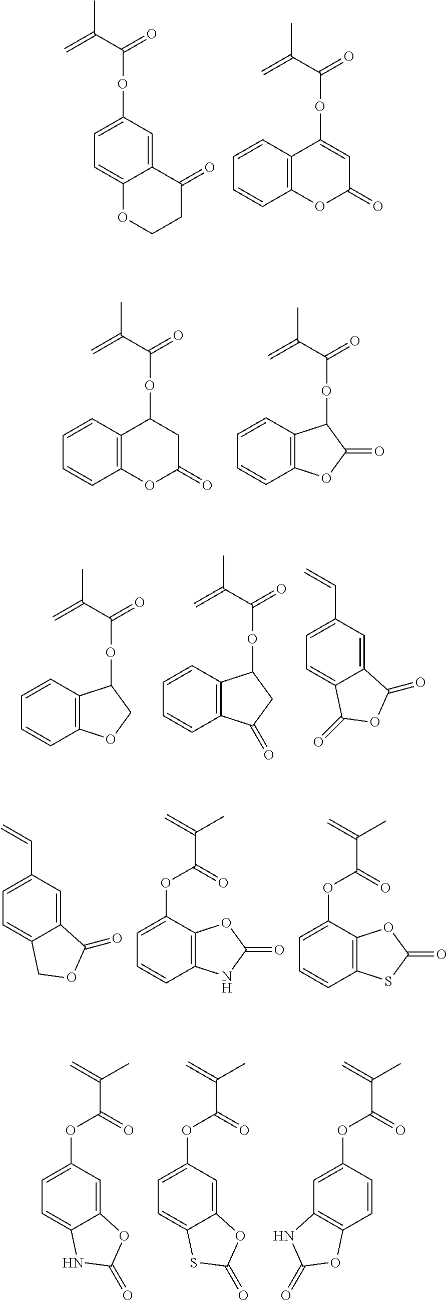

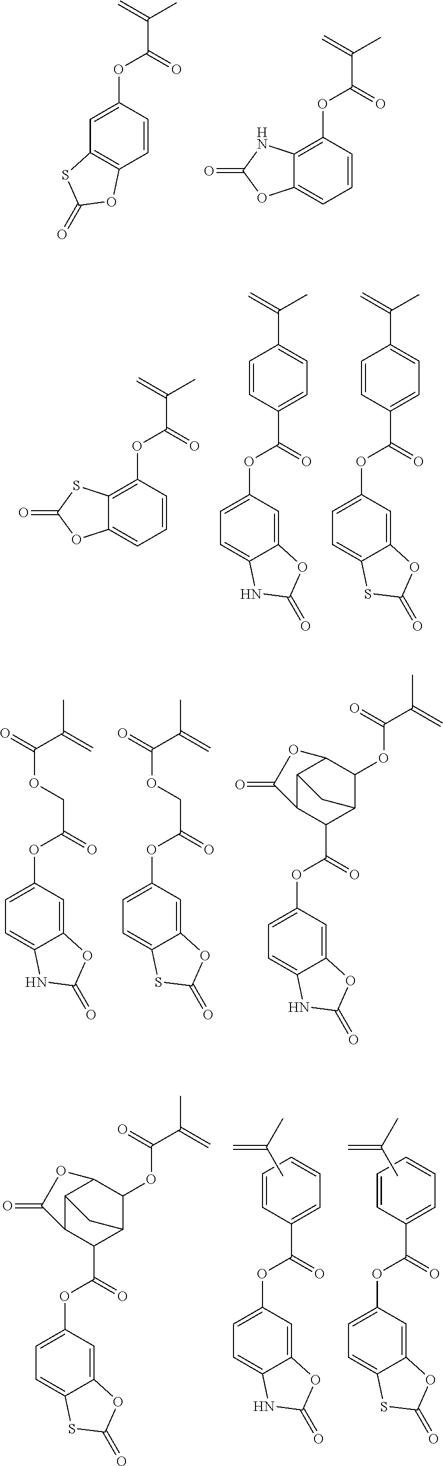

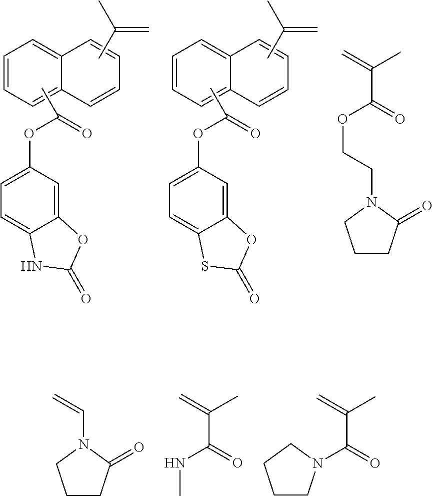

In the case of a hydroxyl-containing monomer, a corresponding monomer in which the hydroxyl group has been replaced by an acetal group which is susceptible to deprotection with acid, typically ethoxyethoxy, may be used, and polymerization be followed by deprotection with weak acid and water. Alternatively, the hydroxyl group may have been replaced by an acetyl, formyl or pivaloyl group, and polymerization be followed by alkaline hydrolysis.

Further, another monomer (f) may be copolymerized, for example, indene, benzofuran, benzothiophene, acenaphthylene, chromone, coumarin, norbornadiene, and derivatives thereof. Examples are shown below.

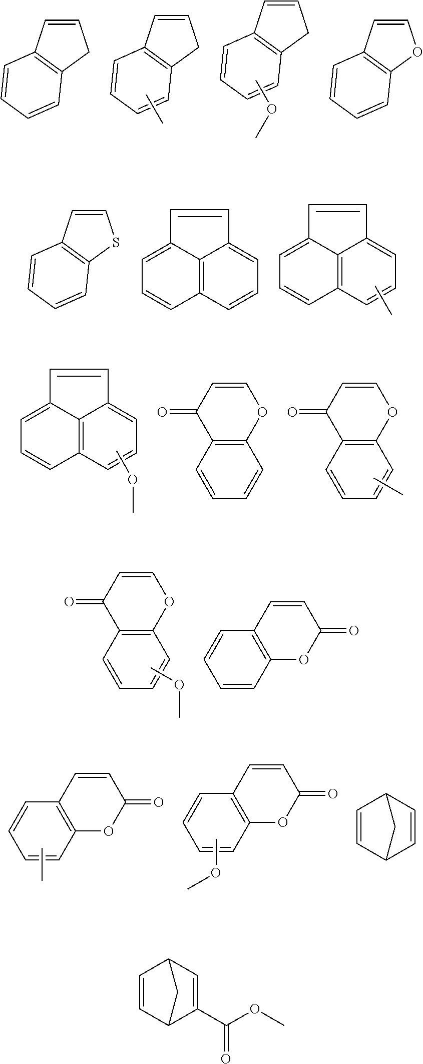

Examples of recurring units (g) other than the foregoing which can be copolymerized herein include styrene, vinylnaphthalene, vinylanthracene, vinylpyrene, and methyleneindane, but are not limited thereto.

In a copolymer having units (a1), (a2), (b1), (b2), (c1), (c2), (c3), (d), (e), (f), and (g) copolymerized therein, the copolymerization ratio may preferably fall in the range: 0≦a1≦0.9, 0≦a2≦0.9, 0<a1+a2≦0.9, 0≦b1≦0.8, 0≦b2≦0.8, 0<b1+b2≦0.8, 0≦c1≦0.35, 0≦c2≦0.35, 0≦c3≦0.35, 0≦c1+c2+c3≦0.3, 0≦d≦0.9, 0≦e≦0.9, 0≦f≦0.5, and 0≦g≦0.5;

more preferably 0≦a1≦0.8, 0≦a2≦0.8, 0.1≦a1+a2≦0.8, 0≦b1≦0.6, 0≦b2≦0.6, 0.001≦b1+b2≦0.6, 0≦c1≦0.34, 0≦c2≦0.34, 0≦c3≦0.34, 0≦c1+c2+c3≦0.3, 0≦d≦0.8, 0≦e≦0.8, 0≦f≦0.4, and 0≦g≦0.4;
even more preferably 0≦a1≦0.75, 0≦a2≦0.75, 0.15≦a1+a2≦0.75, 0≦b1≦0.5, 0≦b2≦0.5, 0.002≦b1+b2≦0.5, 0≦c1≦0.3, 0≦c2≦0.3, 0≦c3≦0.3, 0≦c1+c2+c3≦0.3, 0≦d≦0.7, 0≦e≦0.7, 0≦f≦0.3, and 0≦g≦0.3; also preferably 0<d+e≦0.9, more preferably 0<d+e≦0.8, and even more preferably 0<d+e≦0.7, provided a1+a2+b≦1+b2+c≦1+c2+c3+d+e+f+g=1.

The polymer as used herein may be synthesized by any desired method, for example, by dissolving monomers corresponding to the respective units (a1), (a2), (b1), (b2), (c1), (c2), (c3), (d), (e), (f) and (g) in an organic solvent, adding a radical polymerization initiator thereto, and effecting heat polymerization. Examples of the organic solvent which can be used for polymerization include toluene, benzene, tetrahydrofuran, diethyl ether and dioxane. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. Preferably the system is heated at 50 to 80° C. for polymerization to take place. The reaction time is 2 to 100 hours, preferably 5 to 20 hours.

When hydroxystyrene or hydroxyvinylnaphthalene is to be copolymerized, one possible procedure is by carrying out polymerization using acetoxystyrene or acetoxyvinylnaphthalene instead of hydroxystyrene or hydroxyvinylnaphthalene, and effecting alkaline hydrolysis for deprotection of the acetoxy group for converting back to polyhydroxystyrene or hydroxypolyvinylnaphthalene. Suitable bases used for alkaline hydrolysis include ammonia water and triethylamine. The reaction conditions include a temperature of −20° C. to 100° C., preferably 0° C. to 60° C. and a time of 0.2 to 100 hours, preferably 0.5 to 20 hours.

The polymer used herein should preferably have a weight average molecular weight (Mw) in the range of 1,000 to 500,000, and more preferably 2,000 to 30,000, as measured in tetrahydrofuran solvent by GPC versus polystyrene standards. With a Mw of at least 1,000, the resist composition is fully heat resistant. A polymer with a Mw of up to 500,000 may be devoid of a loss of alkaline solubility or a footing phenomenon after pattern formation.

If a multi-component polymer has a broad molecular weight distribution or dispersity (Mw/Mn), which indicates the presence of lower and higher molecular weight polymer fractions, there is a possibility that following exposure, foreign matter is left on the pattern or the pattern profile is exacerbated. The influences of molecular weight and dispersity become stronger as the pattern rule becomes finer. Therefore, the multi-component copolymer should preferably have a narrow dispersity (Mw/Mn) of 1.0 to 2.0, especially 1.0 to 1.5, in order to provide a resist composition suitable for micropatterning to a small feature size.

While the polymer is characterized by comprising, in copolymerized form, recurring units (a1) of acid labile group-substituted (meth)acrylic acid, styrenecarboxylic acid or vinylnaphthalenecarboxylic acid and/or recurring units (a2) having an acid labile group-substituted phenolic hydroxyl group, and recurring units (b1) of a magnesium, copper or zinc salt of (meth)acrylic acid, styrenecarboxylic acid or vinylnaphthalenecarboxylic acid and/or recurring units (b2) of a cesium salt of (meth)acrylic acid, styrenecarboxylic acid or vinylnaphthalenecarboxylic acid, it is acceptable to use a blend of two or more such polymers which differ in compositional ratio, molecular weight or dispersity. It is also acceptable for sensitivity adjustment to use a blend of a polymer comprising recurring units (b1) of a magnesium, copper or zinc salt of (meth)acrylic acid, styrenecarboxylic acid or vinylnaphthalenecarboxylic acid and/or recurring units (b2) of a cesium salt of (meth)acrylic acid, styrenecarboxylic acid or vinylnaphthalenecarboxylic acid with another polymer free of recurring units (b1) and/or (b2).

The polymer defined above is especially suited as a base resin in a positive resist composition. When a positive resist composition is prepared by using the relevant polymer as the base resin and combining it with suitable other components such as organic solvent, acid generator, dissolution inhibitor, basic compound, and surfactant, the resist composition has a very high sensitivity in that the polymer in the exposed region accelerates its dissolution rate in developer through catalytic reaction. The resist composition has many advantages including a high dissolution contrast, a high resolution, exposure latitude, process adaptability, a good pattern profile after exposure, high etch resistance, and minimized proximity bias due to controlled acid diffusion. Because of these advantages, the resist composition is fully viable in commercial processes and best suited as the micropatterning resist material for the fabrication of VLSIs.

Specifically, when an acid generator is added to formulate a chemically amplified positive resist composition capable of utilizing acid catalyzed reaction, a higher sensitivity is given and the aforementioned properties are further improved. When a dissolution inhibitor is added to the positive resist composition, the difference in dissolution rate between the exposed and unexposed regions is enhanced, with the resolution being further improved. When a basic compound is added, the rate of acid diffusion in the resist film can be suppressed, with the resolution being further improved. When a surfactant is added, the resist composition is further improved or controlled in coating operation.

In one embodiment, an acid generator is added to the resist composition in order that the composition function as a chemically amplified positive resist composition. Typical of the acid generator used herein is a photoacid generator (PAG) capable of generating an acid in response to actinic radiation or high-energy radiation. Suitable PAGs include sulfonium salts, iodonium salts, sulfonyldiazomethane, N-sulfonyloxyimide, and oxime-O-sulfonate acid generators. The PAGs may be used alone or in admixture of two or more. Exemplary acid generators are described in U.S. Pat. No. 7,537,880 (JP-A 2008-111103, paragraphs [0122] to [0142]).

Examples of the organic solvent used herein are described in JP-A 2008-111103, paragraphs [0144] to [0145], exemplary basic compounds or quenchers in paragraphs [0146]-[0164], and exemplary surfactants in paragraphs [0165]-[0166]. Examples of the dissolution inhibitor used herein are described in JP-A 2008-122932, paragraphs [0155]-[0178]. Also polymeric quenchers as described in JP-A 2008-239918 may be added. If necessary, acetylene alcohols may be added, for example, those described in JP-A 2008-122932, paragraphs [0179]-[0182].

Since the polymeric surfactant segregates at the surface of a resist film as coated, it is effective for rendering the resist pattern more rectangular. The polymeric quencher is effective for reducing a film loss and preventing the pattern from being rounded at the top when a protective topcoat for the immersion lithography is applied.

When used, the acid generator is preferably added in an amount of 0.1 to 50 parts by weight per 100 parts by weight of the polymer or base resin. When used, the basic compound or quencher is preferably added in an amount of 0.01 to 20 parts, more preferably 0.02 to 15 parts by weight per 100 parts by weight of the base resin. When used, the dissolution inhibitor is preferably added in an amount of 0.5 to 50 parts, more preferably 1.0 to 30 parts by weight per 100 parts by weight of the base resin. When used, the surfactant is preferably added in an amount of 0.0001 to 10 parts, more preferably 0.001 to 5 parts by weight per 100 parts by weight of the base resin. When used, the solvent is preferably added in an amount of 100 to 10,000 parts, more preferably 200 to 8,000 parts by weight per 100 parts by weight of the base resin.

Another embodiment of the invention is a pattern forming process comprising the steps of coating the resist composition defined above onto a substrate, baking the coating to form a resist film, exposing the resist film to high-energy radiation, and developing the exposed resist film with a developer.

The step of exposing the resist film to high-energy radiation may use EUV radiation having a wavelength of 3 to 15 nm or an accelerated electron beam, specifically an electron beam at an accelerating voltage of 1 to 150 keV. In the resist film, magnesium, copper or zinc forms a conductive metal salt which is an antistatic agent effective for preventing the resist film from being charged during EB image writing. This eliminates a need for an antistatic film on the resist film. In addition, since magnesium, copper or zinc has a strong absorption of EUV having a wavelength of 13.5 nm, the sensitivity of the resist is improved upon exposure to EUV by the mechanism that the outer shell electrons of magnesium, copper or zinc are excited, and the electrons transfer to the acid generator, whereby the efficiency of acid generation is enhanced.

When the resist composition, typically chemically amplified positive resist composition comprising the polymer of formula (1), an acid generator and a basic compound in an organic solvent is used for the microfabrication of various integrated circuits, any well-known lithography processes may be applied.

For example, the resist composition is applied onto a substrate for integrated circuit fabrication or a processable layer thereon (e.g., Si, SiO₂, SiN, SiON, TiN, WSi, BPSG, SOG, or organic antireflective coating) or a substrate for mask circuit fabrication or a processable layer thereon (e.g., Cr, CrO, CrON, MoSi, or SiO₂) by any suitable technique such as spin coating, roll coating, flow coating, dip coating, spray coating or doctor coating. The coating is prebaked on a hot plate at a temperature of 60 to 150° C. for 10 seconds to 30 minutes, preferably 80 to 120° C. for 30 seconds to 20 minutes to form a resist film having a thickness of 0.1 to 2.0 μm.

Next the resist film is exposed imagewise to high-energy radiation selected from among UV, DUV, EB, x-ray, excimer laser, γ-ray, synchrotron radiation, or EUV (or soft x-ray) directly or through a mask having the desired pattern. The exposure is preferably carried out to provide a dose of 1 to 200 mJ/cm², preferably 10 to 100 mJ/cm², or 0.1 to 100 μC/cm², preferably 0.5 to 50 μC/cm². This is followed by baking (PEB) on a hot plate at 60 to 150° C. for 10 seconds to 30 minutes, preferably at 80 to 120° C. for 30 seconds to 20 minutes.

Finally, the exposed resist film is developed with a developer which is an aqueous alkaline solution, typically a 0.1 to 5%, preferably 2 to 3% by weight of tetramethylammonium hydroxide (TMAH), choline hydroxide, tetraethylammonium hydroxide (TEAH), tetrapropylammonium hydroxide (TPAH) or tetrabutylammonium hydroxide (TBAH). Development is carried out for 3 seconds to 3 minutes, preferably 5 seconds to 2 minutes by any conventional techniques such as dip, puddle and spray techniques. The exposed region of resist film is dissolved in the developer, but not the unexposed region. In this way, the desired positive pattern is formed on the substrate.

Of the variety of high-energy radiation, the resist composition is best suited in micropatterning with EB, EUV (or soft x-ray), x-ray, γ-ray, or synchrotron radiation. Particularly when EUV radiation having a wavelength of 3 to 15 nm or an EB at an accelerating voltage of up to 100 keV, especially an EB at an accelerating voltage of up to 50 keV is used, a finer size pattern can be formed.

### Example

Synthesis Examples, Comparative Synthesis Examples, Examples, and Comparative Examples are given below by way of illustration of the invention and not by way of limitation. The abbreviation “pbw” is parts by weight. For all polymers, Mw and Mn are determined by GPC versus polystyrene standards using tetrahydrofuran solvent. AIBN stands for azobisisobutyronitrile, and TMAH for tetramethylammonium hydroxide.

The monomers used in Synthesis Examples, specifically Monomers 1 to 4, PAG Monomers 1 to 5, and Adhesive Monomers 1, 2 are identified below.

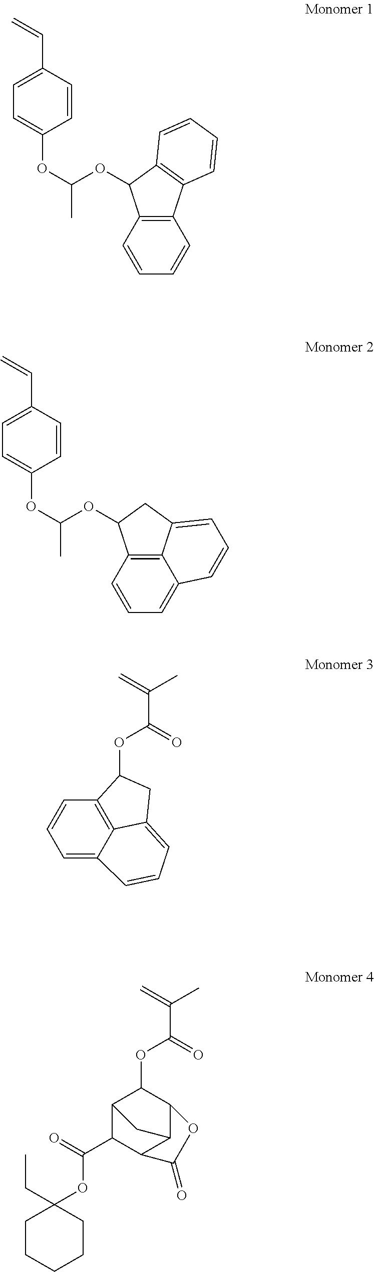

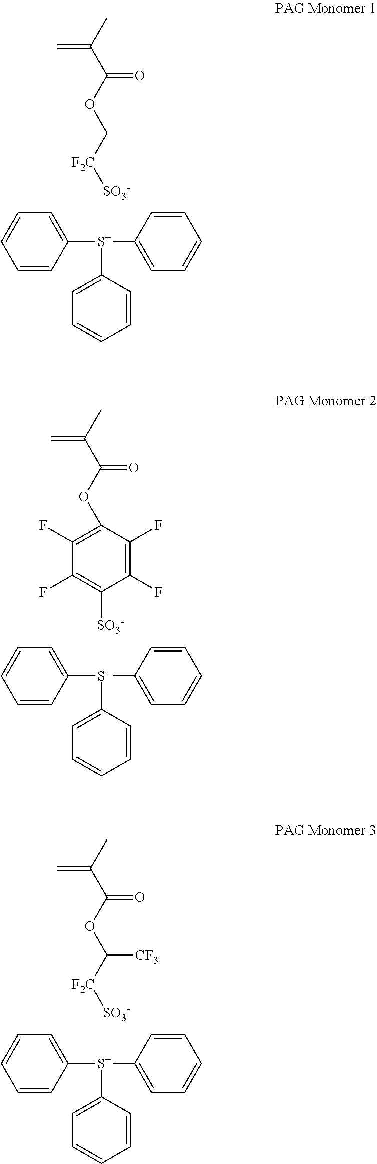

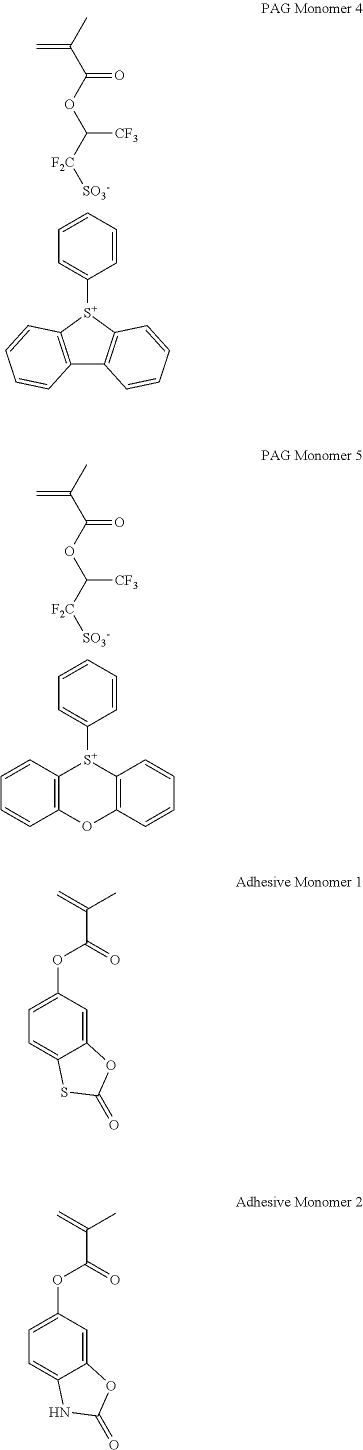

### Synthesis Example 1

A 2-L flask was charged with 5.3 g of 4-t-butoxystyrene, 7.0 g of 4-acetoxystyrene, 5.6 g of 3-oxo-2,7-dioxatricyclo[4.2.1.0^{4,8}]nonan-9-yl methacrylate, 0.4 g of magnesium methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was dissolved again in 100 mL of methanol and 200 mL of tetrahydrofuran, to which 10 g of triethylamine and 10 g of water were added whereupon deprotection reaction of acetyl group ran at 70° C. for 5 hours. The reaction solution was neutralized with acetic acid, concentrated, and dissolved in 100 mL of acetone. This was followed by similar precipitation, filtration and drying at 60° C., yielding a white polymer, designated Polymer 1.

The polymer was analyzed by ¹³C-NMR, ¹H-NMR, and GPC, with the analytical results shown below.

Copolymerization Compositional Ratio (Molar Basis)
4-t-butoxystyrene:4-hydroxystyrene:3-oxo-2,7-dioxatricyclo[4.2.1.0^{4,8}]nonan-9-yl methacrylate:magnesium methacrylate=0.30:0.43:0.25:0.02

Mw=10,200

Mw/Mn=1.99

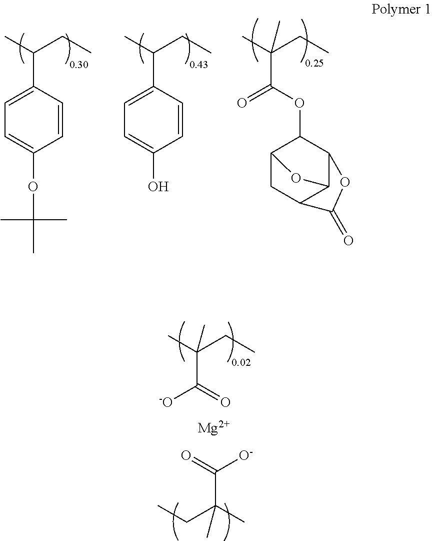

### Synthesis Example 2

A 2-L flask was charged with 5.7 g of 4-t-amyloxystyrene, 7.7 g of 4-hydroxyphenyl methacrylate, 5.6 g of 3-oxo-2,7-dioxatricyclo[4.2.1.0^{4,8}]nonan-9-yl methacrylate, 0.5 g of zinc methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 2.

The polymer was analyzed by ¹³C-NMR, ¹H-NMR, and GPC, with the analytical results shown below.

Copolymerization Compositional Ratio (Molar Basis)
4-t-amyloxystyrene:4-hydroxyphenyl methacrylate:3-oxo-2,7-dioxatricyclo[4.2.1.0^{4,8}]nonan-9-yl methacrylate:zinc methacrylate=0.30:0.43:0.25:0.02

Mw=10,200

Mw/Mn=2.11

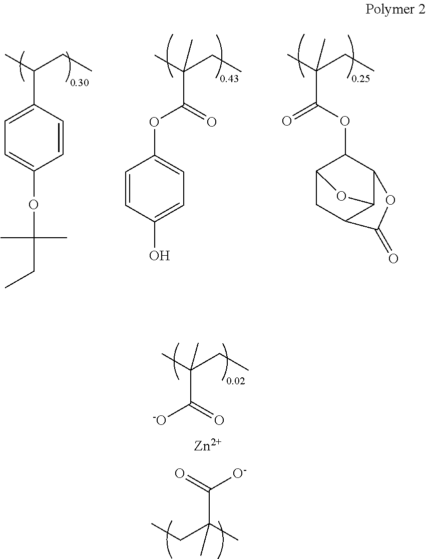

### Synthesis Example 3

A 2-L flask was charged with 9.8 g of Monomer 1, 9.8 g of 6-hydroxynaphthalen-2-yl methacrylate, 4.2 g of tetrahydro-2-oxofuran-3-yl methacrylate, 0.5 g of copper acrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 3.

The polymer was analyzed by ¹³C-NMR, ¹H-NMR, and GPC, with the analytical results shown below.

Copolymerization Compositional Ratio (Molar Basis)
Monomer 1:6-hydroxynaphthalen-2-yl methacrylate:tetrahydro-2-oxofuran-3-yl methacrylate:copper acrylate=0.30:0.43:0.25:0.02

Mw=9,300

Mw/Mn=2.06

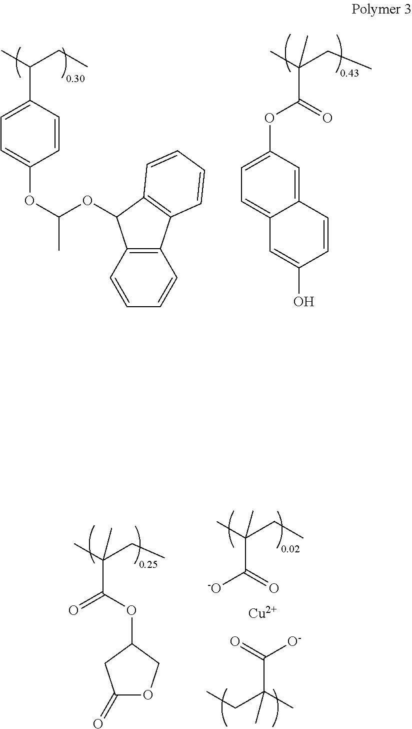

### Synthesis Example 4

A 2-L flask was charged with 8.8 g of Monomer 2, 9.1 g of 6-hydroxynaphthalen-2-yl methacrylate, 5.1 g of tetrahydro-2-oxofuran-3-yl methacrylate, 0.4 g of magnesium 2-butenoate methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 4.

The polymer was analyzed by ¹³C-NMR, ¹H-NMR, and GPC, with the analytical results shown below.

Copolymerization Compositional Ratio (Molar Basis)
Monomer 2:6-hydroxynaphthalen-2-yl methacrylate:tetrahydro-2-oxofuran-3-yl methacrylate:magnesium 2-butenoate methacrylate=0.28:0.40:0.30:0.02

Mw=9,300

Mw/Mn=1.76

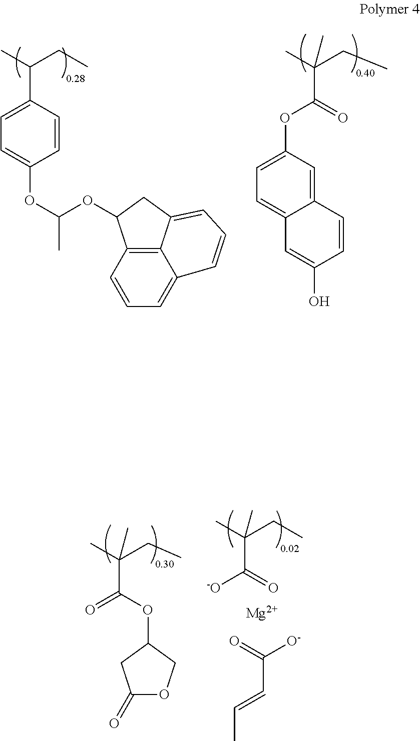

### Synthesis Example 5

A 2-L flask was charged with 5.7 g of 4-t-amyloxystyrene, 10.8 g of 4-acetoxystyrene, 1.8 g of acenaphthylene, 0.7 g of zinc methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was dissolved again in 100 mL of methanol and 200 mL of tetrahydrofuran, to which 10 g of triethylamine and 10 g of water were added whereupon deprotection reaction of acetyl group ran at 70° C. for 5 hours. The reaction solution was neutralized with acetic acid, concentrated, and dissolved in 100 mL of acetone. This was followed by similar precipitation, filtration and drying at 60° C., yielding a white polymer, designated Polymer 5.

The polymer was analyzed by ¹³C-NMR, ¹H-NMR, and GPC, with the analytical results shown below.

Copolymerization Compositional Ratio (Molar Basis)
4-t-amyloxystyrene:4-hydroxystyrene:acenaphthylene:zinc methacrylate=0.30:0.57:0.10:0.03

Mw=8,200

Mw/Mn=2.11

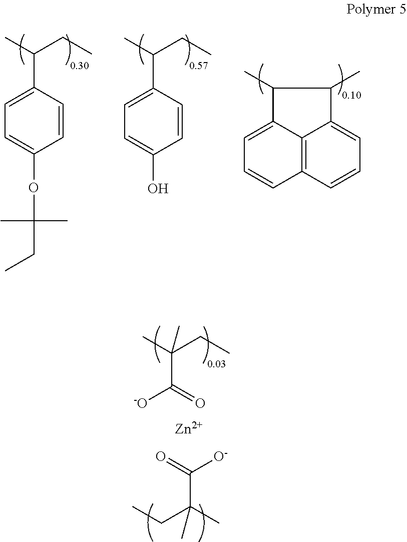

### Synthesis Example 6

A 2-L flask was charged with 8.2 g of 3-ethyl-3-exo-tetracyclo[4.4.0.1^{2,5}.1^{7,10}]dodecanyl methacrylate, 3.6 g of 4-hydroxyphenyl methacrylate, 10.7 g of 3-oxo-2,7-dioxatricyclo[4.2.1.0^{4,8}]nonan-9-yl methacrylate, 0.4 g of zinc acrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 6.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:3-oxo-2,7-dioxatricyclo[4.2.1.0^{4,8}]nonan-9-yl methacrylate:zinc acrylate=0.30:0.20:0.48:0.02

Mw=9,400

Mw/Mn=1.96

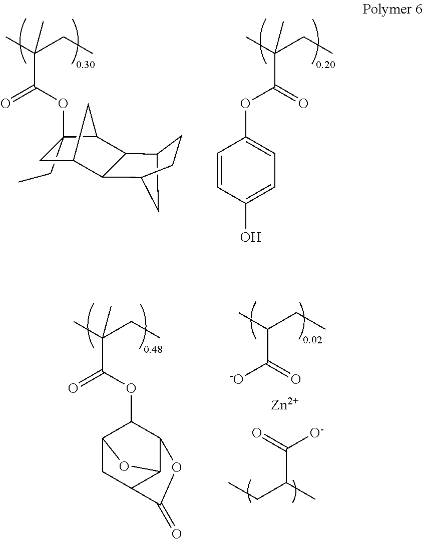

### Synthesis Example 7

A 2-L flask was charged with 8.2 g of 3-ethyl-3-exo-tetracyclo[4.4.0.1^{2,5}.1^{7,10}]dodecanyl methacrylate, 6.5 g of 5-hydroxyindan-2-yl methacrylate, 6.7 g of 3-oxo-2,7-dioxatricyclo[4.2.1.0^{4,8}]nonan-9-yl methacrylate, 4.5 g of PAG Monomer 3, 0.4 g of zinc acetate methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 7.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:5-hydroxyindan-2-yl methacrylate:3-oxo-2,7-dioxatricyclo[4.2.1.0^{4,8}]nonan-9-yl methacrylate:PAG Monomer 3:zinc acetate methacrylate=0.30:0.30:0.30:0.08:0.02

Mw=7,500

Mw/Mn=1.79

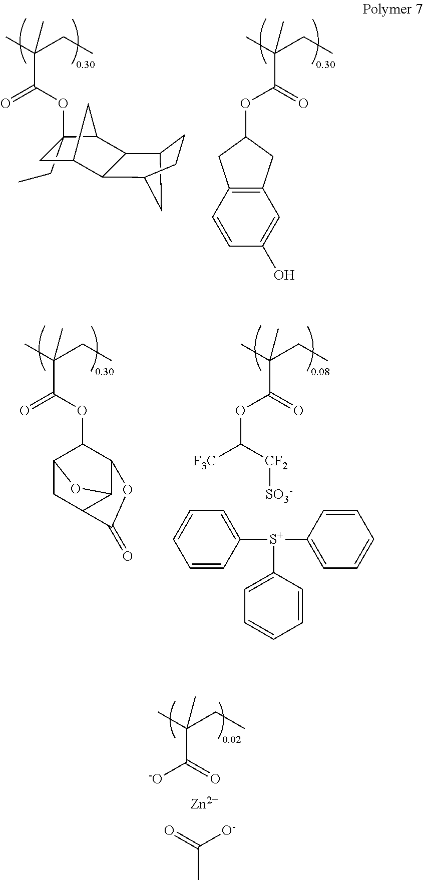

### Synthesis Example 8

A 2-L flask was charged with 7.6 g of 4-t-amyloxystyrene, 4.4 g of 5-hydroxyindan-2-yl methacrylate, 6.7 g of 3-oxo-2,7-dioxatricyclo[4.2.1.0^{4,8}]nonan-9-yl methacrylate, 3.9 g of PAG Monomer 1, 0.4 g of zinc propionate methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 8.

The polymer was analyzed by ¹³C-NMR, ¹H-NMR, and GPC, with the analytical results shown below.

Copolymerization Compositional Ratio (Molar Basis)
4-t-amyloxystyrene:5-hydroxyindan-2-yl methacrylate:3-oxo-2,7-dioxatricyclo[4.2.1.0^{4,8}]nonan-9-yl methacrylate:PAG Monomer 1:zinc propionate methacrylate=0.40:0.20:0.30:0.08:0.02

Mw=7,500

Mw/Mn=1.73

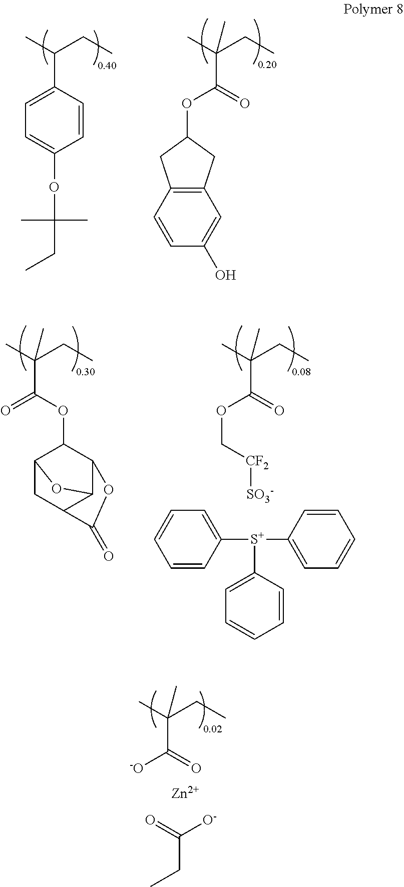

### Synthesis Example 9

A 2-L flask was charged with 6.5 g of Monomer 3, 4.5 g of 5-(methacryloylamino)-1-naphthol, 9.0 g of 3-oxo-2,7-dioxatricyclo[4.2.1.0^{4,8}]nonan-9-yl methacrylate, 4.6 g of PAG Monomer 2, 0.7 g of zinc cyclohexylcarboxylate 4-vinylbenzoate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 9.

The polymer was analyzed by ¹³C-NMR, ¹H-NMR, and GPC, with the analytical results shown below.

Copolymerization Compositional Ratio (Molar Basis)
Monomer 3:5-(methacryloylamino)-1-naphthol:3-oxo-2,7-dioxatricyclo[4.2.1.0^{4,8}]nonan-9-yl methacrylate:PAG Monomer 2:zinc cyclohexylcarboxylate 4-vinylbenzoate=0.30:0.20:0.40:0.08:0.02

Mw=7,900

Mw/Mn=1.97

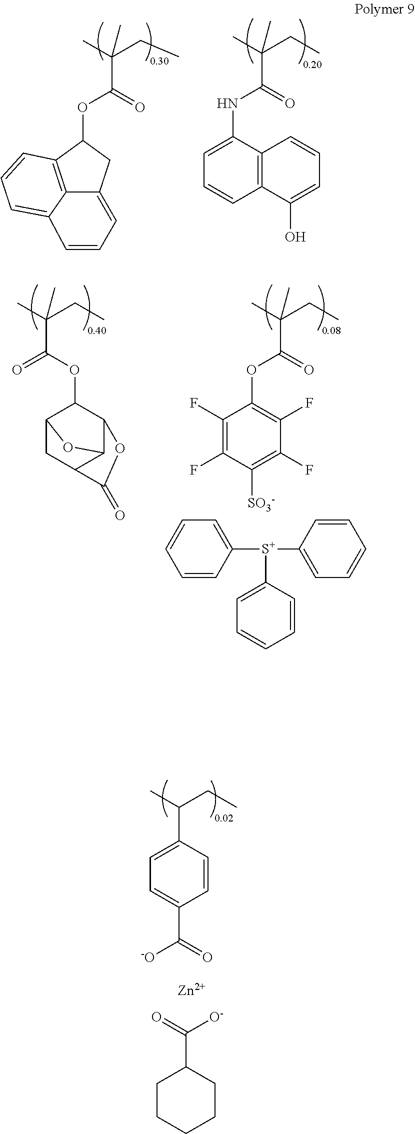

### Synthesis Example 10

A 2-L flask was charged with 15.0 g of Monomer 4, 3.5 g of 4-hydroxyphenylmethacrylamide, 6.7 g of 5-oxo-4-oxatricyclo[4.2.1.0^{3,7}]nonan-2-yl methacrylate, 4.5 g of PAG Monomer 3, 0.7 g of zinc 1-adamantanecarboxylate methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 10.

The polymer was analyzed by ¹³C-NMR, ¹H-NMR, and GPC, with the analytical results shown below.

Copolymerization Compositional Ratio (Molar Basis)
Monomer 4:4-hydroxyphenylmethacrylamide:5-oxo-4-oxatricyclo[4.2.1.0^{3,7}]nonan-2-yl methacrylate:PAG Monomer 3:zinc 1-adamantanecarboxylate methacrylate=0.40:0.20:0.30:0.08:0.02

Mw=9,100

Mw/Mn=1.77

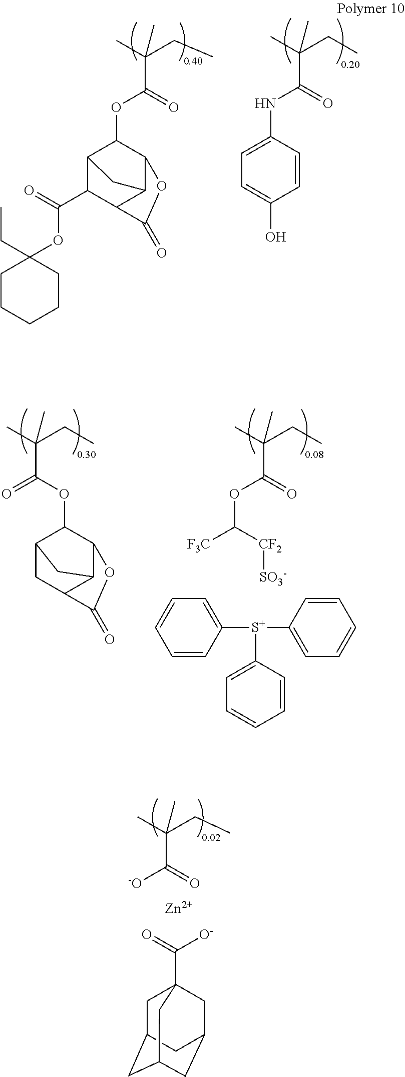

### Synthesis Example 11

A 2-L flask was charged with 5.5 g of 3-ethyl-3-exo-tetracyclo[4.4.0.1^{2,5}.1^{7,10}]dodecanyl methacrylate, 3.5 g of 4-tert-butoxyphenyl methacrylate, 3.6 g of 5-hydroxypyridin-6-yl methacrylate, 7.4 g of 3-oxo-2,7-dioxatricyclo[4.2.1.0^{4,8}]nonan-9-yl methacrylate, 5.6 g of PAG Monomer 3, 0.6 g of zinc 2-nitropyridine-4-carboxylate methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 11.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-tert-butoxyphenyl methacrylate:5-hydroxypyridin-6-yl methacrylate:3-oxo-2,7-dioxa-tricyclo[4.2.1.0^{4,8}]nonan-9-yl methacrylate:PAG Monomer 3:zinc 2-nitropyridine-4-carboxylate methacrylate=0.20:0.15:0.20:0.33:0.10:0.02

Mw=9,000

Mw/Mn=1.98

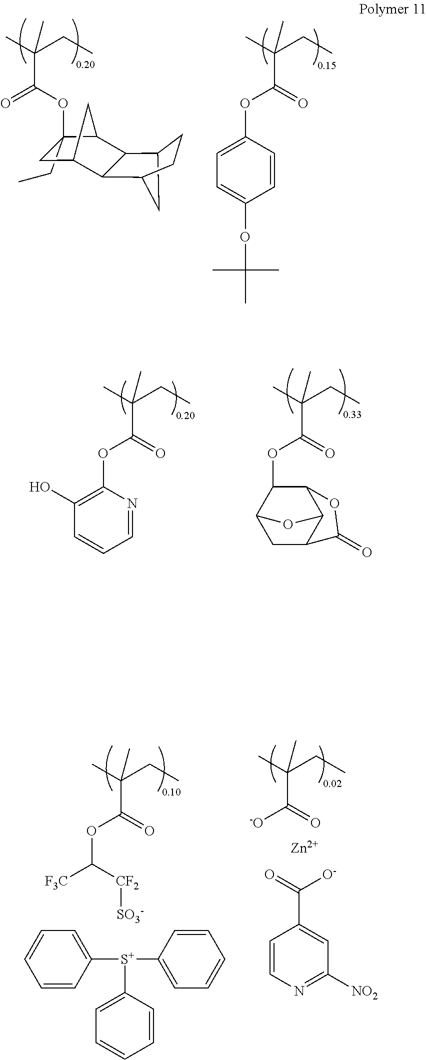

### Synthesis Example 12

A 2-L flask was charged with 6.9 g of 6,7,8,9-tetrahydro-5H-benzocyclohepten-5-yl methacrylate, 3.6 g of 4-hydroxypyrimidin-6-yl methacrylate, 8.5 g of 3-oxo-2,7-dioxatricyclo[4.2.1.0^{4,8}]nonan-9-yl methacrylate, 5.6 g of PAG Monomer 3, 1.1 g of zinc cholate methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 12.

The polymer was analyzed by ¹³C-NMR, ¹H-NMR, and GPC, with the analytical results shown below.

Copolymerization Compositional Ratio (Molar Basis)
6,7,8,9-tetrahydro-5H-benzocyclohepten-5-yl methacrylate:4-hydroxypyrimidin-6-yl methacrylate:3-oxo-2,7-dioxatricyclo[4.2.1.0^{4,8}]nonan-9-yl methacrylate:PAG Monomer 3:zinc cholate methacrylate=0.30:0.20:0.38:0.10:0.02

Mw=9,900

Mw/Mn=1.86

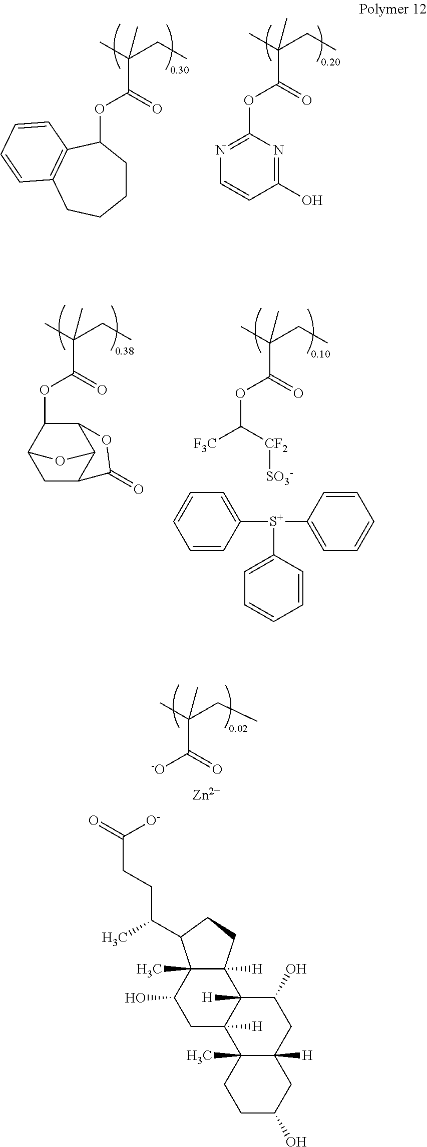

### Synthesis Example 13

A 2-L flask was charged with 8.2 g of 3-ethyl-3-exo-tetracyclo[4.4.0.1^{2,5}.1^{7,10}]dodecanyl methacrylate, 3.6 g of 4-hydroxyphenyl methacrylate, 9.4 g of Adhesive Monomer 1, 4.5 g of PAG Monomer 3, 0.6 g of zinc naphthalene-1-carboxylate methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 13.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:Adhesive Monomer 1:PAG Monomer 3:zinc naphthalene-1-carboxylate methacrylate=0.30:0.20:0.40:0.08:0.02

Mw=7,900

Mw/Mn=1.79

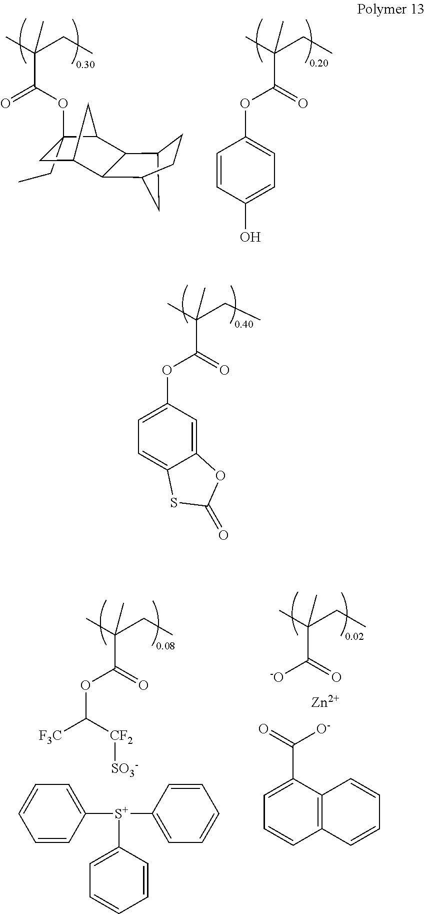

### Synthesis Example 14

A 2-L flask was charged with 8.2 g of 3-ethyl-3-exo-tetracyclo[4.4.0.1^{2,5}.1^{7,10}]dodecanyl methacrylate, 3.6 g of 4-hydroxyphenyl methacrylate, 8.7 g of Adhesive Monomer 2, 4.5 g of PAG Monomer 3, 0.7 g of zinc fluorene-9-carboxylate methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 14.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:Adhesive Monomer 2:PAG Monomer 3:zinc fluorene-9-carboxylate methacrylate=0.30:0.20:0.40:0.08:0.02

Mw=7,800

Mw/Mn=1.78

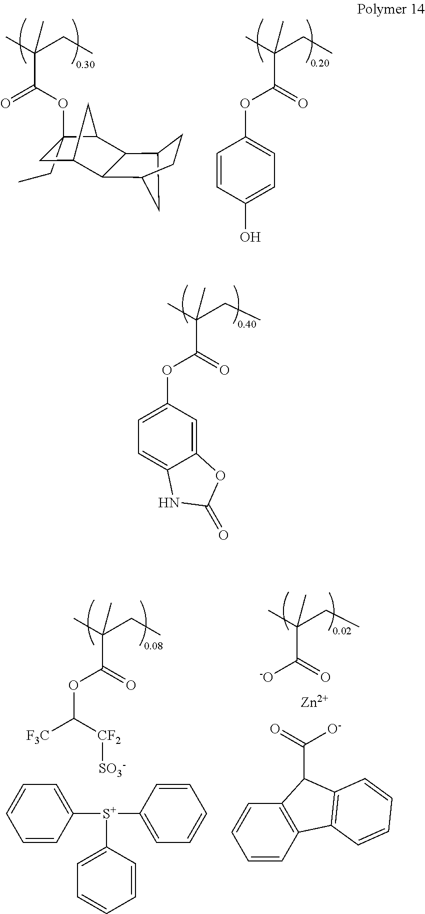

### Synthesis Example 15

A 2-L flask was charged with 8.2 g of 3-ethyl-3-exo-tetracyclo[4.4.0.1^{2,5}.1^{7,10}]dodecanyl methacrylate, 3.6 g of 4-hydroxyphenyl methacrylate, 9.0 g of 3-oxo-2,7-dioxatricyclo[4.2.1.0^{4,8}]nonan-9-yl methacrylate, 4.5 g of PAG Monomer 4, 0.5 g of magnesium 4-pyridinecarboxylate methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 15.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:3-oxo-2,7-dioxatricyclo[4.2.1.0^{4,8}]nonan-9-yl methacrylate:PAG Monomer 4:magnesium 4-pyridinecarboxylate methacrylate=0.30:0.20:0.40:0.08:0.02

Mw=9,700

Mw/Mn=1.97

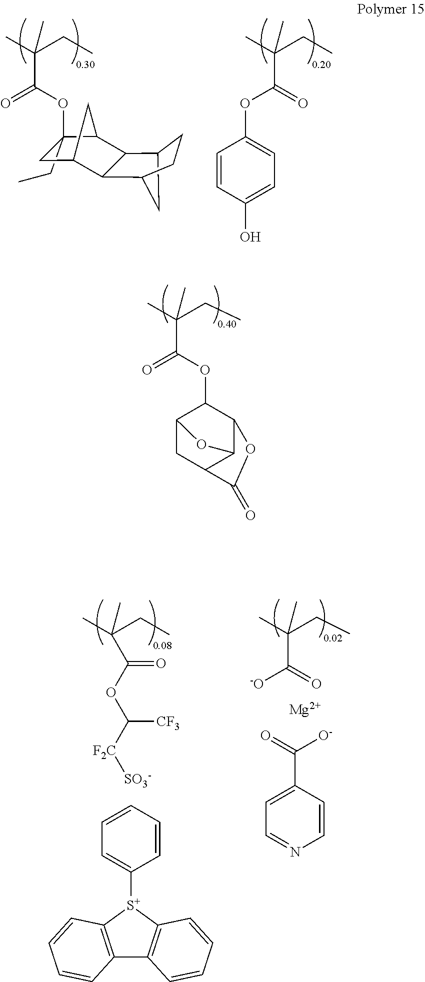

### Synthesis Example 16

A 2-L flask was charged with 8.2 g of 3-ethyl-3-exo-tetracyclo[4.4.0.1^{2,5}.1^{7,10}]dodecanyl methacrylate, 3.6 g of 4-hydroxyphenyl methacrylate, 9.0 g of 3-oxo-2,7-dioxatricyclo[4.2.1.0^{4,8}]nonan-9-yl methacrylate, 4.6 g of PAG Monomer 5, 0.8 g of magnesium 2-fluoropyridine-4-carboxylate methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 16.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:3-oxo-2,7-dioxatricyclo[4.2.1.0^{4,8}]nonan-9-yl methacrylate:PAG Monomer 5:magnesium 2-fluoropyridine-4-carboxylate methacrylate=0.30:0.20:0.40:0.08:0.02

Mw=9,700

Mw/Mn=1.97

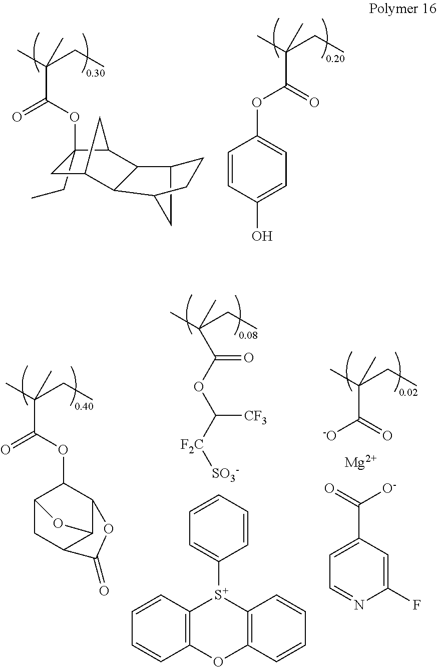

### Synthesis Example 17

A 2-L flask was charged with 8.2 g of 3-ethyl-3-exo-tetracyclo[4.4.0.1^{2,5}.1^{7,10}]dodecanyl methacrylate, 3.6 g of 4-hydroxyphenyl methacrylate, 9.0 g of 3-oxo-2,7-dioxatricyclo[4.2.1.0^{4,8}]nonan-9-yl methacrylate, 4.5 g of PAG Monomer 3, 0.7 g of zinc acetate methacrylphenyl-4-carboxylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 17.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:3-oxo-2,7-dioxatricyclo[4.2.1.0^{4,8}]nonan-9-yl methacrylate:PAG Monomer 3:zinc acetate methacrylphenyl-4-carboxylate=0.30:0.20:0.40:0.08:0.02

Mw=7,500

Mw/Mn=1.76

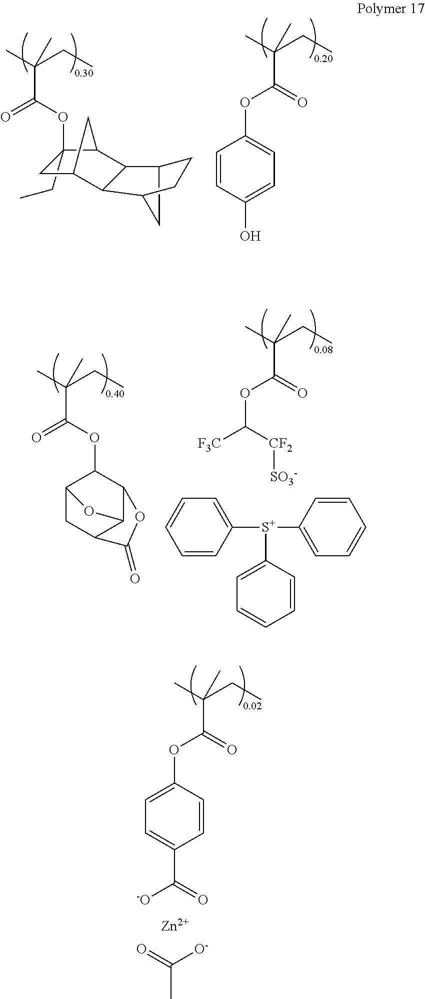

### Synthesis Example 18

A 2-L flask was charged with 8.2 g of 3-ethyl-3-exo-tetracyclo[4.4.0.1^{2,5}.1^{7,10}]dodecanyl methacrylate, 3.6 g of 4-hydroxyphenyl methacrylate, 9.0 g of 3-oxo-2,7-dioxatricyclo[4.2.1.0^{4,8}]nonan-9-yl methacrylate, 4.5 g of PAG Monomer 3, 0.6 g of zinc acetate 2-vinyl-6-naphthalenecarboxylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 18.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:3-oxo-2,7-dioxatricyclo[4.2.1.0^{4,8}]nonan-9-yl methacrylate:PAG Monomer 3:zinc acetate 2-vinyl-6-naphthalenecarboxylate=0.30:0.20:0.40:0.08:0.02

Mw=7,900

Mw/Mn=1.89

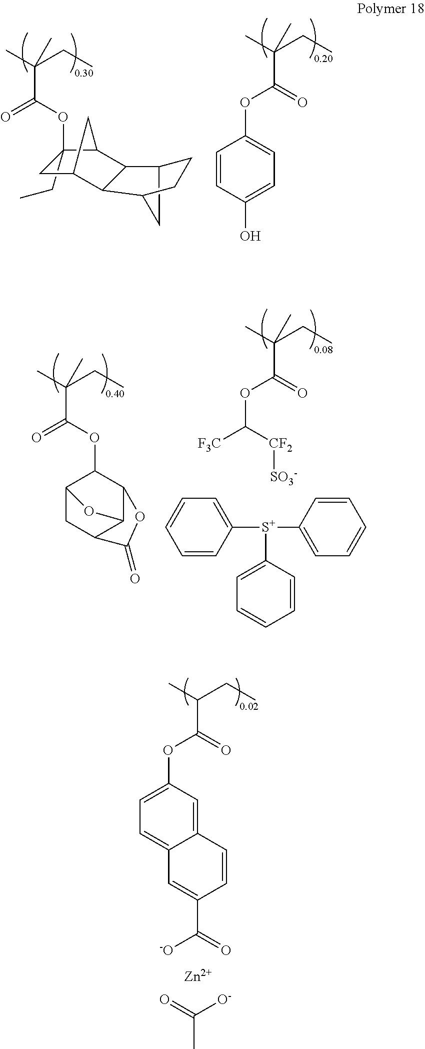

### Synthesis Example 19

A 2-L flask was charged with 8.2 g of 3-ethyl-3-exo-tetracyclo[4.4.0.1^{2,5}.1^{7,10}]dodecanyl methacrylate, 3.6 g of 4-hydroxyphenyl methacrylate, 9.0 g of 3-oxo-2,7-dioxatricyclo[4.2.1.0^{4,8}]nonan-9-yl methacrylate, 4.6 g of PAG Monomer 5, 0.8 g of magnesium 1-adamantane-carboxylate methacryl-1-adamantane-3-carboxylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 19.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:3-oxo-2,7-dioxatricyclo[4.2.1.0^{4,8}]nonan-9-yl methacrylate:PAG Monomer 5:magnesium 1-adamantanecarboxylate methacryl-1-adamantane-3-carboxylate=0.30:0.20:0.40:0.08:0.02

Mw=9,700

Mw/Mn=1.97

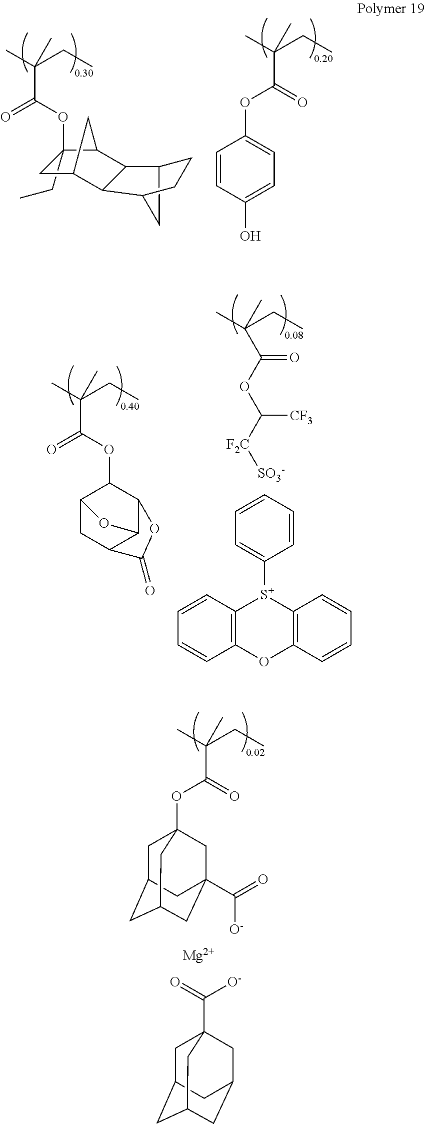

### Synthesis Example 20

A 2-L flask was charged with 8.2 g of 3-ethyl-3-exo-tetracyclo[4.4.0.1^{2,5}.1^{7,10}]dodecanyl methacrylate, 3.6 g of 4-hydroxyphenyl methacrylate, 9.0 g of 3-oxo-2,7-dioxatricyclo[4.2.1.0^{4,8}]nonan-9-yl methacrylate, 4.5 g of PAG Monomer 3, 0.6 g of zinc 4-fluorobenzoate methacryl-1-naphthalene-5-carboxylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 20.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:3-oxo-2,7-dioxatricyclo[4.2.1.0^{4,8}]nonan-9-yl methacrylate:PAG Monomer 3:zinc 4-fluorobenzoate methacryl-1-naphthalene-5-carboxylate=0.30:0.20:0.40:0.08:0.02

Mw=7,300

Mw/Mn=1.64

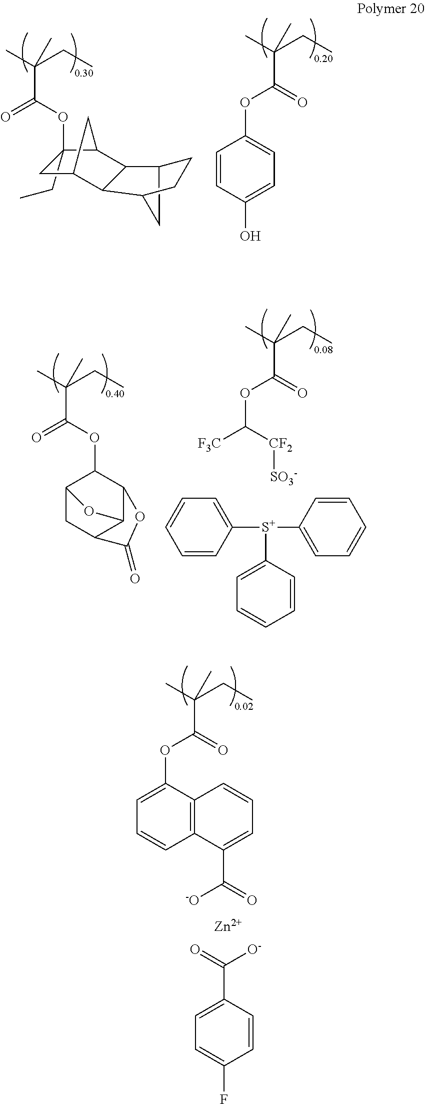

### Synthesis Example 21

A 2-L flask was charged with 8.2 g of 3-ethyl-3-exo-tetracyclo[4.4.0.1^{2,5}.1^{7,10}]dodecanyl methacrylate, 3.6 g of 4-hydroxyphenyl methacrylate, 9.0 g of 3-oxo-2,7-dioxatricyclo[4.2.1.0^{4,8}]nonan-9-yl methacrylate, 4.5 g of PAG Monomer 3, 0.4 g of cesium methacrylate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 21.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:3-oxo-2,7-dioxatricyclo[4.2.1.0^{4,8}]nonan-9-yl methacrylate:PAG Monomer 3:cesium methacrylate=0.30:0.20:0.40:0.08:0.02

Mw=7,100

Mw/Mn=1.67

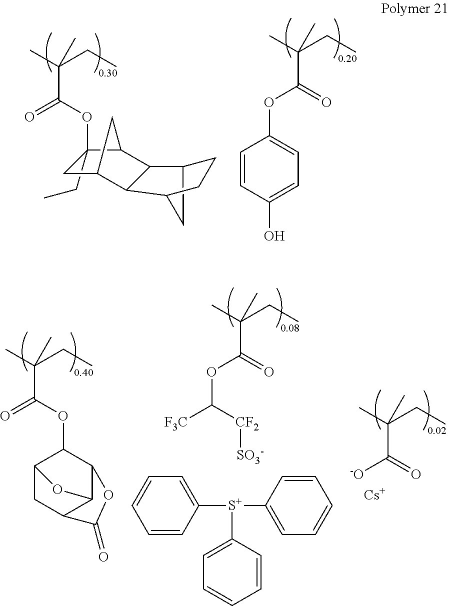

### Synthesis Example 22

A 2-L flask was charged with 8.2 g of 3-ethyl-3-exo-tetracyclo[4.4.0.1^{2,5}.1^{7,10}]dodecanyl methacrylate, 3.6 g of 4-hydroxyphenyl methacrylate, 9.0 g of 3-oxo-2,7-dioxatricyclo[4.2.1.0^{4,8}]nonan-9-yl methacrylate, 4.5 g of PAG Monomer 4, 0.6 g of cesium 4-vinylbenzoate, and 40 g of tetrahydrofuran as solvent. In a nitrogen atmosphere, the reactor was cooled down to −70° C., followed by three cycles of vacuum evacuation and nitrogen blow. The reactor was warmed up to room temperature, whereupon 1.2 g of AIBN was added as polymerization initiator. The reactor was heated at 60° C., whereupon reaction ran for 15 hours. The reaction solution was precipitated from 1 L of isopropyl alcohol. The resulting white solid was filtered and dried in vacuum at 60° C., yielding a white polymer, designated Polymer 22.

The polymer was analyzed by ¹³C-NMR, ¹H-NMR, and GPC, with the analytical results shown below.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:3-oxo-2,7-dioxatricyclo[4.2.1.0^{4,8}]nonan-9-yl methacrylate:PAG Monomer 4:cesium 4-vinylbenzoate=0.30:0.20:0.40:0.08:0.02

Mw=7,900

Mw/Mn=1.62

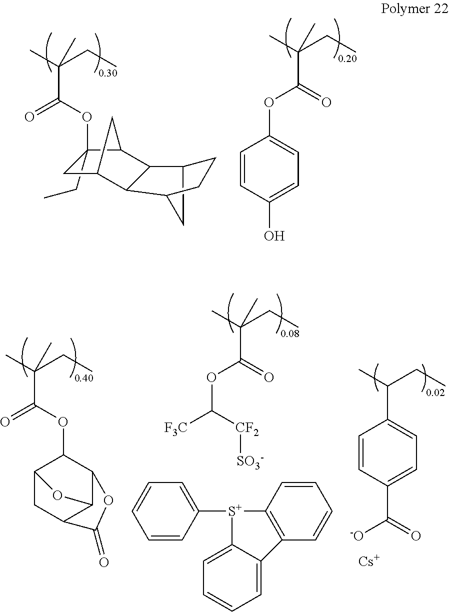

### Comparative Synthesis Example 1

A polymer of the following composition, designated Comparative Polymer 1, was synthesized by the same procedure as in Synthesis Examples.

Copolymerization Compositional Ratio (Molar Basis)
3-ethyl-3-exo-tetracyclo[4.4.0.1^{2,5}.1^{7,10}]dodecanyl methacrylate:3-oxo-2,7-dioxatricyclo[4.2.1.0^{4,8}]nonan-9-yl methacrylate:4-hydroxyphenyl methacrylate=0.30:0.40:0.30

Mw=8,200

Mw/Mn=1.89

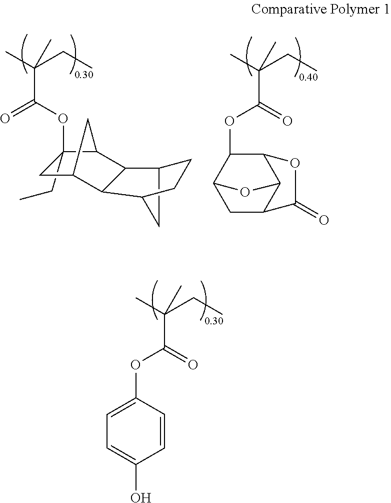

### Comparative Synthesis Example 2

A polymer of the following composition, designated Comparative Polymer 2, was synthesized by the same procedure as in Synthesis Examples.

Copolymerization Compositional Ratio (Molar Basis)
4-t-amyloxystyrene:3-oxo-2,7-dioxatricyclo[4.2.1.0^{4,8}]-nonan-9-yl methacrylate:4-hydroxyphenyl methacrylate=0.40:0.20:0.40

Mw=8,500

Mw/Mn=1.89

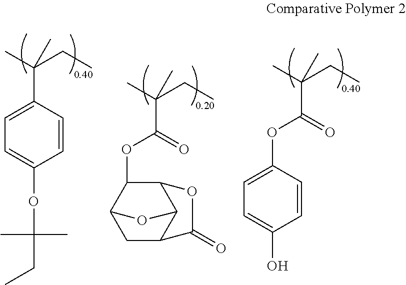

### Comparative Synthesis Example 3

A polymer of the following composition, designated Comparative Polymer 3, was synthesized by the same procedure as in Synthesis Examples.

Copolymerization Compositional Ratio (Molar Basis)
3-ethyl-3-exo-tetracyclo[4.4.0.1^{2,5}.1^{7,10}]dodecanyl methacrylate:4-hydroxyphenyl methacrylate:3-oxo-2,7-dioxatricyclo[4.2.1.0^{4,8}]nonan-9-yl methacrylate:PAG Monomer 1=0.30:0.30:0.30:0.10

Mw=7,300

Mw/Mn=1.88

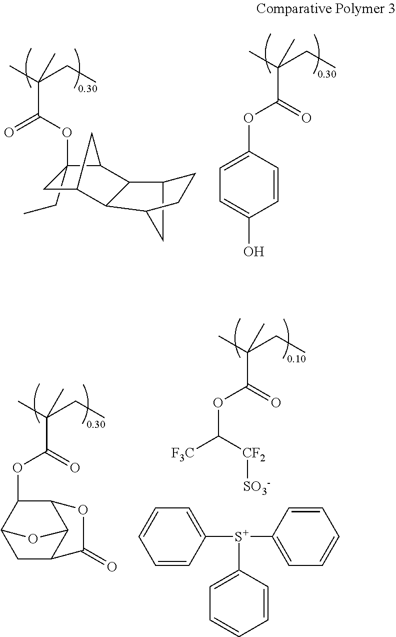

Positive resist compositions were prepared in solution form by using the polymers synthesized above, dissolving each polymer and selected components in a solvent in accordance with the recipe of Tables 1 and 2, and filtering through a filter with a pore size of 0.2 μm. The solvent contained 100 ppm of surfactant FC-4430 (commercially available from 3M). The components in Tables 1 and 2 are identified below.

### Polymers 1 to 22: Synthesis Examples 1 to 22

### Comparative Polymers 1 to 3:

Comparative Synthesis Examples 1 to 3

### Organic Solvents:

PGMEA (propylene glycol monomethyl ether acetate)

CyH (cyclohexanone)

CyP (cyclopentanone)

PGME (propylene glycol monomethyl ether)

Acid generator: PAG1 of the structural formula below

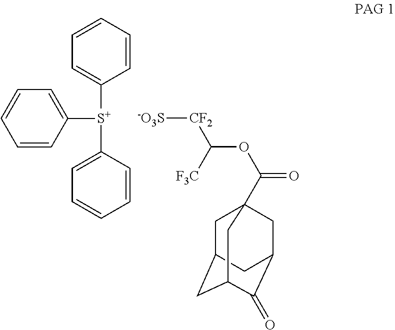

Basic compound: Amine 1 of the structural formula below

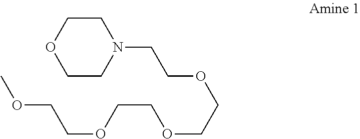

### Examples 1-1 to 1-23 & Comparative Examples 1-1 to 1-4

### EB Writing Test

Using a coater/developer system Clean Track Mark 5 (Tokyo Electron Ltd.), the positive resist composition was spin coated onto a silicon substrate (diameter 6 inches, vapor primed with hexamethyldisilazane (HMDS)) and pre-baked on a hot plate at 110° C. for 60 seconds to form a resist film of 100 nm thick. Using a system HL-800D (Hitachi Ltd.) at a HV voltage of 50 keV, the resist film was exposed imagewise to EB in a vacuum chamber.

Using Clean Track Mark 5, immediately after the imagewise exposure, the resist film was baked (PEB) on a hot plate at the temperature shown in Tables 1 and 2 for 60 seconds and puddle developed in a 2.38 wt % TMAH aqueous solution for 30 seconds to form a positive pattern.

Resolution is a minimum size at the exposure dose (sensitivity) that provides a 1:1 resolution of a 100-nm line-and-space pattern. The 100-nm line-and-space pattern was measured for line width roughness (LWR) under SEM.

The resist composition is shown in Tables 1 and 2 along with the sensitivity and resolution of EB lithography.

TABLE 1

| | | | Acid | | | | PEB | | | |
|---|---|---|---|---|---|---|---|---|---|---|
| | | Polymer | generator | Quencher | Organic solvent | | temp. | Sensitivity | Resolution | LWR |
| | | (pbw) | (pbw) | (pbw) | (pbw) | | (° C.) | (μC/cm²) | (nm) | (nm) |
| Example | 1-1 | Polymer 1 | PAG 1 | — | PGMEA | (1,500) | 95 | 28.3 | 75 | 6.2 |
| | | (100) | (12) | | CyH | (200) | | | | |
| | 1-2 | Polymer 2 | PAG 1 | — | PGMEA | (1,500) | 90 | 30.3 | 75 | 6.2 |
| | | (100) | (12) | | CyH | (200) | | | | |
| | 1-3 | Polymer 3 | PAG 1 | — | PGMEA | (1,500) | 90 | 25.3 | 75 | 6.2 |
| | | (100) | (12) | | CyH | (200) | | | | |
| | 1-4 | Polymer 4 | PAG 1 | — | PGMEA | (1,500) | 90 | 26.3 | 75 | 6.2 |
| | | (100) | (12) | | CyH | (200) | | | | |
| | 1-5 | Polymer 5 | PAG 1 | — | PGMEA | (1,500) | 95 | 28.3 | 75 | 6.4 |
| | | (100) | (12) | | CyH | (200) | | | | |
| | 1-6 | Polymer 6 | PAG 1 | — | PGMEA | (1,500) | 95 | 26.4 | 75 | 6.8 |
| | | (100) | (12) | | CyH | (200) | | | | |
| | 1-7 | Polymer 7 | — | — | PGMEA | (500) | 95 | 30.3 | 70 | 5.8 |
| | | (100) | | | CyH | (1,450) | | | | |
| | | | | | PGME | (50) | | | | |
| | 1-8 | Polymer 8 | — | — | PGMEA | (500) | 90 | 36.2 | 75 | 6.1 |
| | | (100) | | | CyH | (1,450) | | | | |
| | | | | | PGME | (50) | | | | |
| | 1-9 | Polymer 9 | — | — | PGMEA | (500) | 110 | 39.3 | 70 | 5.1 |
| | | (100) | | | CyH | (1,450) | | | | |
| | | | | | PGME | (50) | | | | |
| | 1-10 | Polymer 10 | — | — | PGMEA | (500) | 90 | 27.3 | 70 | 5.3 |
| | | (100) | | | CyH | (1,450) | | | | |
| | | | | | PGME | (50) | | | | |
| | 1-11 | Polymer 11 | — | — | PGMEA | (300) | 90 | 29.3 | 70 | 5.6 |
| | | (100) | | | CyH | (1,450) | | | | |
| | | | | | CyP | (250) | | | | |
| | 1-12 | Polymer 12 | — | — | PGMEA | (300) | 95 | 25.6 | 70 | 5.1 |
| | | (100) | | | CyH | (1,450) | | | | |
| | | | | | CyP | (250) | | | | |
| | 1-13 | Polymer 13 | — | — | PGMEA | (300) | 95 | 31.3 | 70 | 5.6 |
| | | (100) | | | CyH | (1,450) | | | | |
| | | | | | CyP | (250) | | | | |
| | 1-14 | Polymer 14 | — | — | PGMEA | (300) | 95 | 33.9 | 70 | 5.6 |
| | | (100) | | | CyH | (1,450) | | | | |
| | | | | | CyP | (250) | | | | |
| | 1-15 | Polymer 15 | — | — | PGMEA | (300) | 95 | 32.9 | 70 | 5.2 |
| | | (100) | | | CyH | (1,450) | | | | |
| | | | | | CyP | (250) | | | | |
| | 1-16 | Polymer 16 | — | — | PGMEA | (300) | 95 | 33.6 | 70 | 5.0 |
| | | (100) | | | CyH | (1,450) | | | | |
| | | | | | PGME | (50) | | | | |
| | 1-17 | Polymer 17 | — | — | PGMEA | (300) | 95 | 28.9 | 70 | 5.7 |
| | | (100) | | | CyH | (1,450) | | | | |
| | | | | | PGME | (50) | | | | |
| | 1-18 | Polymer 18 | — | — | PGMEA | (300) | 95 | 29.9 | 70 | 5.9 |
| | | (100) | | | CyH | (1,450) | | | | |
| | | | | | PGME | (50) | | | | |
| | 1-19 | Polymer 19 | — | — | PGMEA | (300) | 95 | 27.9 | 70 | 5.2 |
| | | (100) | | | CyH | (1,450) | | | | |
| | | | | | PGME | (50) | | | | |
| | 1-20 | Polymer 20 | — | — | PGMEA | (300) | 95 | 33.9 | 70 | 5.9 |
| | | (100) | | | CyH | (1,450) | | | | |
| | | | | | PGME | (50) | | | | |
| | 1-21 | Polymer 21 | — | Amine 1 | PGMEA | (300) | 95 | 38.9 | 70 | 4.9 |
| | | (100) | | (0.5) | CyH | (1,450) | | | | |
| | | | | | CyP | (250) | | | | |
| | 1-22 | Polymer 22 | — | — | PGMEA | (300) | 95 | 27.9 | 70 | 4.9 |
| | | (100) | | | CyH | (1,450) | | | | |
| | | | | | PGME | (50) | | | | |
| | 1-23 | Polymer 23 | — | — | PGMEA | (300) | 95 | 28.9 | 70 | 4.6 |
| | | (100) | | | CyH | (1,450) | | | | |
| | | | | | PGME | (50) | | | | |

TABLE 2

| | | | Acid | | | | PEB | | | |
|---|---|---|---|---|---|---|---|---|---|---|
| | | Polymer | generator | Quencher | Organic solvent | | temp. | Sensitivity | Resolution | LWR |
| | | (pbw) | (pbw) | (pbw) | (pbw) | | (° C.) | (μC/cm²) | (nm) | (nm) |
| Comparitive | 1-1 | Comparative | PAG 1 | Amine 1 | PGMEA | (1,500) | 95 | 23.5 | 90 | 8.9 |
| Example | | Polymer 1 | (12) | (0.6) | CyH | (200) | | | | |
| | | (100) | | | | | | | | |
| | 1-2 | Comparative | PAG 1 | Amine 1 | PGMEA | (1,500) | 90 | 28.5 | 90 | 8.8 |
| | | Polymer 2 | (12) | (0.6) | CyH | (200) | | | | |
| | | (100) | | | | | | | | |
| | 1-3 | Comparative | — | Amine 1 | PGMEA | (500) | 95 | 22.0 | 80 | 6.1 |
| | | Polymer 3 | | (0.6) | CyH | (1,450) | | | | |
| | | (100) | | | PGME | (50) | | | | |
| | 1-4 | Comparative | PAG 1 | magnesium | PGMEA | (1,500) | 95 | 36.5 | 80 | 9.9 |
| | | Polymer 1 | (12) | ethyl butyrate | CyH | (200) | | | | |
| | | (100) | | (0.6) | | | | | | |

### Examples 2-1, 2-2 & Comparative Example 2-1

### EUV Exposure Test

The positive resist composition was spin coated onto a silicon substrate (diameter 4 inches, vapor primed with hexamethyldisilazane (HMDS)) and pre-baked on a hot plate at 105° C. for 60 seconds to form a resist film of 40 nm thick. Using a EUV microstepper (NA 0.3, dipole illumination), the resist film was exposed imagewise to EUV.

Immediately after the imagewise exposure, the resist film was baked (PEB) on a hot plate at the temperature shown in Table 3 for 60 seconds and puddle developed in a 2.38 wt % TMAH aqueous solution for 30 seconds to form a positive pattern.

Resolution is a minimum size at the exposure dose (sensitivity) that provides a 1:1 resolution of a 25-nm line-and-space pattern. The 25-nm line-and-space pattern was measured for LWR under SEM.

The resist composition is shown in Table 3 along with the sensitivity and resolution of EUV lithography.

TABLE 3

| | | | Acid | | | | PEB | | | |
|---|---|---|---|---|---|---|---|---|---|---|
| | | Polymer | generator | Quencher | Organic solvent | | temp. | Sensitivity | Resolution | LWR |
| | | (pbw) | (pbw) | (pbw) | (pbw) | | (° C.) | (μC/cm²) | (nm) | (nm) |
| Example | 2-1 | Polymer 21 | — | — | PGMEA | (300) | 95 | 12.5 | 22 | 4.9 |
| | | (100) | | | CyH | (1,450) | | | | |
| | | | | | PGME | (50) | | | | |
| | 2-2 | Polymer 22 | — | — | PGMEA | (300) | 95 | 13.7 | 22 | 4.6 |
| | | (100) | | | CyH | (1,450) | | | | |
| | | | | | PGME | (50) | | | | |
| Comparative | 2-1 | Comparative | — | Amine 1 | PGMEA | (300) | 95 | 15.6 | 24 | 5.8 |
| Example | | Polymer 3 | | (0.6) | CyH | (1,450) | | | | |
| | | (100) | | | PGME | (50) | | | | |

It is evident from Tables 1 to 3 that the resist compositions of Examples have a sufficient resolution and an appropriate sensitivity and are fully reduced in edge roughness. The resist compositions of Comparative Examples have a sufficient resolution and sensitivity, but their LWR values are noticeably higher than those of Examples.

It is demonstrated that the resist composition of the invention comprising a polymer having recurring units having an acid labile group and recurring units of a magnesium, copper, zinc or cesium salt of (meth)acrylic acid, styrenecarboxylic acid or vinylnaphthalenecarboxylic acid copolymerized together exhibits a high resolution, a high sensitivity, and a minimal LER. The resist composition is best suited as the resist material for VLSIs and patterning material for masks.

While the invention has been described with reference to a preferred embodiment, it will be understood by those skilled in the art that various changes may be made and equivalents may be substituted for elements thereof without departing from the scope of the invention. Therefore, it is intended that the invention not be limited to the particular embodiment disclosed as the best mode contemplated for carrying out this invention, but that the invention will include all embodiments falling within the scope of the appended claims.

Japanese Patent Application No. 2011-025653 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a polymer having copolymerized together recurring units of acid labile group-substituted (meth)acrylic acid, styrenecarboxylic acid or vinylnaphthalenecarboxylic acid and/or recurring units having an acid labile group-substituted phenolic hydroxyl group, and recurring units of a magnesium, copper, zinc or cesium salt of (meth)acrylic acid, styrenecarboxylic acid or vinylnaphthalenecarboxylic acid.

2. The resist composition of claim 1 wherein the polymer comprises recurring units (a1) of acid labile group-substituted (meth)acrylic acid, styrenecarboxylic acid or vinylnaphthalenecarboxylic acid and/or recurring units (a2) having an acid labile group-substituted phenolic hydroxyl group, and recurring units (b1) of a magnesium, copper or zinc salt of (meth)acrylic acid, styrenecarboxylic acid or vinylnaphthalenecarboxylic acid and/or recurring units (b2) of a cesium salt of (meth)acrylic acid, styrenecarboxylic acid or vinylnaphthalenecarboxylic acid, as represented by the general formula (1): 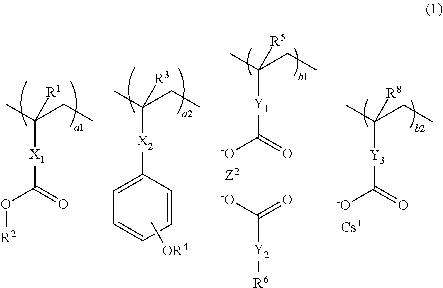
wherein R¹, R³, R⁵, and R⁸ are each independently hydrogen or methyl, R² and R⁴ each are an acid labile group, X₁ is a single bond, a C₁-C₁₂ linking group having at least one of ester moiety, lactone ring, phenylene moiety or naphthylene moiety, a phenylene group, or a naphthylene group, X₂ is a single bond or an ester group, Y₁, Y₂ and Y₃ are each independently a single bond, a C₆-C₁₂ arylene group, or —C(═O)—O—R⁷—, R⁷ is a straight, branched or cyclic C₁-C₁₀ alkylene group or C₆-C₁₂ arylene group, which may contain an ether, ester, lactone ring, hydroxyl, amino, cyano moiety, double bond, or triple bond, R⁶ is hydrogen, a straight, branched or cyclic C₁-C₁₀ alkyl group, C₂-C₁₆ alkenyl group, or C₂-C₁₆ alkynyl group, which may contain an ether, ester, amino, amide, sulfonic acid ester, halogen, cyano, nitro, carbonate, carbamate, thiol, sulfide, thioketone moiety or hetero-aromatic ring, 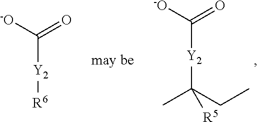
Z is magnesium, copper or zinc, a1, a2, b1 and b2 are numbers in the range: 0≦a1≦0.9, 0≦a2≦0.9, 0<a1+a2<1, 0≦b1≦0.8, 0≦b2≦0.8, and 0<b1+b2≦0.8.

3. The resist composition of claim 2 wherein in addition to recurring units (a1), (a2), (b1) and (b2), the polymer comprises recurring units (c1), (c2) or (c3) of a sulfonium salt having the general formula (2): 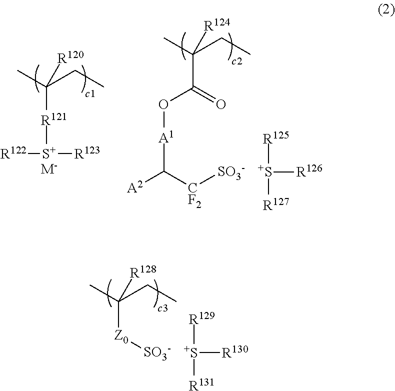
wherein R¹²⁰, R¹²⁴, and R¹²⁸ each are hydrogen or methyl, R¹²¹ is a single bond, phenylene, —O—R—, or —C(═O)—Y—R—, Y is oxygen or NH, R is a straight, branched or cyclic C₁-C₆ alkylene group, C₃-C₁₀ alkenylene or phenylene group, which may contain a carbonyl, ester, ether or hydroxyl moiety, R¹²², R¹²³, R¹²⁵, R¹²⁶, R¹²⁷, R¹²⁹, R¹³⁰, and R¹³¹ are each independently a straight, branched or cyclic C₁-C₁₂ alkyl group which may contain a carbonyl, ester or ether moiety, or a C₆-C₁₂ aryl, C₇-C₂₀ aralkyl, or thiophenyl group, A¹ is a single bond, -A⁰—C(═O)—O— or -A⁰-O—C(═O)—, A⁰ is a straight, branched or cyclic C₁-C₁₂ alkylene group which may contain a carbonyl, ester or ether moiety, A² is hydrogen or CF₃, Z₀ is a single bond, methylene, ethylene, phenylene, fluorophenylene, —O—R¹³²—, or —C(═O)—Z₁—R¹³²—, Z₁ is oxygen or NH, R¹³² is a straight, branched or cyclic C₁-C₆ alkylene group, alkenylene, phenylene, fluorophenylene, or trifluoromethyl-substituted phenylene group, which may contain a carbonyl, ester, ether or hydroxyl moiety, M⁻ is a non-nucleophilic counter ion, c1, c2 and c3 are in the range of 0≦c1≦0.3, 0≦c2≦0.3, 0≦c3≦0.3, and 0<c1+c2+c3≦0.3.

4. The resist composition of claim 1 wherein the polymer has further copolymerized therein recurring units having an adhesive group selected from the group consisting of phenolic hydroxyl, hydroxyl other than phenolic hydroxyl, carboxyl, lactone ring, carbonate, thiocarbonate, carbonyl, cyclic acetal, ether, ester, sulfonic acid ester, cyano, amide, and —O—C(═O)-G- wherein G is sulfur or NH.

5. The resist composition of claim 1 which is a chemically amplified positive resist composition.

6. The resist composition of claim 1, further comprising at least one component selected from among an organic solvent, a dissolution inhibitor, an acid generator, a basic compound, and a surfactant.

7. A pattern forming process comprising the steps of coating the resist composition of claim 1 onto a substrate, baking, exposing to high-energy radiation, and developing with a developer.

8. The process of claim 7 wherein the high-energy radiation is EUV radiation having a wavelength of 3 to 15 nm.

9. The process of claim 7 wherein the high-energy radiation is an electron beam at an accelerating voltage of 1 to 150 keV.
